(19) United States
(12) Patent Application Publication
(10) Pub. No.: US 2014/0217378 A1
(43) Pub. Date: Aug. 7, 2014

(54) ORGANIC ELECTROLUMINESCENT ELEMENT

(71) Applicants: Kazuki Nishimura, Sodegaura-shi (JP); Toshinari Ogiwara, Sodegaura-shi (JP); Taakshi Arakane, Sodegaura-shi (JP); Kumiko Hibino, Sodegaura-shi (JP)

(72) Inventors: Kazuki Nishimura, Sodegaura-shi (JP); Toshinari Ogiwara, Sodegaura-shi (JP); Taakshi Arakane, Sodegaura-shi (JP); Kumiko Hibino, Sodegaura-shi (JP)

(73) Assignee: IDEMITSU KOSAN CO., LTD., Tokyo (JP)

(21) Appl. No.: 14/128,132

(22) PCT Filed: Jun. 20, 2012
(86) PCT No.: PCT/JP2012/065778

§ 371 Date: Dec. 20, 2013

(30) Foreign Application Priority Data
Jun. 24, 2011 (JP) 2011-141258

(51) Int. Cl. H01L 51/00

(52) U.S. Cl. CPC H01L 51/006; H01L 51/0072; H01L 51/0067; H01L 51/0071; H01L 51/0061
USPC 257/40

(57) ABSTRACT

An organic electroluminescence includes an anode, a cathode and at least an emitting layer interposed between the anode and the cathode, in which the emitting layer contains a first host material, a second host material and a phosphorescent dopant material as main components. The first host material is a compound represented by the following formula (1). The second host material is a compound represented by the following formula (2).

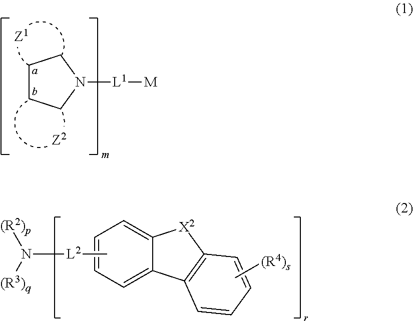

### TECHNICAL FIELD

The present invention relates to an organic electroluminescence device.

### BACKGROUND ART

There has been known an organic electroluminescence device (hereinafter, referred to as an “organic EL device”) that includes an emitting unit (in which an emitting layer is included) between an anode and a cathode and emits light using exciton energy generated by a recombination of holes and electrons that have been injected into the emitting layer.

As the organic EL device, a phosphorescent organic EL device using a phosphorescent dopant material as a luminescent material has been known. The phosphorescent organic EL device can achieve a high luminous efficiency by using the singlet state and the triplet state of the phosphorescent dopant material. It is believed that singlet excitons and triplet excitons are produced at a rate of 1:3 due to difference in spin multiplicity when electrons and holes are recombined in an emitting layer. Accordingly, it is presumed that the organic EL device using the phosphorescent dopant material can achieve a three to four times higher luminous efficiency than an organic EL device using only a fluorescent material.

Patent Literature 1 discloses a compound in which a nitrogen-containing heterocyclic group is bonded to an arylcarbazoyl group or a carbazoylalkylene group which is suitable as a phosphorescent host material combinable with a phosphorescent dopant material. By using the phosphorescent dopant material and this compound in the emitting layer, an organic EL device driven at a low voltage and having a high color purity can be obtained.

### CITATION LIST

### Patent Literature(s)

Patent Literature 1: International Publication No. WO2003/080760

### SUMMARY OF THE INVENTION

### Problems to be Solved by the Invention

However, since the phosphorescent host material disclosed in Patent Literature 1 has a large HOMO, it is difficult to inject holes to the emitting layer. Accordingly, in the organic EL device disclosed in Patent Literature 1, hole injection to the emitting layer is conducted using HOMO of the phosphorescent dopant material, where a concentration of the phosphorescent dopant material determines performance of the organic EL device. When the concentration of the phosphorescent dopant material is low, the hole injection to the emitting layer becomes difficult to cause insufficient recombination of holes and electrons, thereby reducing initial performance. Additionally, since light is emitted on an interface of the holes transporting layer, a life of the organic EL device is also shortened. However, when the concentration of the phosphorescent dopant material is increased, the luminous efficiency is reduced due to concentration quenching.

An object of the invention is to provide an organic electroluminescence device having a high luminous efficiency and a long life even using a phosphorescent dopant material having a low concentration.

### Means for Solving the Problems

After conducting concentrated studies in order to achieve such an object, the inventors have found that an energy barrier between the emitting layer and layers adjacent thereto can be decreased by the emitting layer containing a specific first host material and a specific second host material in combination as main components, whereby an injection efficiency of holes into the emitting layer can be improved with a low content of the phosphorescent dopant material. The invention has been achieved based on the above findings.

An organic electroluminescence according to an aspect of the invention includes an anode, a cathode and at least an emitting layer interposed between the anode and the cathode, in which the emitting layer contains a first host material, a second host material and a phosphorescent dopant material as main components, the first host material is a compound represented by the following formula (1), and the second host material is a compound represented by the following formula (2).

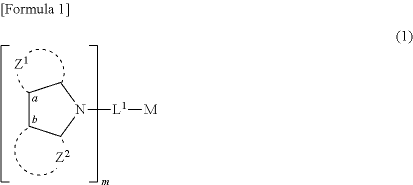

In the formula (1), Z¹ to be fused at a represents a cyclic structure represented by the following formula (1-1) or (1-2). Z² to be fused at b represents a cyclic structure represented by the following formula (1-1) or (1-2). At least one of Z¹ and Z² is represented by the formula (1-1). M is a substituted or unsubstituted nitrogen-containing heteroaromatic ring having 2 to 40 ring carbon atoms. L¹ is a single bond or a linking group and represents as the linking group a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group. m is 1 or 2.

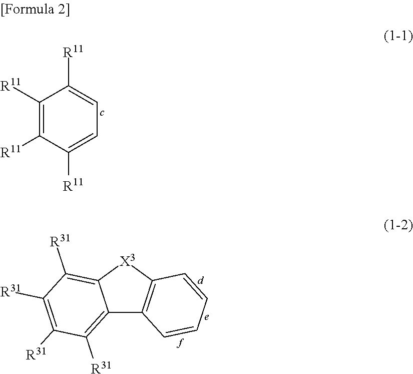

In the formulae (1-1) and (1-2), c, d, e and f are fused to a or b in the formula (1). R¹¹ and R³¹ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms. A plurality of R¹¹ may be mutually the same or different. A plurality of R³¹ may be mutually the same or different. X³ represents a sulfur atom, an oxygen atom or N—R³². R³² represents the same described above as R¹¹ and R³¹.

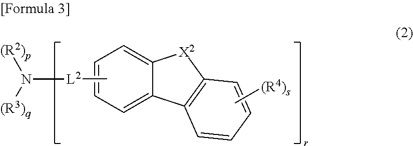

In the formula (2), X² represents a sulfur atom, an oxygen atom or N—R⁵. L² is a single bond or a linking group and represents the same as L¹ in the formula (1). R² and R³ each independently represent a substituted or unsubstituted aromatic hydrocarbon group having 6 to 30 ring carbon atoms, or a substituted or unsubstituted aromatic heterocyclic group having 2 to 30 ring carbon atoms. R⁴ and R⁵ are the same as R¹¹ and R³¹ in the formulae (1-1) and (1-2). p and q represent an integer of 0 to 2 and r represents an integer of 1 to 3, provided that p+q+r=3. s represents an integer 1 to 4. When s is an integer of 2 to 4, a plurality of R⁴ are optionally the same or different.

It should be noted that “as the main component” means that the first host material is contained in the emitting layer with a content of 50 mass % or more.

In the organic EL device according to the above aspect of the invention, the first host material is preferably represented by a formula (3) below.

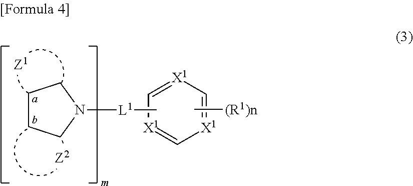

In the formula (3), Z¹ to be fused at a represents a cyclic structure represented by the formula (1-1) or (1-2). Z² to be fused at b represents a cyclic structure represented by the formula (1-1) or (1-2); At least one of Z¹ and Z² is represented by the formula (1-1). L¹ is a single bond or a linking group and represents as the linking group a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group.

X¹ is a nitrogen atom or C—R¹⁰, and at least one of a plurality of X¹ is a nitrogen atom.

R¹ and R¹⁰ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms. m and n are an integer of 1 to 2.

In the formulae (1-1) and (1-2), c, d, e and f are fused to a or b in the formula (3).

Examples of a compound represented by the formula (3) in which a and b are fused to the cyclic structures represented by the formulae (1-1) and (1-2) are compounds represented by the following formulae.

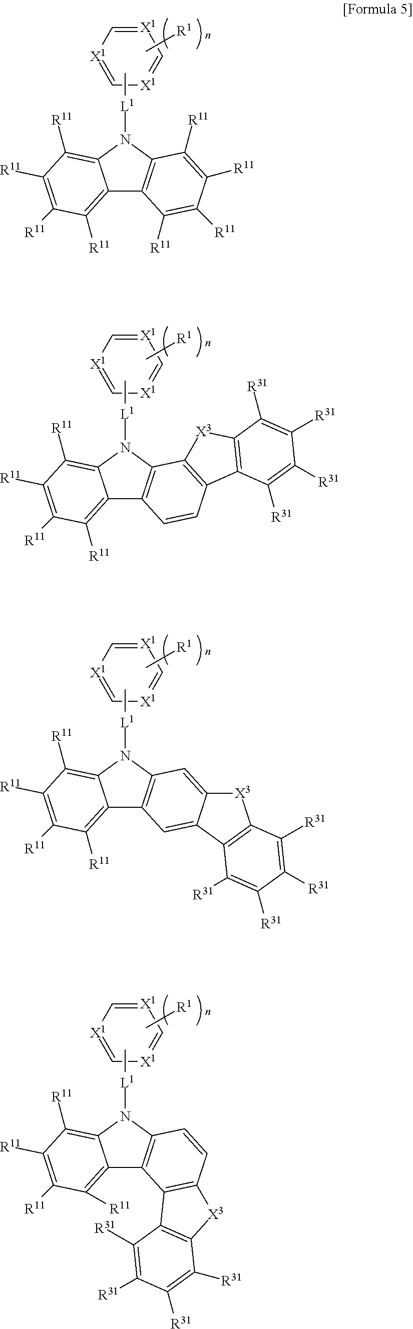

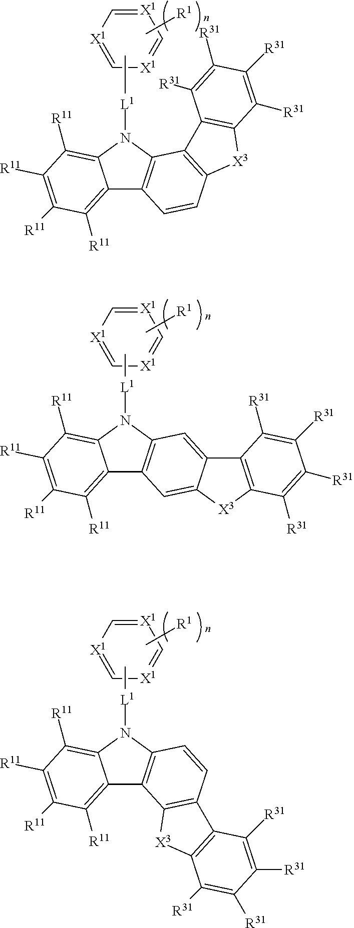

In the organic EL device according to the above aspect of the invention, the first host material is preferably represented by a formula (4) below.

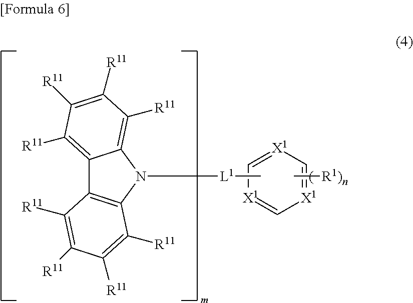

In the formula (4), L¹ represents a single bond or a linking group and represents as the linking group a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group.

X¹ is a nitrogen atom or C—R¹⁰, and at least one of a plurality of X¹ is a nitrogen atom.

R¹, R¹⁰ and R¹¹ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms. m and n are an integer of 1 to 2.

In the organic electroluminescence device according to the above aspect of the invention, an ionization potential Ip(h1) of the first host material, an ionization potential Ip(h2) of the second host material and an ionization potential Ip(d) of the phosphorescent dopant material preferably satisfy the following relationship:

Ip(h1)>Ip(h2)>Ip(d)

Further, in the organic electroluminescence device according to the above aspect of the invention, a wavelength of an emission peak of the phosphorescent dopant material is preferably in a range of 510 nm to 570 nm.

According to the above aspects of the inventions, an organic electroluminescence device having a high luminous efficiency and a long life even using a phosphorescent dopant material at a low concentration can be provided.

### BRIEF DESCRIPTION OF DRAWINGS

FIG. 1 schematically shows an exemplary arrangement of an organic EL device according to a first exemplary embodiment of the invention.

FIG. 2 schematically shows an exemplary arrangement of an organic EL device according to a second exemplary embodiment.

FIG. 3 schematically shows an exemplary arrangement of an organic EL device according to a third exemplary embodiment.

### DESCRIPTION OF EMBODIMENT(S)

### First Exemplary Embodiment

Arrangement of Organic EL Device

Arrangement(s) of an organic electroluminescence device (hereinafter, referred to as an organic EL device) according to the invention will be described below.

The followings are representative arrangement examples of the organic EL device:

(1) anode/emitting layer/cathode;
(2) anode/hole injecting layer/emitting layer/cathode;
(3) anode/emitting layer/electron injecting•transporting layer/cathode;
(4) anode/hole injecting layer/emitting layer/electron injecting•transporting layer/cathode; and
(5) anode/hole injecting•transporting layer/emitting layer/electron injecting•transporting layer/cathode.

While the arrangement (5) is preferably used among the above, the arrangement of the invention is not limited to the above arrangements.

It should be noted that the aforementioned “emitting layer” is an organic layer in which a doping system is applied and a host material and a dopant material are contained. The host material generally promotes recombination of electrons and holes and transmits excited energy generated by the recombination to the dopant material. The dopant material is preferably a compound having a high quantum yield. The dopant material after receiving the excited energy from the host material exhibits a high luminescent performance.

The “hole injecting/transporting layer” (or hole injecting•transporting layer) means “at least one of a hole injecting layer and a hole transporting layer” while the “electron injecting/transporting layer” (or electron injecting•transporting layer) means “at least one of an electron injecting layer and an electron transporting layer.” Herein, when the hole injecting layer and the hole transporting layer are provided, the hole injecting layer is preferably adjacent to the anode. When the electron injecting layer and the electron transporting layer are provided, the electron injecting layer is preferably adjacent to the cathode.

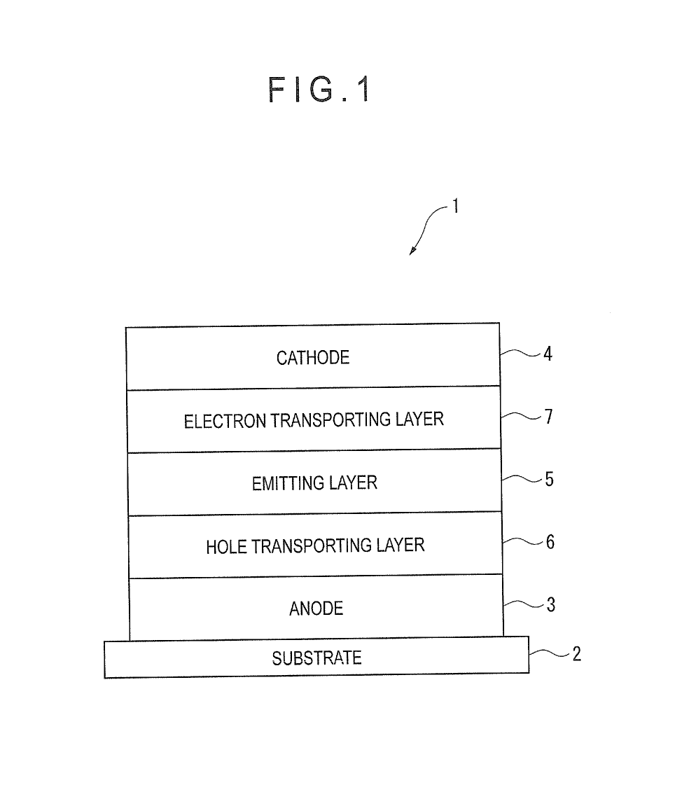

Next, an organic EL device 1 in the first exemplary embodiment is shown in FIG. 1.

The organic EL device 1 includes a transparent substrate 2, an anode 3, a cathode 4, a hole transporting layer 6, an emitting layer 5 and an electron transporting layer 7.

The hole transporting layer 6, the emitting layer 5, the electron transporting layer 7 and the cathode 4 are sequentially laminated from the anode 3.

### Emitting Layer

The emitting layer 5 contains a first host material, a second host material and a phosphorescent dopant material as main components.

The emitting layer contains the first host material in a range of 50 mass % to 90 mass %, the second host material in a range of 5 mass % to 50 mass % and the phosphorescent dopant material in a range of 0.1 mass % to 30 mass %. Herein, the first host material, the second host material and the phosphorescent dopant material preferably accounts for 100 mass % in total in the emitting layer.

The emitting layer 5 has a function for providing recombination of electrons and holes to emit light.

### First Host Material

The first host material used in the organic EL device according to the exemplary embodiment may be a compound represented by the following formula (1).

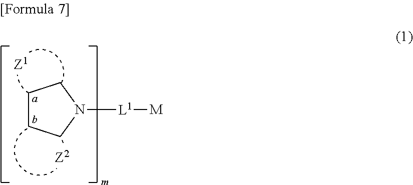

In the formula (1), Z¹ to be fused at a represents a cyclic structure represented by the following formula (1-1) or (1-2). Z² to be fused at b represents a cyclic structure represented by the following formula (1-1) or (1-2). At least one of Z¹ and Z² is represented by the following formula (1-1). M is a substituted or unsubstituted nitrogen-containing heteroaromatic ring having 2 to 40 ring carbon atoms. L¹ is a single bond or a linking group and represents as the linking group a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group. m is 1 or 2.

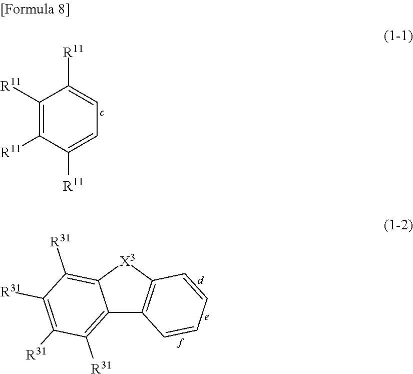

In the formulae (1-1) and (1-2), c, d, e and f are fused to a or b in the formula (1). R¹¹ and R³¹ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms.

A plurality of R¹¹ may be mutually the same or different. A plurality of R³¹ may be mutually the same or different.

X³ represents a sulfur atom, an oxygen atom or N—R³².

R³² represents the same described above as R¹¹ and R³¹.

In the formula (1-1), c is fused a or b in the formula (1).

In the formula (1-2), one of d, e and f is fused to a or b in the formula (1).

It should be noted that “as the main component” means that the first host material is contained in the emitting layer with a content of 50 mass % or more.

Further, the “nitrogen-containing heteroaromatic ring” includes an azine ring.

In the invention, a “hydrogen atom” means isotopes having different neutron numbers and specifically encompasses protium, deuterium and tritium.

Examples of the nitrogen-containing heteroaromatic ring represented by M in the formula (1) are pyridine, pyrimidine, pyrazine, triazine, aziridine, azaindolizine, indolizine, imidazole, indole, isoindole, indazole, purine, pteridine, β-carboline, naphthyridine, quinoxaline, terpyridine, bipyridine, acridine, phenanthroline, phenazine and imidazopyridine.

Particularly, pyridine, pyrimidine and triazine are favorable. The first host material is preferably represented by the following formula (3).

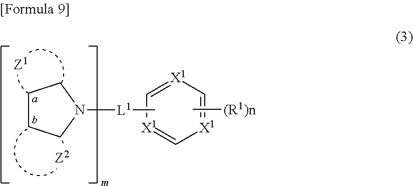

In the formula (3), Z¹ to be fused at a represents a cyclic structure represented by the formula (1-1) or (1-2). Z² to be fused at b represents a cyclic structure represented by the formula (1-1) or (1-2). At least one of Z¹ and Z² is represented by the following formula (1-1).

L¹ is a single bond or a linking group and represents as the linking group a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group.

X¹ is a nitrogen atom or C—R¹⁰. At least one of a plurality of X¹ is a nitrogen atom.

R¹ and R¹⁰ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms. m and n are an integer of 1 to 2,

In the formulae (1-1) and (1-2), c, d, e and f are fused to a or b in the formula (3).

a and b in the formula (3) are fused to c in the formula (1-1) or one of d, e and f in the formula (1-2).

The plurality of X¹ may be mutually the same or different.

When n is 2, a plurality of R¹ may be mutually the same or different.

Herein, examples of the compound represented by the formula (3) in which a and b are fused to the cyclic structures represented by the formulae (1-1) and (1-2) are compounds represented by the following formula.

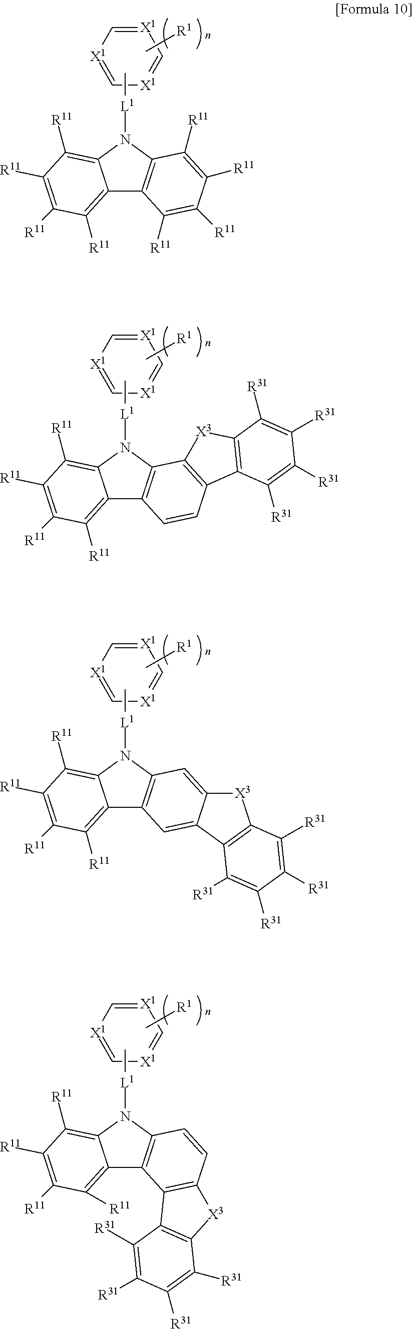

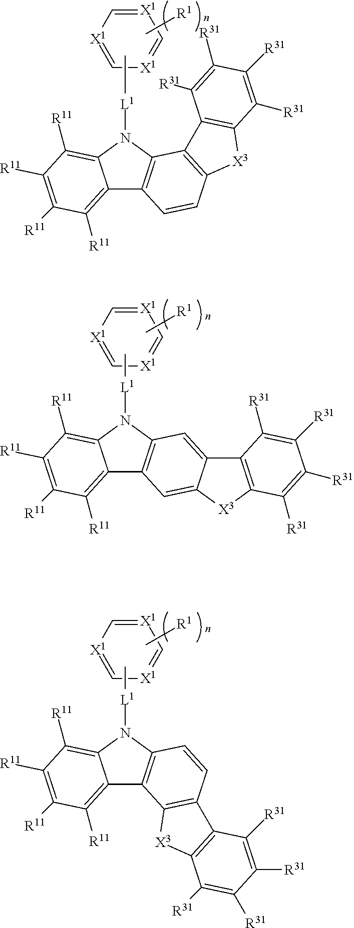

The first host material is more preferably represented by the following formula (4).

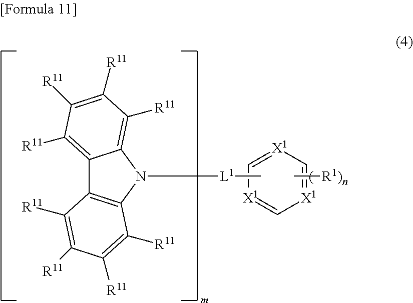

In the formula (4), L¹ represents a single bond or a linking group. Examples of the linking group include a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group.

X¹ is a nitrogen atom or C—R¹⁰. At least one of a plurality of X¹ is a nitrogen atom.

R¹, R¹⁰ and R¹¹ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms. m and n each are an integer of 1 to 2.

A plurality of R¹¹ may be mutually the same or different. A plurality of X¹ may be mutually the same or different. A plurality of R¹ may be mutually the same or different.

Moreover, the plurality of R¹ may be mutually the same or different when n is 2 or more.

In the formulae (1), (3), (4), (1-1) and (1-2), the alkyl group, alkoxy group, haloalkyl group, haloalkoxy group and alkylsilyl group, which are represented by R¹, R¹⁰ to R¹¹ and R³¹ to R³², may be linear, branched or cyclic.

In the formulae (1), (3), (4), (1-1) and (1-2), examples of the alkyl group having 1 to 20 carbon atoms are a methyl group, ethyl group, propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neo-pentyl group, 1-methylpentyl group, 2-methylpentyl group, 1-pentylhexyl group, 1-butylpentyl group, 1-heptyloctyl group, 3-methylpentyl group, cyclopentyl group, cyclohexyl group, cyclooctyl group and 3,5-tetramethylcyclohexyl group.

As the alkoxy group having 1 to 20 carbon atoms, an alkoxy group having 1 to 6 carbon atoms is preferable and specific examples thereof are a methoxy group, ethoxy group, propoxy group, butoxy group, pentyloxy group, and hexyloxy group.

The haloalkyl group having 1 to 20 carbon atoms is exemplified by a haloalkyl group provided by substituting the alkyl group having 1 to 20 carbon atoms with one or more halogen groups.

The haloalkoxy group having 1 to 20 carbon atoms is exemplified by a haloalkoxy group provided by substituting the alkoxy group having 1 to 20 carbon atoms by one or more halogen groups.

Examples of the alkylsilyl group having 1 to 10 carbon atoms are a trimethylsilyl group, triethylsilyl group, tributylsilyl group, dimethylethylsilyl group, dimethylisopropylsilyl group, dimethylpropylsilyl group, dimethylbutylsilyl group, dimethyl-tertiary-butylsilyl group and diethylisopropylsilyl group.

Examples of the arylsilyl group having 6 to 30 carbon atoms are a phenyldimethylsilyl group, diphenylmethylsilyl group, diphenyl-tertiary-butylsilyl group and triphenylsilyl group.

Examples of the aromatic heterocyclic group having 2 to 30 ring carbon atoms (including a fused aromatic heterocyclic group) are a pyroryl group, pyrazinyl group, pyridinyl group, indolyl group, isoindolyl group, furyl group, benzofuranyl group, isobenzofuranyl group, dibenzofuranyl group, dibenzothiophenyl group, quinolyl group, isoquinolyl group, quinoxalinyl group, carbazolyl group, phenanthrydinyl group, acridinyl group, phenanthrolinyl group, thienyl group, and group formed based on a pyridine ring, pyrazine ring, pyrimidine ring, pyridazine ring, triazine ring, indole ring, quinoline ring, acridine ring, pyrrolidine ring, dioxane ring, piperidine ring, morpholine ring, piperazine ring, carbazole ring, furan ring, thiophene ring, oxazole ring, oxadiazole ring, benzoxazole ring, thiazole ring, thiadiazole ring, benzothiazole ring, triazole ring, imidazole ring, benzimidazole ring, pyrane ring and dibenzofuran ring.

Examples of the aromatic hydrocarbon group having 6 to 30 ring carbon atoms (including a fused aromatic hydrocarbon group) are a phenyl group, naphthyl group, phenanthryl group, biphenyl group, terphenyl group, quarterphenyl group, fluoranthenyl group, triphenylenyl group, phenanthrenyl group and fluorenyl group.

The aromatic hydrocarbon group having 6 to 30 ring carbon atoms and the aromatic heterocyclic group having 2 to 30 ring carbon atoms represented by L¹ in the formulae (1), (3) and (4) are exemplified by divalent groups derived from the above-described groups.

Examples of the cyclic hydrocarbon group having 5 to 30 ring carbon atoms are a cyclopentyl group, cyclohexylene group, and cyclohepthylene group.

When L¹, X¹ to X², R¹, R¹⁰ to R¹¹ and R³¹ to R³² of the formulae (1), (3), (4), (1-1) and (1-2) each have one or more substituents, the substituents are preferably a linear, branched or cyclic alkyl group having 1 to 20 carbon atoms; linear, branched or cyclic alkoxy group having 1 to 20 carbon atoms; linear, branched or cyclic haloalkyl group having 1 to 20 carbon atoms; linear, branched or cyclic alkylsilyl group having 1 to 10 carbon atoms; arylsilyl group having 6 to 30 ring carbon atoms; cyano group; halogen atom; aromatic hydrocarbon group or fused aromatic hydrocarbon group having 6 to 30 ring carbon atoms; or aromatic heterocyclic group or fused aromatic heterocyclic group having 2 to 30 ring carbon atoms.

Examples of the linear, branched or cyclic alkyl group having 1 to 20 carbon atoms; linear, branched or cyclic alkoxy group having 1 to 20 carbon atoms; linear, branched or cyclic haloalkyl group having 1 to 20 carbon atoms; linear, branched or cyclic alkylsilyl group having 1 to 10 carbon atoms; arylsilyl group having 6 to 30 ring carbon atoms; aromatic hydrocarbon group or fused aromatic hydrocarbon group having 6 to 30 ring carbon atoms; and aromatic heterocyclic group or fused aromatic heterocyclic group having 2 to 30 ring carbon atoms are the above-described groups. The halogen atom is exemplified by a fluorine atom.

Examples of the compounds represented by the formulae (1) to (4) are as follows.

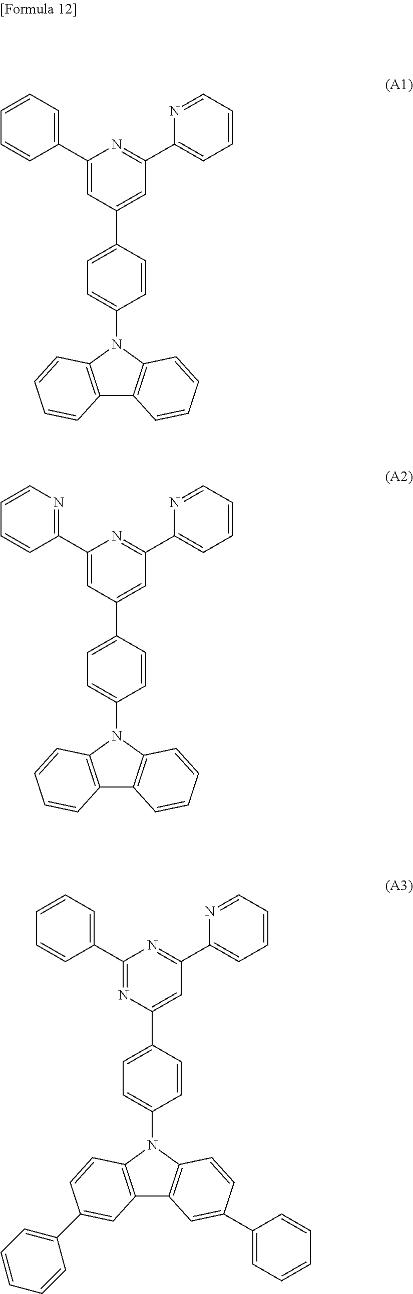 [SMILES: c1ccc(-c2cc(-c3ccc(-n4c5ccccc5c5ccccc54)cc3)cc(-c3ccccn3)n2)cc1 ; c1ccc(-c2cc(-c3ccc(-n4c5ccccc5c5ccccc54)cc3)cc(-c3ccccn3)n2)nc1 ; c1ccc(-c2ccc3c(c2)c2cc(-c4ccccc4)ccc2n3-c2ccc(-c3cc(-c4ccccn4)nc(-c4ccccc4)n3)cc2)cc1]

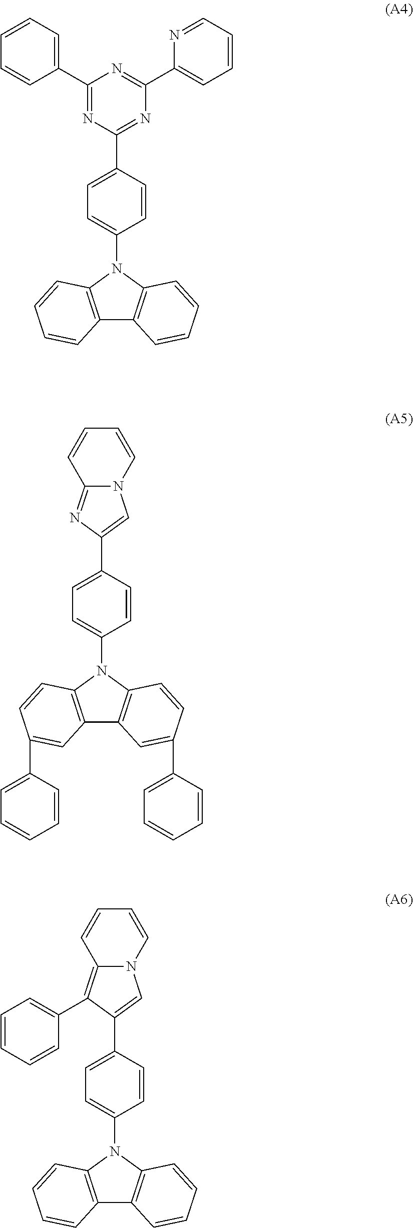 [SMILES: c1ccc(-c2nc(-c3ccc(-n4c5ccccc5c5ccccc54)cc3)nc(-c3ccccn3)n2)cc1 ; c1ccc(-c2ccc3c(c2)c2cc(-c4ccccc4)ccc2n3-c2ccc(-c3cn4ccccc4n3)cc2)cc1 ; c1ccc(-c2c(-c3ccc(-n4c5ccccc5c5ccccc54)cc3)cn3ccccc23)cc1]

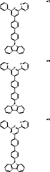 [SMILES: c1ccc(-c2cc(-c3ccc(-c4ccc(-n5c6ccccc6c6ccccc65)cc4)cc3)cc(-c3ccccn3)n2)cc1 ; c1ccc(-c2cc(-c3ccc(-c4ccc(-n5c6ccccc6c6ccccc65)cc4)cc3)cc(-c3ccccn3)n2)nc1 ; c1ccc(-c2nc(-c3ccc(-c4ccc(-n5c6ccccc6c6ccccc65)cc4)cc3)cc(-c3ccccn3)n2)cc1]

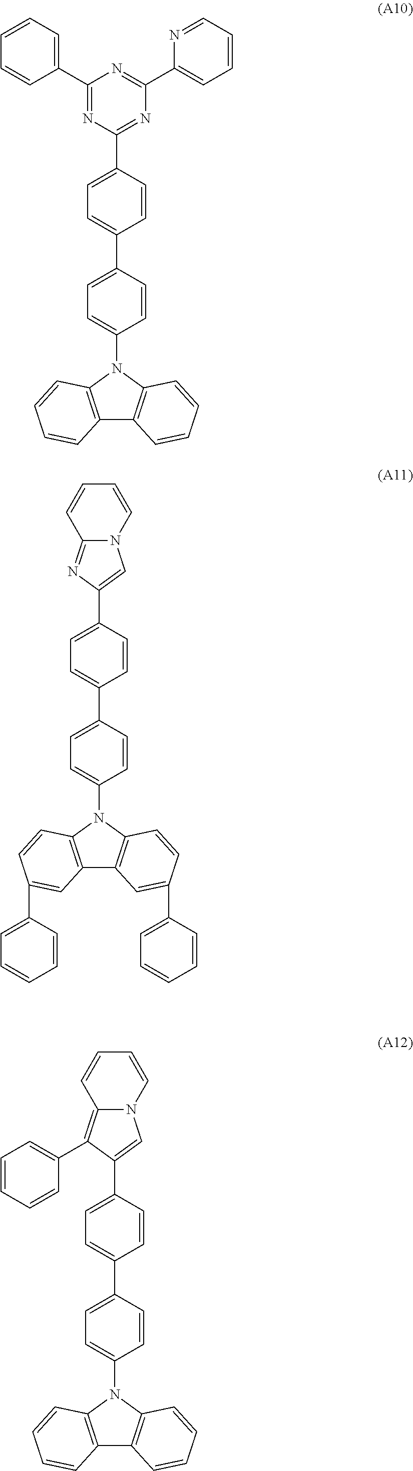

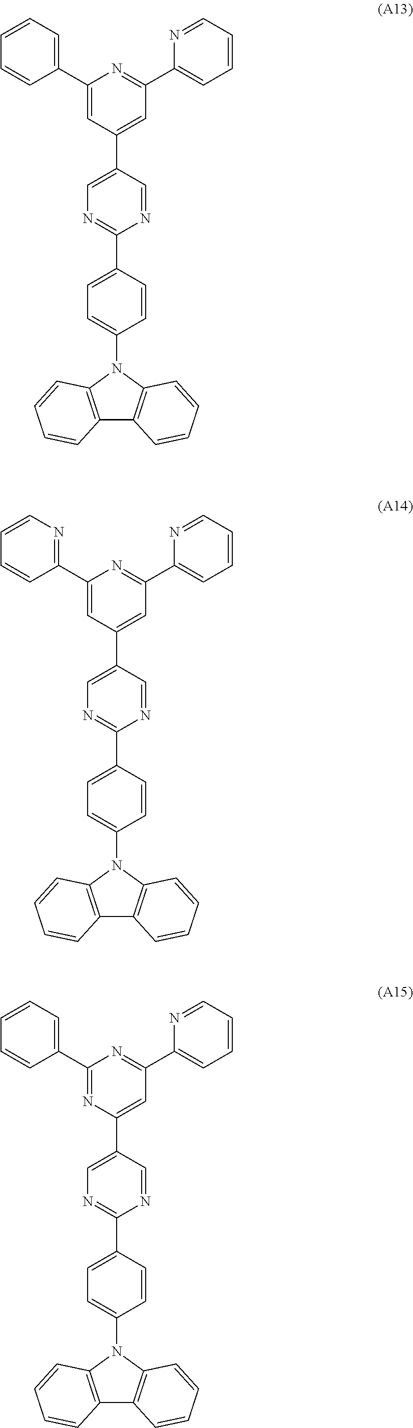 [SMILES: c1ccc(-c2cc(-c3cnc(-c4ccc(-n5c6ccccc6c6ccccc65)cc4)nc3)cc(-c3ccccn3)n2)cc1 ; c1ccc(-c2cc(-c3cnc(-c4ccc(-n5c6ccccc6c6ccccc65)cc4)nc3)cc(-c3ccccn3)n2)nc1 ; c1ccc(-c2nc(-c3cnc(-c4ccc(-n5c6ccccc6c6ccccc65)cc4)nc3)cc(-c3ccccn3)n2)cc1]

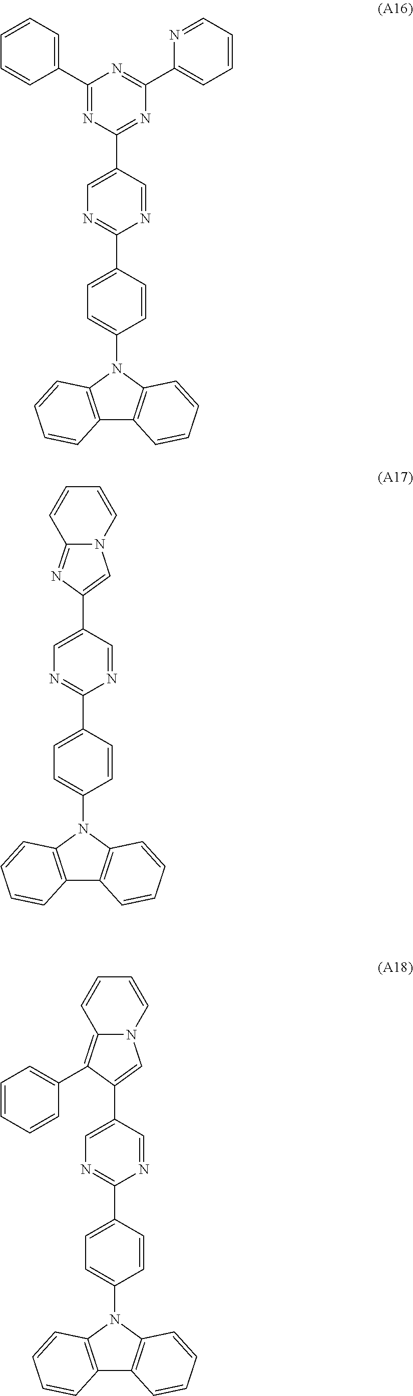

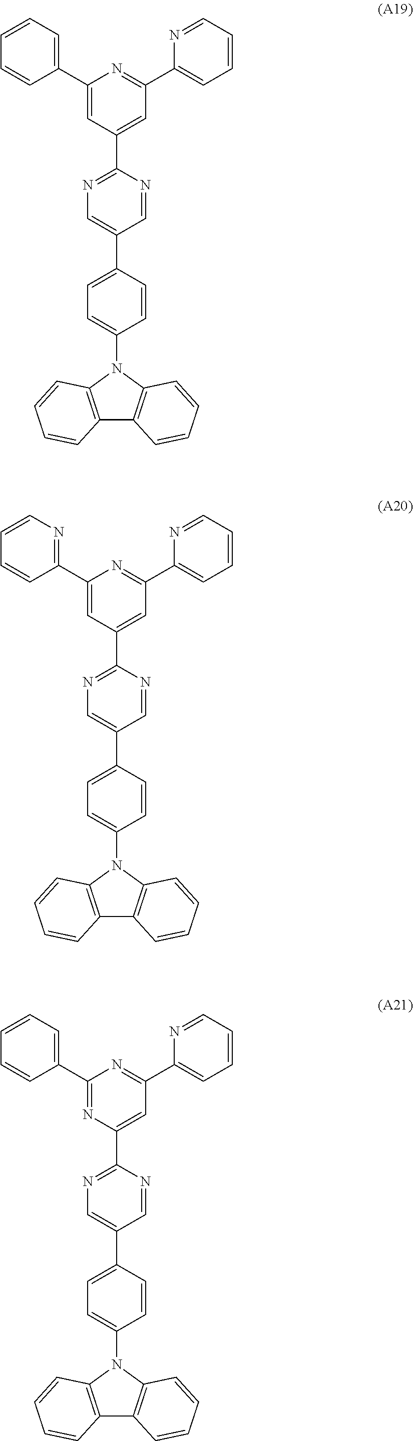 [SMILES: c1ccc(-c2cc(-c3ncc(-c4ccc(-n5c6ccccc6c6ccccc65)cc4)cn3)cc(-c3ccccn3)n2)cc1 ; c1ccc(-c2cc(-c3ncc(-c4ccc(-n5c6ccccc6c6ccccc65)cc4)cn3)cc(-c3ccccn3)n2)nc1 ; c1ccc(-c2nc(-c3ccccn3)cc(-c3ncc(-c4ccc(-n5c6ccccc6c6ccccc65)cc4)cn3)n2)cc1]

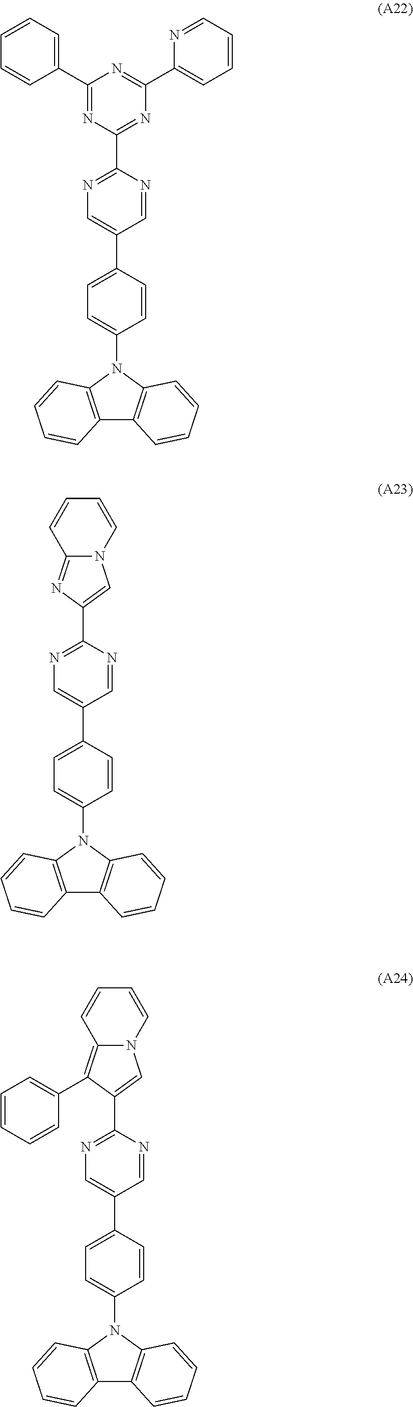 [SMILES: c1ccc(-c2nc(-c3ccccn3)nc(-c3ncc(-c4ccc(-n5c6ccccc6c6ccccc65)cc4)cn3)n2)cc1 ; c1ccc2c(c1)c1ccccc1n2-c1ccc(-c2cnc(-c3cn4ccccc4n3)nc2)cc1 ; c1ccc(-c2c(-c3ncc(-c4ccc(-n5c6ccccc6c6ccccc65)cc4)cn3)cn3ccccc23)cc1]

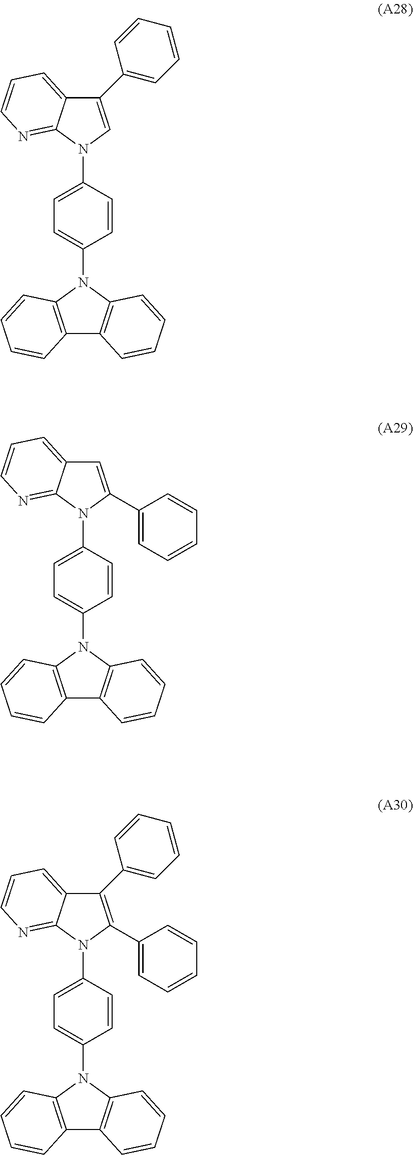 [SMILES: c1ccc(-c2cn(-c3ccc(-n4c5ccccc5c5ccccc54)cc3)c3ncccc23)cc1 ; c1ccc(-c2cc3cccnc3n2-c2ccc(-n3c4ccccc4c4ccccc43)cc2)cc1 ; c1ccc(-c2c(-c3ccccc3)n(-c3ccc(-n4c5ccccc5c5ccccc54)cc3)c3ncccc23)cc1]

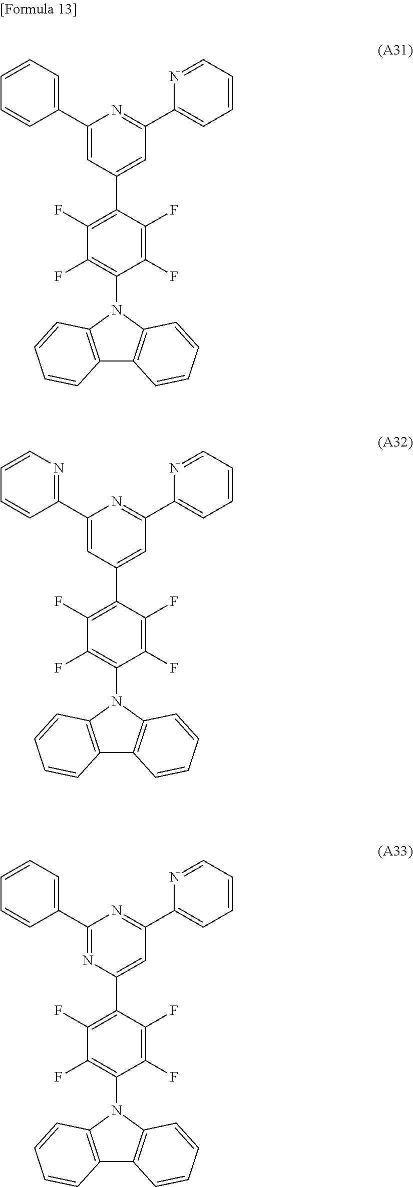 [SMILES: Fc1c(F)c(-n2c3ccccc3c3ccccc32)c(F)c(F)c1-c1cc(-c2ccccc2)nc(-c2ccccn2)c1 ; Fc1c(F)c(-n2c3ccccc3c3ccccc32)c(F)c(F)c1-c1cc(-c2ccccn2)nc(-c2ccccn2)c1 ; Fc1c(F)c(-n2c3ccccc3c3ccccc32)c(F)c(F)c1-c1cc(-c2ccccn2)nc(-c2ccccc2)n1]

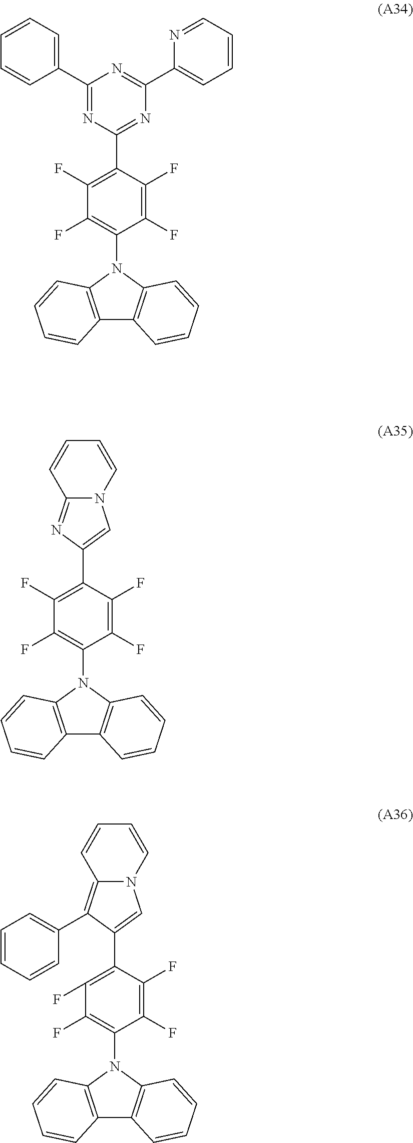 [SMILES: Fc1c(F)c(-n2c3ccccc3c3ccccc32)c(F)c(F)c1-c1nc(-c2ccccc2)nc(-c2ccccn2)n1 ; Fc1c(F)c(-n2c3ccccc3c3ccccc32)c(F)c(F)c1-c1cn2ccccc2n1 ; Fc1c(F)c(-n2c3ccccc3c3ccccc32)c(F)c(F)c1-c1cn2ccccc2c1-c1ccccc1]

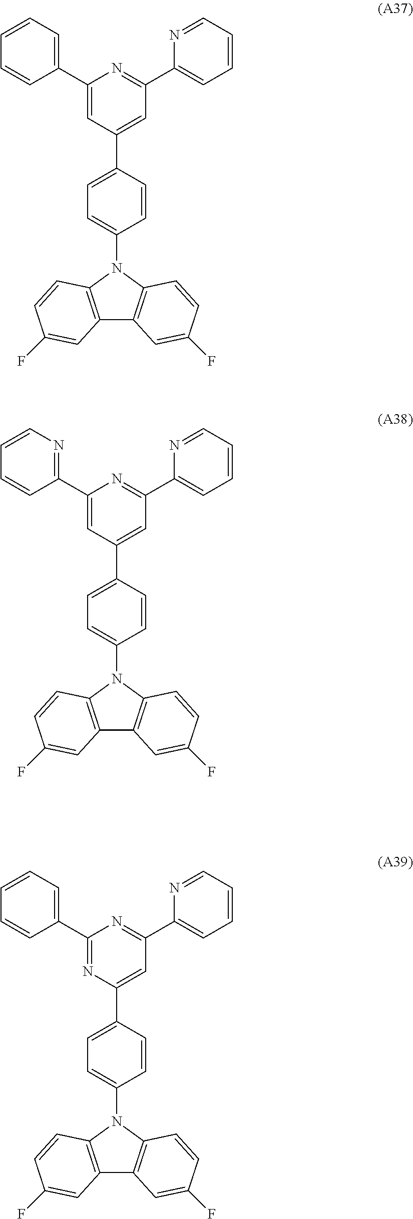 [SMILES: Fc1ccc2c(c1)c1cc(F)ccc1n2-c1ccc(-c2cc(-c3ccccc3)nc(-c3ccccn3)c2)cc1 ; Fc1ccc2c(c1)c1cc(F)ccc1n2-c1ccc(-c2cc(-c3ccccn3)nc(-c3ccccn3)c2)cc1 ; Fc1ccc2c(c1)c1cc(F)ccc1n2-c1ccc(-c2cc(-c3ccccn3)nc(-c3ccccc3)n2)cc1]

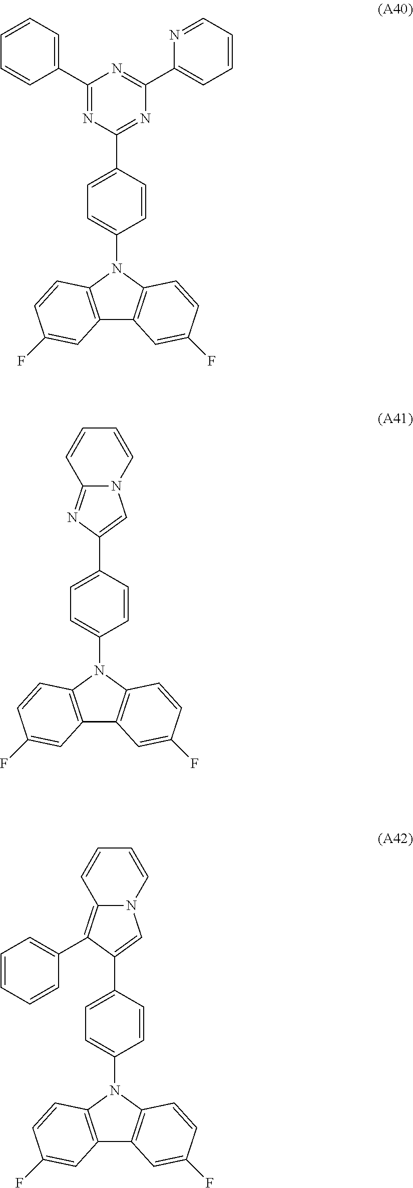 [SMILES: Fc1ccc2c(c1)c1cc(F)ccc1n2-c1ccc(-c2nc(-c3ccccc3)nc(-c3ccccn3)n2)cc1 ; Fc1ccc2c(c1)c1cc(F)ccc1n2-c1ccc(-c2cn3ccccc3n2)cc1 ; Fc1ccc2c(c1)c1cc(F)ccc1n2-c1ccc(-c2cn3ccccc3c2-c2ccccc2)cc1]

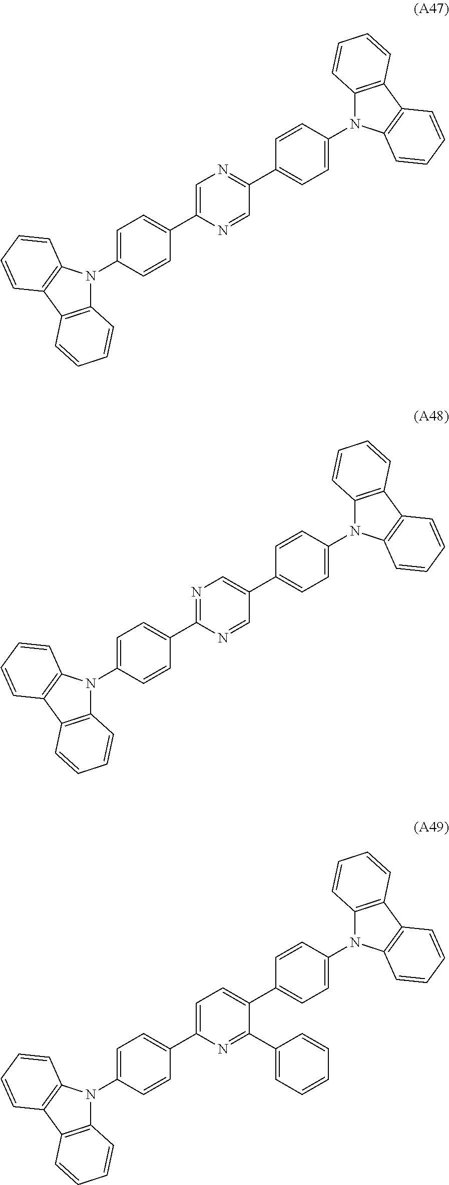 [SMILES: c1ccc2c(c1)c1ccccc1n2-c1ccc(-c2cnc(-c3ccc(-n4c5ccccc5c5ccccc54)cc3)cn2)cc1 ; c1ccc2c(c1)c1ccccc1n2-c1ccc(-c2cnc(-c3ccc(-n4c5ccccc5c5ccccc54)cc3)nc2)cc1 ; c1ccc(-c2nc(-c3ccc(-n4c5ccccc5c5ccccc54)cc3)ccc2-c2ccc(-n3c4ccccc4c4ccccc43)cc2)cc1]

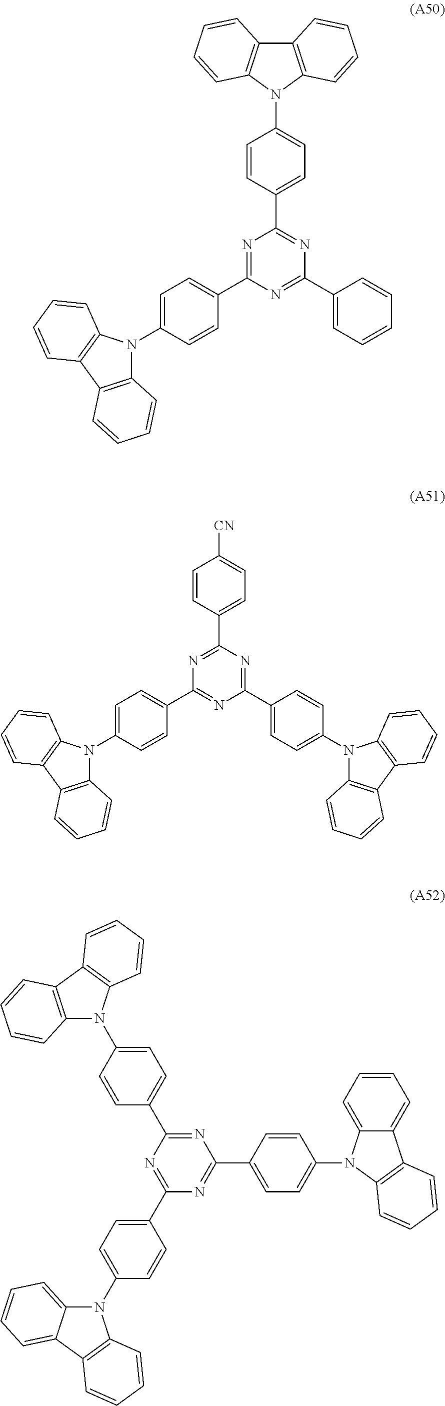 [SMILES: c1ccc(-c2nc(-c3ccc(-n4c5ccccc5c5ccccc54)cc3)nc(-c3ccc(-n4c5ccccc5c5ccccc54)cc3)n2)cc1 ; N#Cc1ccc(-c2nc(-c3ccc(-n4c5ccccc5c5ccccc54)cc3)nc(-c3ccc(-n4c5ccccc5c5ccccc54)cc3)n2)cc1 ; c1ccc2c(c1)c1ccccc1n2-c1ccc(-c2nc(-c3ccc(-n4c5ccccc5c5ccccc54)cc3)nc(-c3ccc(-n4c5ccccc5c5ccccc54)cc3)n2)cc1]

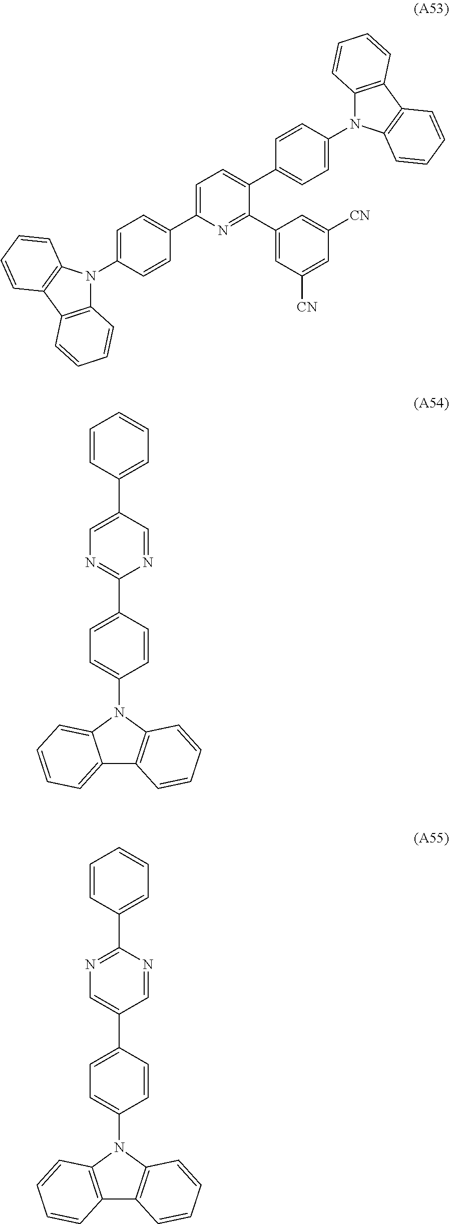 [SMILES: N#Cc1cc(C#N)cc(-c2nc(-c3ccc(-n4c5ccccc5c5ccccc54)cc3)ccc2-c2ccc(-n3c4ccccc4c4ccccc43)cc2)c1 ; c1ccc(-c2cnc(-c3ccc(-n4c5ccccc5c5ccccc54)cc3)nc2)cc1 ; c1ccc(-c2ncc(-c3ccc(-n4c5ccccc5c5ccccc54)cc3)cn2)cc1]

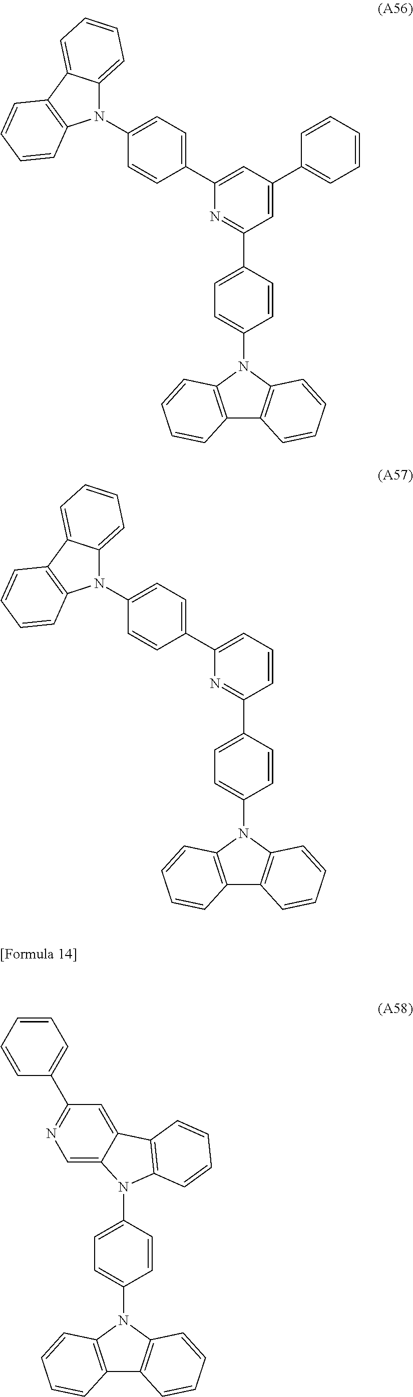 [SMILES: c1ccc(-c2cc(-c3ccc(-n4c5ccccc5c5ccccc54)cc3)nc(-c3ccc(-n4c5ccccc5c5ccccc54)cc3)c2)cc1 ; c1cc(-c2ccc(-n3c4ccccc4c4ccccc43)cc2)nc(-c2ccc(-n3c4ccccc4c4ccccc43)cc2)c1 ; c1ccc(-c2cc3c4ccccc4n(-c4ccc(-n5c6ccccc6c6ccccc65)cc4)c3cn2)cc1]

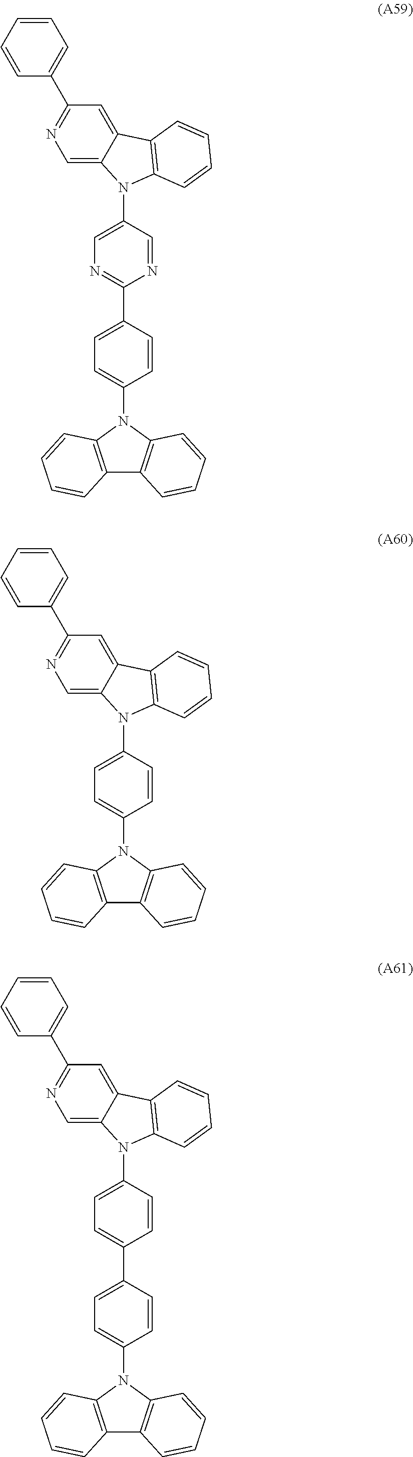 [SMILES: c1ccc(-c2cc3c4ccccc4n(-c4cnc(-c5ccc(-n6c7ccccc7c7ccccc76)cc5)nc4)c3cn2)cc1 ; c1ccc(-c2cc3c4ccccc4n(-c4ccc(-n5c6ccccc6c6ccccc65)cc4)c3cn2)cc1 ; c1ccc(-c2cc3c4ccccc4n(-c4ccc(-c5ccc(-n6c7ccccc7c7ccccc76)cc5)cc4)c3cn2)cc1]

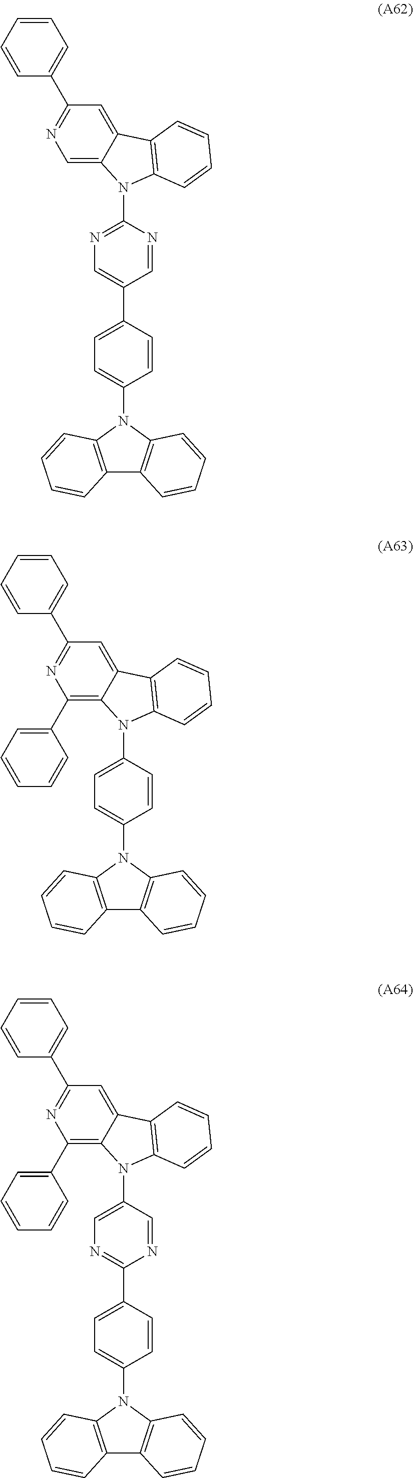 [SMILES: c1ccc(-c2cc3c4ccccc4n(-c4ncc(-c5ccc(-n6c7ccccc7c7ccccc76)cc5)cn4)c3cn2)cc1 ; c1ccc(-c2cc3c4ccccc4n(-c4ccc(-n5c6ccccc6c6ccccc65)cc4)c3c(-c3ccccc3)n2)cc1 ; c1ccc(-c2cc3c4ccccc4n(-c4cnc(-c5ccc(-n6c7ccccc7c7ccccc76)cc5)nc4)c3c(-c3ccccc3)n2)cc1]

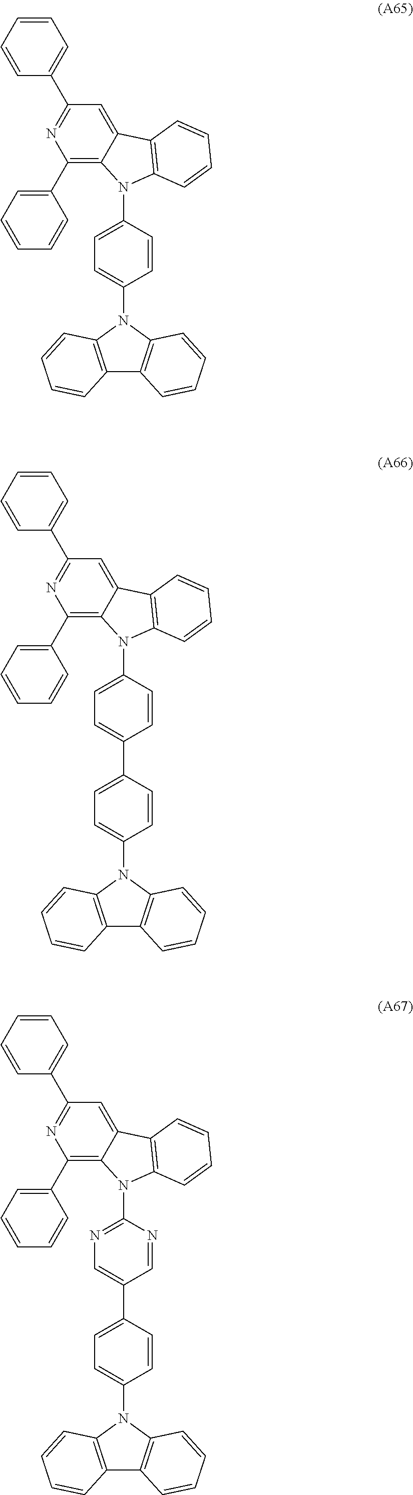 [SMILES: c1ccc(-c2cc3c4ccccc4n(-c4ccc(-n5c6ccccc6c6ccccc65)cc4)c3c(-c3ccccc3)n2)cc1 ; c1ccc(-c2cc3c4ccccc4n(-c4ccc(-c5ccc(-n6c7ccccc7c7ccccc76)cc5)cc4)c3c(-c3ccccc3)n2)cc1 ; c1ccc(-c2cc3c4ccccc4n(-c4ncc(-c5ccc(-n6c7ccccc7c7ccccc76)cc5)cn4)c3c(-c3ccccc3)n2)cc1]

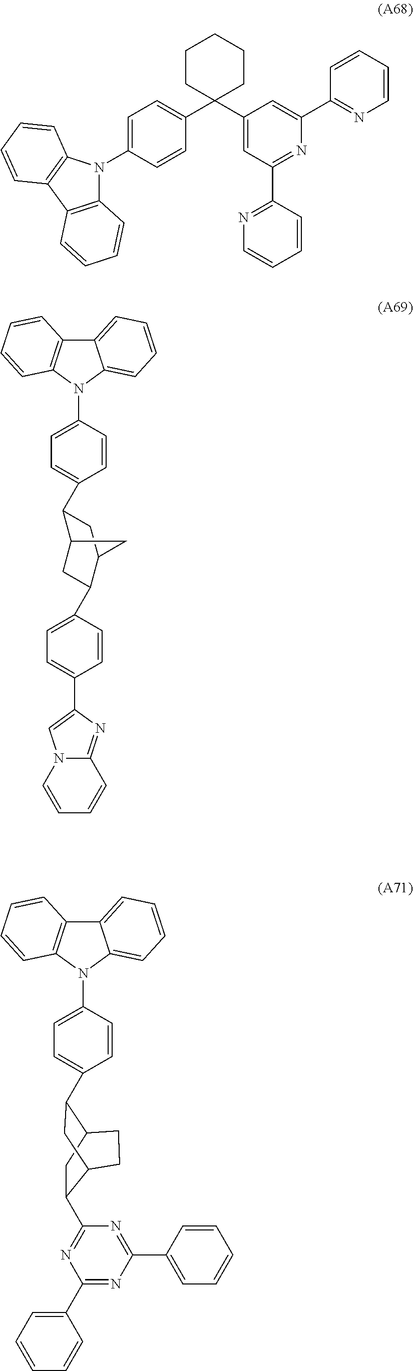 [SMILES: c1ccc(-c2cc(C3(c4ccc(-n5c6ccccc6c6ccccc65)cc4)CCCCC3)cc(-c3ccccn3)n2)nc1 ; c1ccc2c(c1)c1ccccc1n2-c1ccc(C2CC3CC2CC3c2ccc(-c3cn4ccccc4n3)cc2)cc1 ; c1ccc(-c2nc(-c3ccccc3)nc(C3CC4CCC3CC4c3ccc(-n4c5ccccc5c5ccccc54)cc3)n2)cc1]

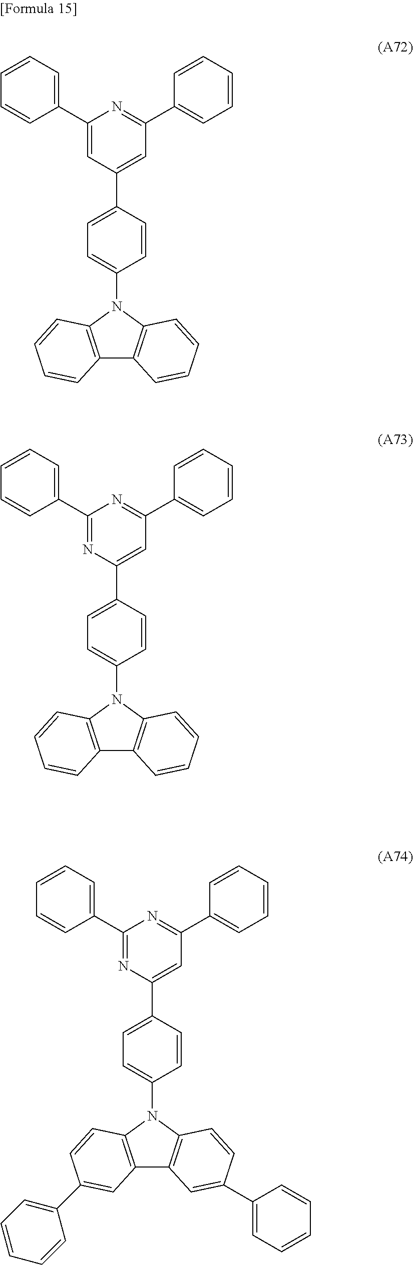 [SMILES: c1ccc(-c2cc(-c3ccc(-n4c5ccccc5c5ccccc54)cc3)cc(-c3ccccc3)n2)cc1 ; c1ccc(-c2cc(-c3ccc(-n4c5ccccc5c5ccccc54)cc3)nc(-c3ccccc3)n2)cc1 ; c1ccc(-c2ccc3c(c2)c2cc(-c4ccccc4)ccc2n3-c2ccc(-c3cc(-c4ccccc4)nc(-c4ccccc4)n3)cc2)cc1]

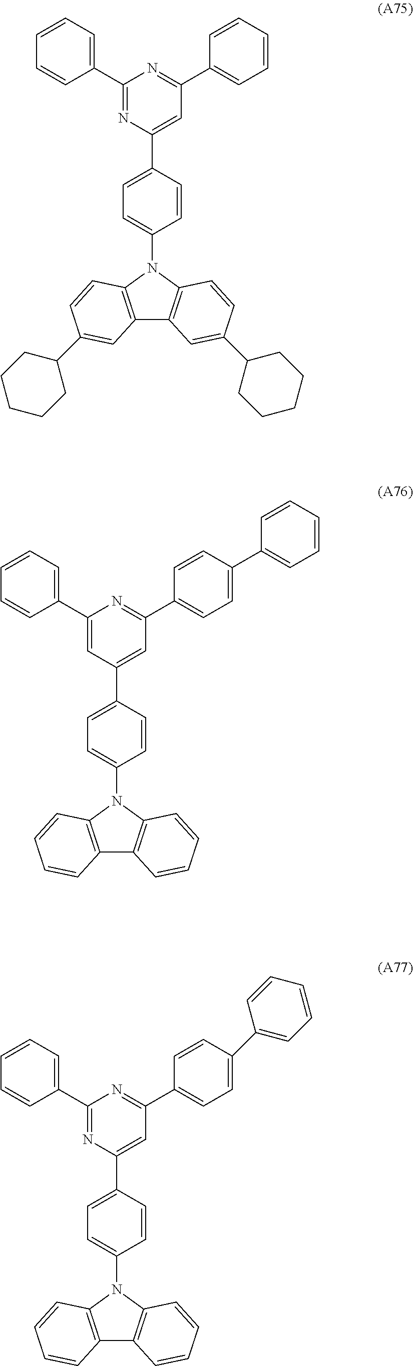 [SMILES: c1ccc(-c2cc(-c3ccc(-n4c5ccc(C6CCCCC6)cc5c5cc(C6CCCCC6)ccc54)cc3)nc(-c3ccccc3)n2)cc1 ; c1ccc(-c2ccc(-c3cc(-c4ccc(-n5c6ccccc6c6ccccc65)cc4)cc(-c4ccccc4)n3)cc2)cc1 ; c1ccc(-c2ccc(-c3cc(-c4ccc(-n5c6ccccc6c6ccccc65)cc4)nc(-c4ccccc4)n3)cc2)cc1]

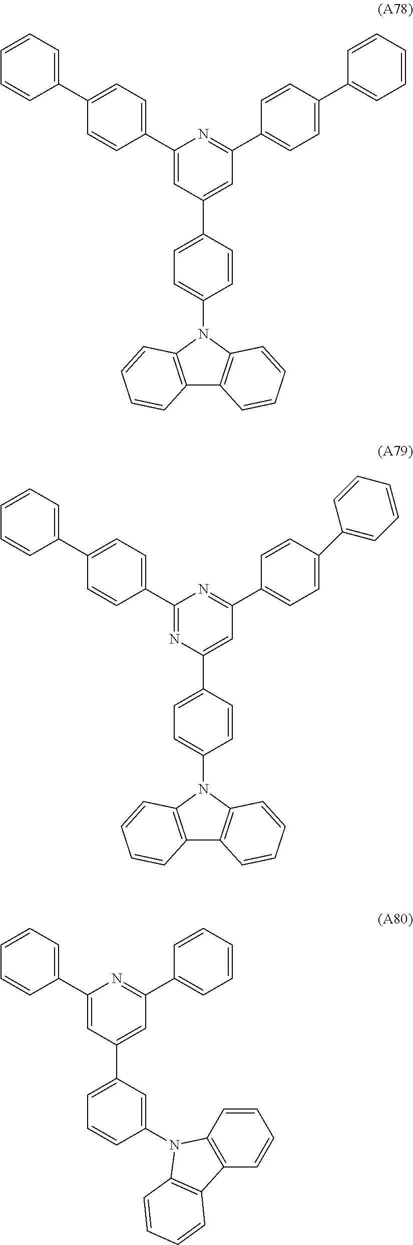 [SMILES: c1ccc(-c2ccc(-c3cc(-c4ccc(-n5c6ccccc6c6ccccc65)cc4)cc(-c4ccc(-c5ccccc5)cc4)n3)cc2)cc1 ; c1ccc(-c2ccc(-c3cc(-c4ccc(-n5c6ccccc6c6ccccc65)cc4)nc(-c4ccc(-c5ccccc5)cc4)n3)cc2)cc1 ; c1ccc(-c2cc(-c3cccc(-n4c5ccccc5c5ccccc54)c3)cc(-c3ccccc3)n2)cc1]

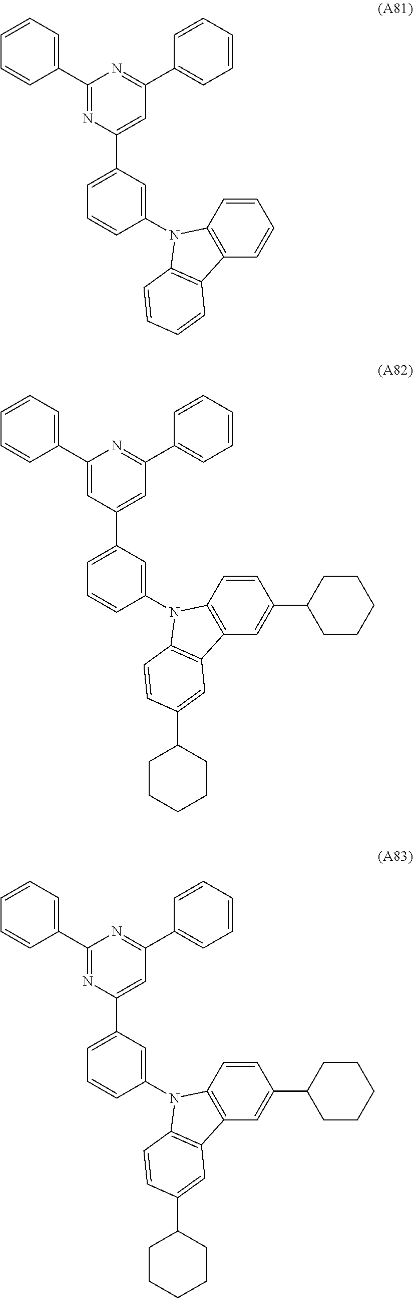 [SMILES: c1ccc(-c2cc(-c3cccc(-n4c5ccccc5c5ccccc54)c3)nc(-c3ccccc3)n2)cc1 ; c1ccc(-c2cc(-c3cccc(-n4c5ccc(C6CCCCC6)cc5c5cc(C6CCCCC6)ccc54)c3)cc(-c3ccccc3)n2)cc1 ; c1ccc(-c2cc(-c3cccc(-n4c5ccc(C6CCCCC6)cc5c5cc(C6CCCCC6)ccc54)c3)nc(-c3ccccc3)n2)cc1]

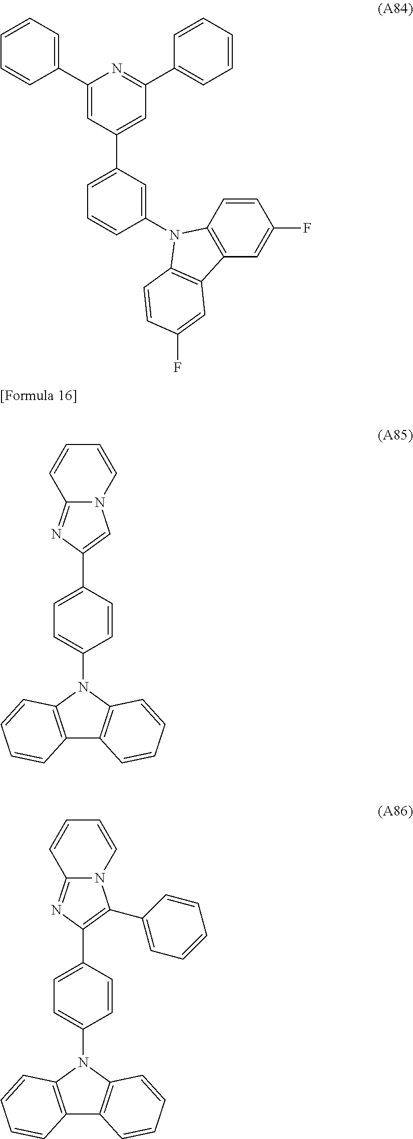 [SMILES: Fc1ccc2c(c1)c1cc(F)ccc1n2-c1cccc(-c2cc(-c3ccccc3)nc(-c3ccccc3)c2)c1 ; c1ccc2c(c1)c1ccccc1n2-c1ccc(-c2cn3ccccc3n2)cc1 ; c1ccc(-c2c(-c3ccc(-n4c5ccccc5c5ccccc54)cc3)nc3ccccn23)cc1]

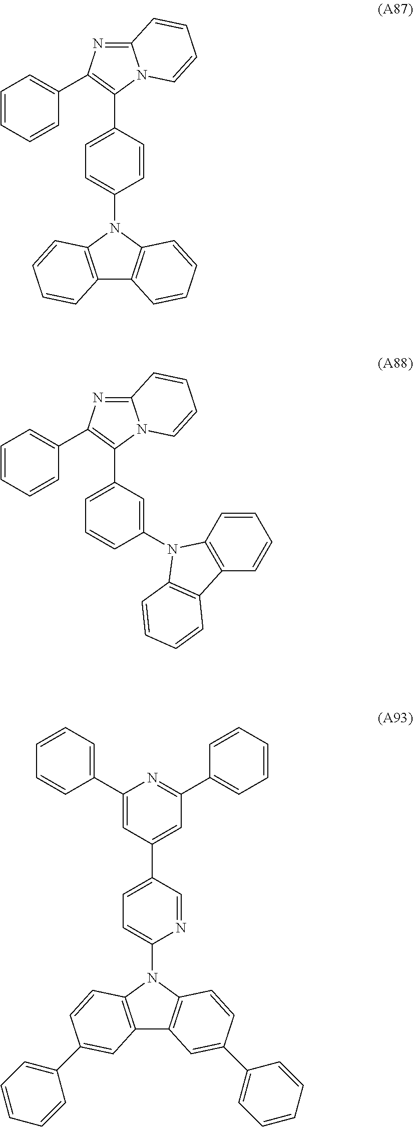 [SMILES: c1ccc(-c2nc3ccccn3c2-c2ccc(-n3c4ccccc4c4ccccc43)cc2)cc1 ; c1ccc(-c2nc3ccccn3c2-c2cccc(-n3c4ccccc4c4ccccc43)c2)cc1 ; c1ccc(-c2ccc3c(c2)c2cc(-c4ccccc4)ccc2n3-c2ccc(-c3cc(-c4ccccc4)nc(-c4ccccc4)c3)cn2)cc1]

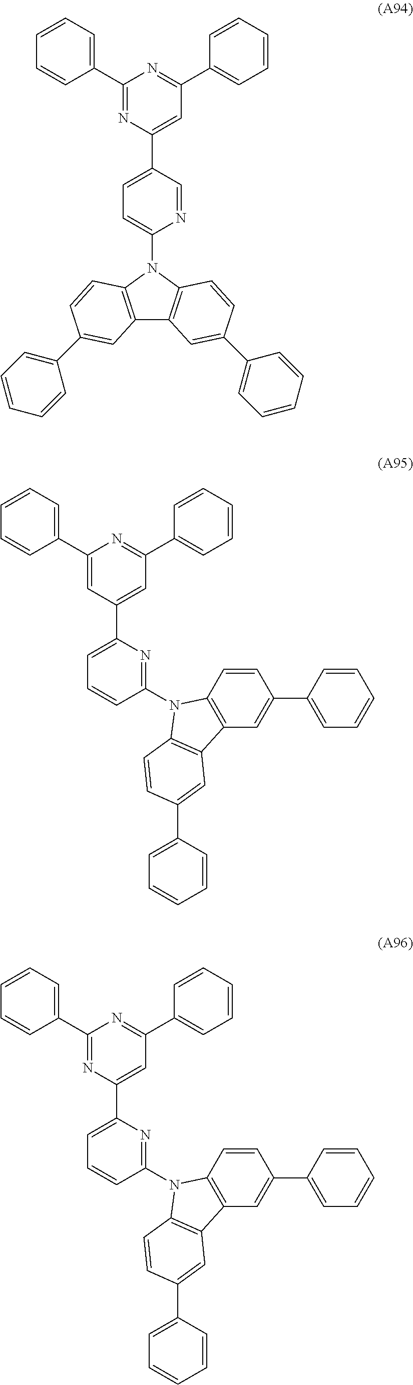 [SMILES: c1ccc(-c2ccc3c(c2)c2cc(-c4ccccc4)ccc2n3-c2ccc(-c3cc(-c4ccccc4)nc(-c4ccccc4)n3)cn2)cc1 ; c1ccc(-c2ccc3c(c2)c2cc(-c4ccccc4)ccc2n3-c2cccc(-c3cc(-c4ccccc4)nc(-c4ccccc4)c3)n2)cc1 ; c1ccc(-c2ccc3c(c2)c2cc(-c4ccccc4)ccc2n3-c2cccc(-c3cc(-c4ccccc4)nc(-c4ccccc4)n3)n2)cc1]

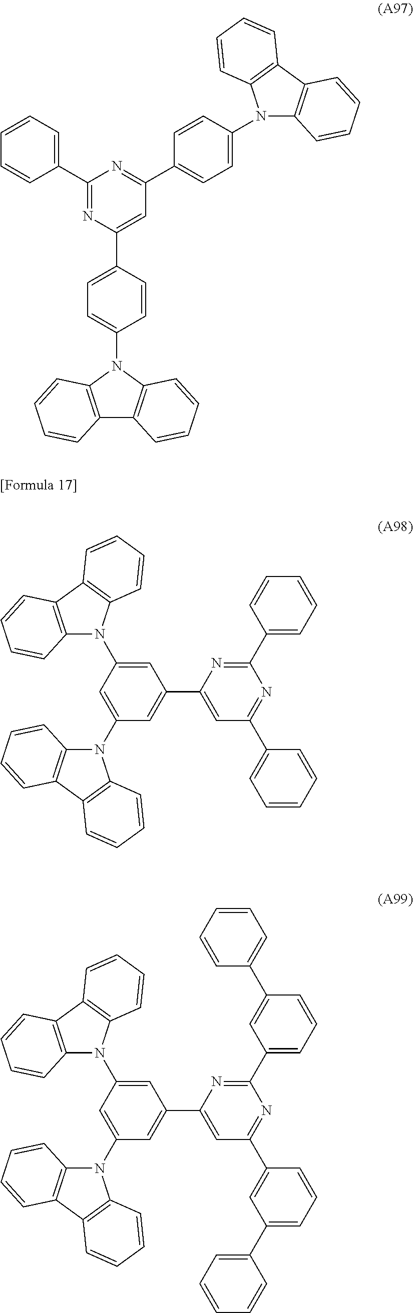 [SMILES: c1ccc(-c2nc(-c3ccc(-n4c5ccccc5c5ccccc54)cc3)cc(-c3ccc(-n4c5ccccc5c5ccccc54)cc3)n2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cccc(-c3cc(-c4cc(-n5c6ccccc6c6ccccc65)cc(-n5c6ccccc6c6ccccc65)c4)nc(-c4cccc(-c5ccccc5)c4)n3)c2)cc1]

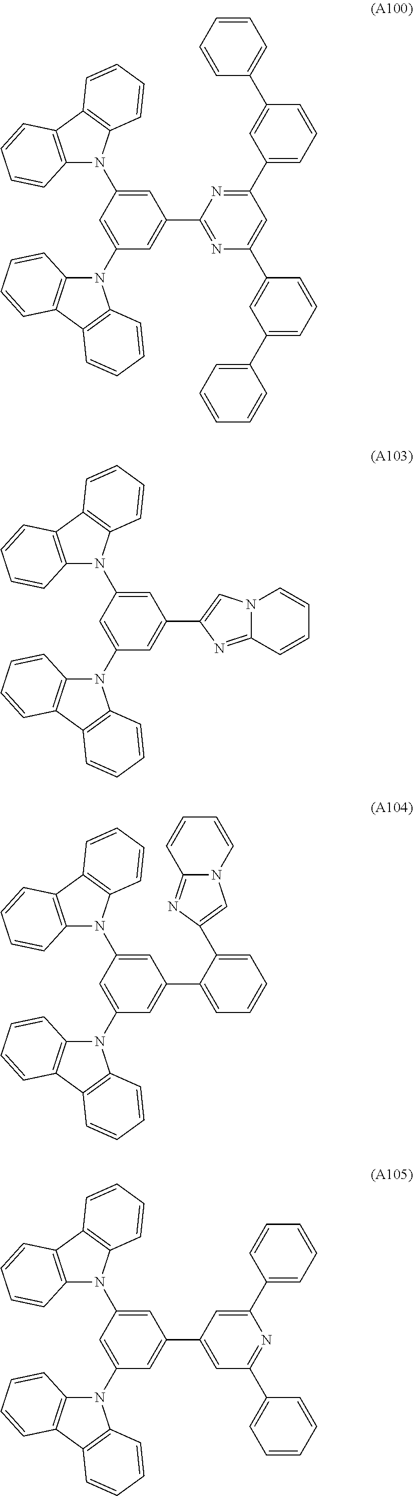

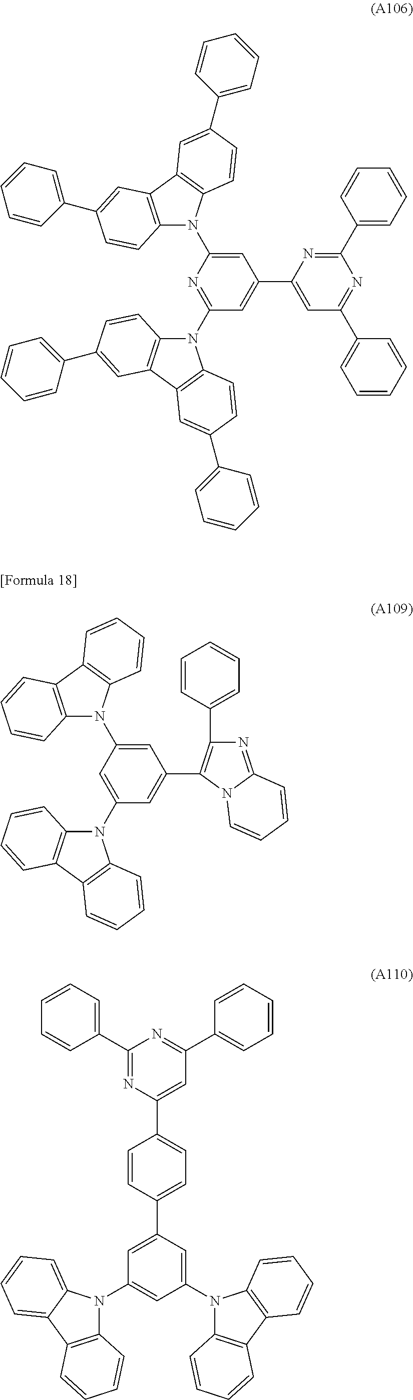 [SMILES: c1ccc(-c2ccc3c(c2)c2cc(-c4ccccc4)ccc2n3-c2cc(-c3cc(-c4ccccc4)nc(-c4ccccc4)n3)cc(-n3c4ccc(-c5ccccc5)cc4c4cc(-c5ccccc5)ccc43)n2)cc1 ; c1ccc(-c2nc3ccccn3c2-c2cc(-n3c4ccccc4c4ccccc43)cc(-n3c4ccccc4c4ccccc43)c2)cc1 ; c1ccc(-c2cc(-c3ccc(-c4cc(-n5c6ccccc6c6ccccc65)cc(-n5c6ccccc6c6ccccc65)c4)cc3)nc(-c3ccccc3)n2)cc1]

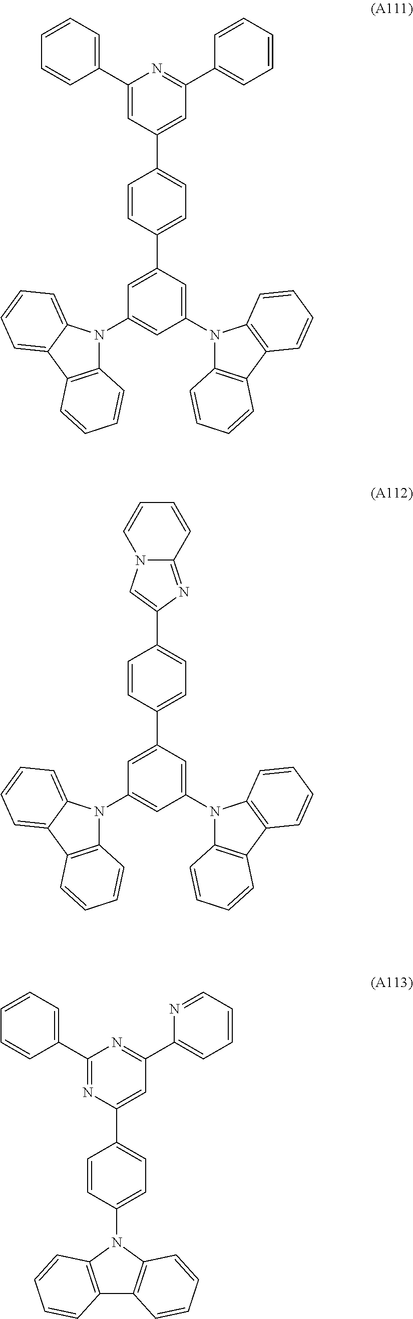 [SMILES: c1ccc(-c2cc(-c3ccc(-c4cc(-n5c6ccccc6c6ccccc65)cc(-n5c6ccccc6c6ccccc65)c4)cc3)cc(-c3ccccc3)n2)cc1 ; c1ccc2c(c1)c1ccccc1n2-c1cc(-c2ccc(-c3cn4ccccc4n3)cc2)cc(-n2c3ccccc3c3ccccc32)c1 ; c1ccc(-c2nc(-c3ccc(-n4c5ccccc5c5ccccc54)cc3)cc(-c3ccccn3)n2)cc1]

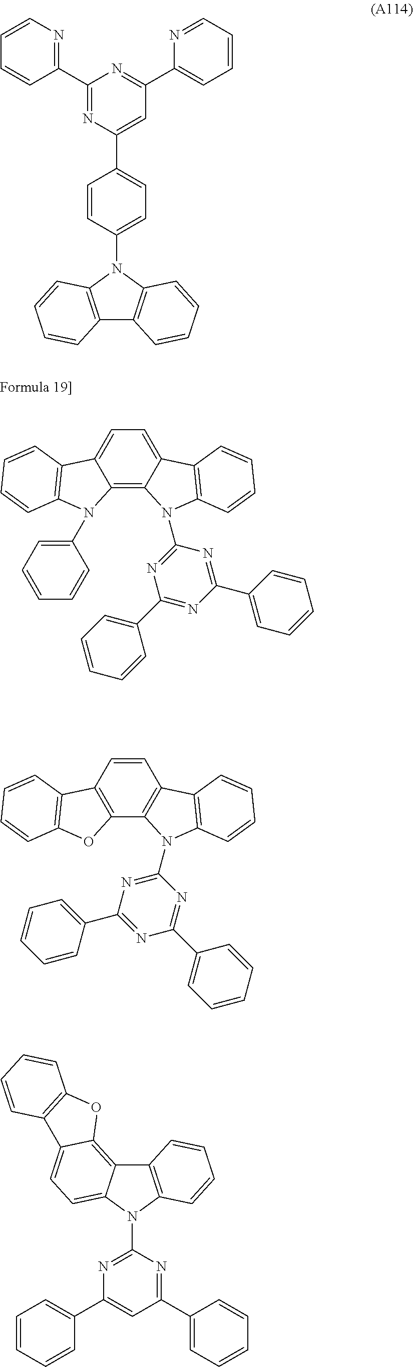 [SMILES: c1ccc(-c2cc(-c3ccc(-n4c5ccccc5c5ccccc54)cc3)nc(-c3ccccn3)n2)nc1 ; c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c6ccccc6oc5c43)n2)cc1 ; c1ccc(-c2cc(-c3ccccc3)nc(-n3c4ccccc4c4c5oc6ccccc6c5ccc43)n2)cc1]

Although depending on a combination of the hole transporting material, later-described second host material and phosphorescent dopant material, the first host material preferably has the ionization potential Ip(h1) in a range of 5.5 eV to 6.2 eV, more preferably in a range of 5.7 eV to 6.1 eV.

### Second Host Material

As the second host material used for the organic EL device in this exemplary embodiment, a compound represented by a formula (2) below is preferably used.

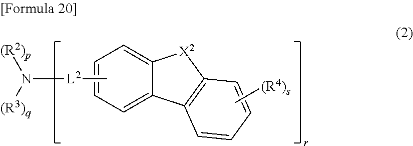

In the formula (2), X² represents a sulfur atom, oxygen atom or N—R⁵.

L² is a single bond or a linking group and represents the same as Y¹ in the formula (1).

R² to R³ each independently represent a substituted or unsubstituted aromatic hydrocarbon group having 6 to 30 ring carbon atoms, and a substituted or unsubstituted aromatic heterocyclic group having 2 to 30 ring carbon atoms.

R⁴ to R⁵ represent the same as R¹¹ and R³¹ in the formulae (1-1) and (1-2).

p and q represent an integer in a range of 0 to 2 and r is an integer in a range of 1 to 3, provided that p+q+r=3.

s represents an integer of 1 to 4. When s is an integer of 2 to 4, a plurality of R⁴ may be the same or different.

When r is an integer of 2 to 3, a plurality of X² may be the same or different and a plurality of L² may be the same or different.

When p is 2, a plurality of R² may be the same or different. When q is 2, a plurality of R³ may be the same or different.

In the formula (2), the alkyl group, alkoxy group, haloalkyl group, haloalkoxy group and alkylsilyl group, which are represented by R² to R⁵, may be linear, branched or cyclic.

In the formula (2), examples of the alkyl group having 1 to 20 carbon atoms, alkoxy group having 1 to 20 carbon atoms, haloalkyl group having 1 to 20 carbon atoms, haloalkoxy group having 1 to 20 carbon atoms, alkylsilyl group having 1 to 10 carbon atoms, arylsilyl group having 6 to 30 carbon atoms, aromatic hydrocarbon group having 6 to 30 ring carbon atoms, fused aromatic hydrocarbon group having 6 to 30 ring carbon atoms, aromatic heterocyclic group having 2 to 30 ring carbon atoms and fused aromatic heterocyclic group having 2 to 30 ring carbon atoms are the same as those in the formula (1).

When L², X², R² to R⁵ in the formula (2) has a substituent or a plurality of substituents, the substituent(s) is the same as those in the formula (1).

Examples of the compound represented by the formula (2) are as follows.

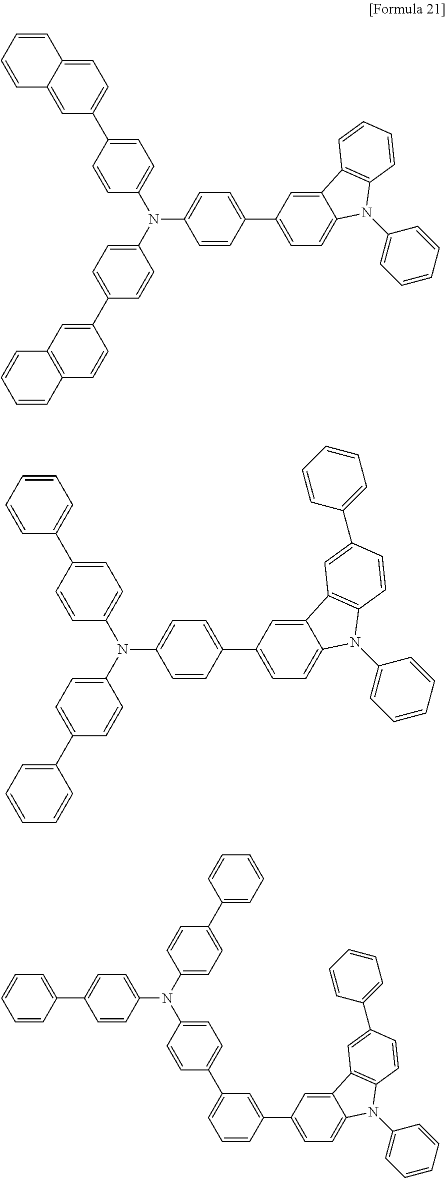 [SMILES: c1ccc(-n2c3ccccc3c3cc(-c4ccc(N(c5ccc(-c6ccc7ccccc7c6)cc5)c5ccc(-c6ccc7ccccc7c6)cc5)cc4)ccc32)cc1 ; c1ccc(-c2ccc(N(c3ccc(-c4ccccc4)cc3)c3ccc(-c4ccc5c(c4)c4cc(-c6ccccc6)ccc4n5-c4ccccc4)cc3)cc2)cc1 ; c1ccc(-c2ccc(N(c3ccc(-c4ccccc4)cc3)c3ccc(-c4cccc(-c5ccc6c(c5)c5cc(-c7ccccc7)ccc5n6-c5ccccc5)c4)cc3)cc2)cc1]

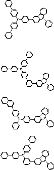 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(-c2ccc(N(c3ccc(-c4ccccc4)cc3)c3ccc(-c4cccc(-c5ccc6c(c5)c5ccccc5n6-c5ccccc5)c4)cc3)cc2)cc1 ; c1ccc(N(c2ccc(-c3ccc4ccccc4c3)cc2)c2ccc(-c3ccc4c(c3)c3ccccc3n4-c3ccccc3)cc2)cc1 ; c1ccc(-c2ccc(N(c3ccc(-c4ccccc4)cc3)c3cccc(-c4ccc5c(c4)c4ccccc4n5-c4ccccc4)c3)cc2)cc1]

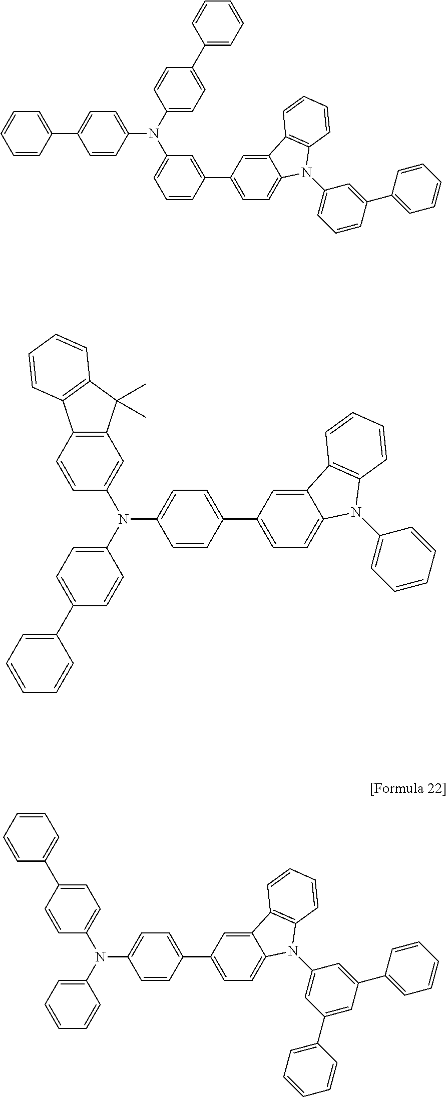 [SMILES: c1ccc(-c2ccc(N(c3ccc(-c4ccccc4)cc3)c3cccc(-c4ccc5c(c4)c4ccccc4n5-c4cccc(-c5ccccc5)c4)c3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccccc3)c3ccc(-c4ccc5c(c4)c4ccccc4n5-c4cc(-c5ccccc5)cc(-c5ccccc5)c4)cc3)cc2)cc1]

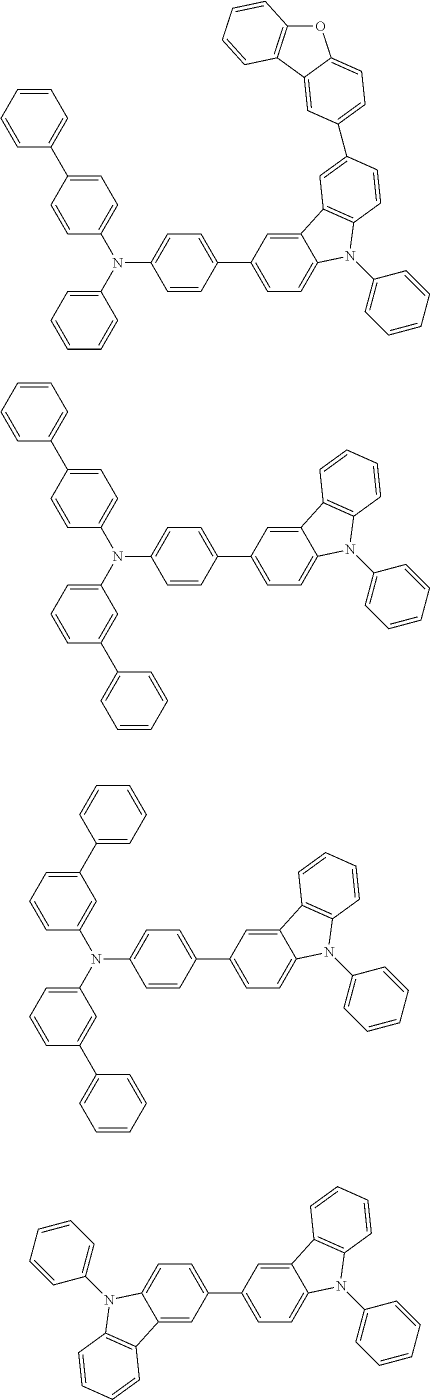

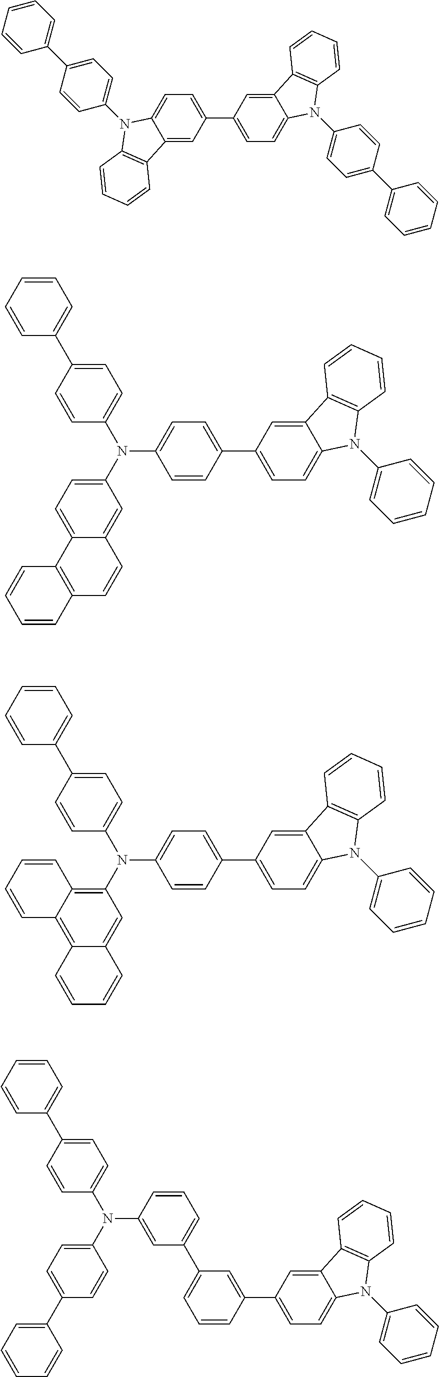 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(N(c3ccc(-c4ccc5c(c4)c4ccccc4n5-c4ccccc4)cc3)c3ccc4c(ccc5ccccc54)c3)cc2)cc1 ; c1ccc(-c2ccc(N(c3ccc(-c4ccc5c(c4)c4ccccc4n5-c4ccccc4)cc3)c3cc4ccccc4c4ccccc34)cc2)cc1 ; c1ccc(-c2ccc(N(c3ccc(-c4ccccc4)cc3)c3cccc(-c4cccc(-c5ccc6c(c5)c5ccccc5n6-c5ccccc5)c4)c3)cc2)cc1]

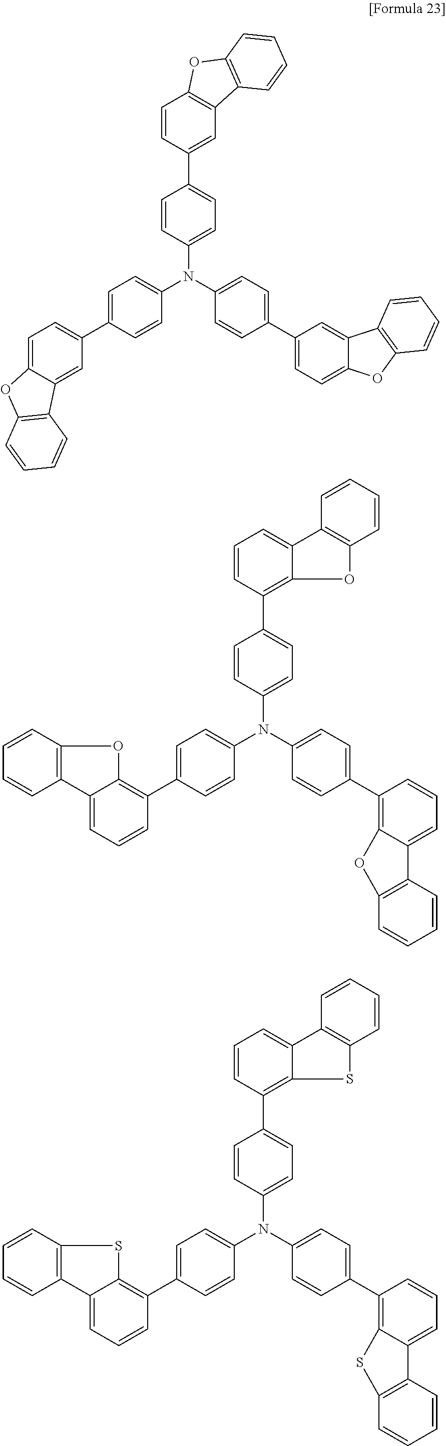 [SMILES: c1ccc2c(c1)oc1ccc(-c3ccc(N(c4ccc(-c5ccc6oc7ccccc7c6c5)cc4)c4ccc(-c5ccc6oc7ccccc7c6c5)cc4)cc3)cc12 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc2c(c1)sc1c(-c3ccc(N(c4ccc(-c5cccc6c5sc5ccccc56)cc4)c4ccc(-c5cccc6c5sc5ccccc56)cc4)cc3)cccc12]

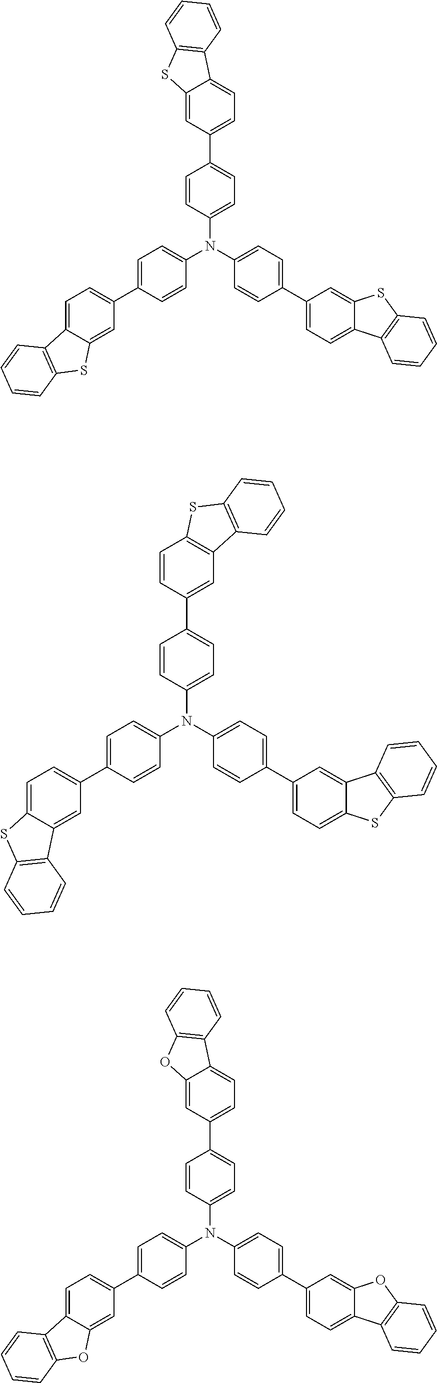 [SMILES: c1ccc2c(c1)sc1cc(-c3ccc(N(c4ccc(-c5ccc6c(c5)sc5ccccc56)cc4)c4ccc(-c5ccc6c(c5)sc5ccccc56)cc4)cc3)ccc12 ; c1ccc2c(c1)sc1ccc(-c3ccc(N(c4ccc(-c5ccc6sc7ccccc7c6c5)cc4)c4ccc(-c5ccc6sc7ccccc7c6c5)cc4)cc3)cc12 ; c1ccc2c(c1)oc1cc(-c3ccc(N(c4ccc(-c5ccc6c(c5)oc5ccccc56)cc4)c4ccc(-c5ccc6c(c5)oc5ccccc56)cc4)cc3)ccc12]

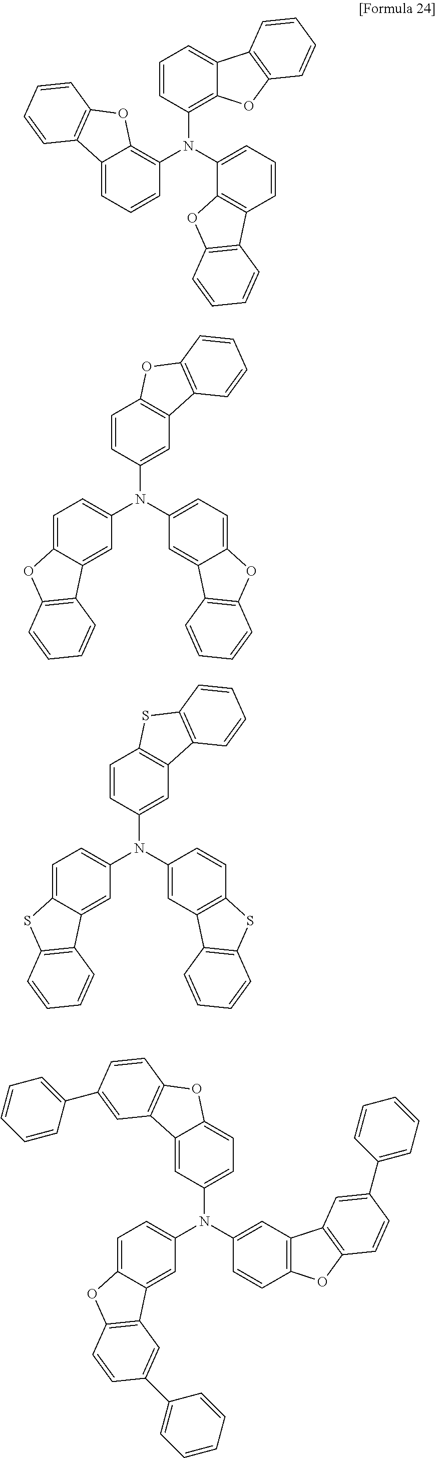

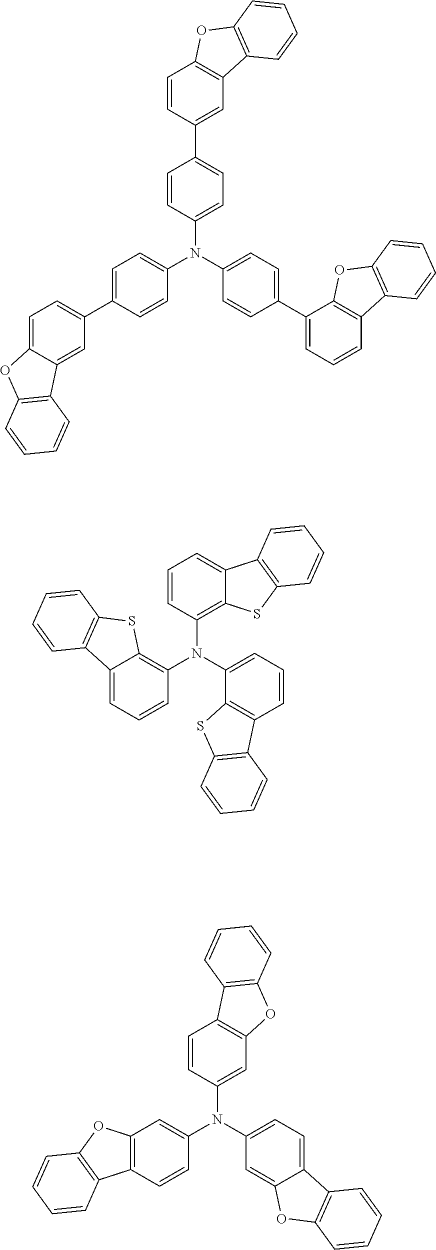 [SMILES: c1ccc2c(c1)oc1ccc(-c3ccc(N(c4ccc(-c5ccc6oc7ccccc7c6c5)cc4)c4ccc(-c5cccc6c5oc5ccccc56)cc4)cc3)cc12 ; c1ccc2c(c1)sc1c(N(c3cccc4c3sc3ccccc34)c3cccc4c3sc3ccccc34)cccc12 ; c1ccc2c(c1)oc1cc(N(c3ccc4c(c3)oc3ccccc34)c3ccc4c(c3)oc3ccccc34)ccc12]

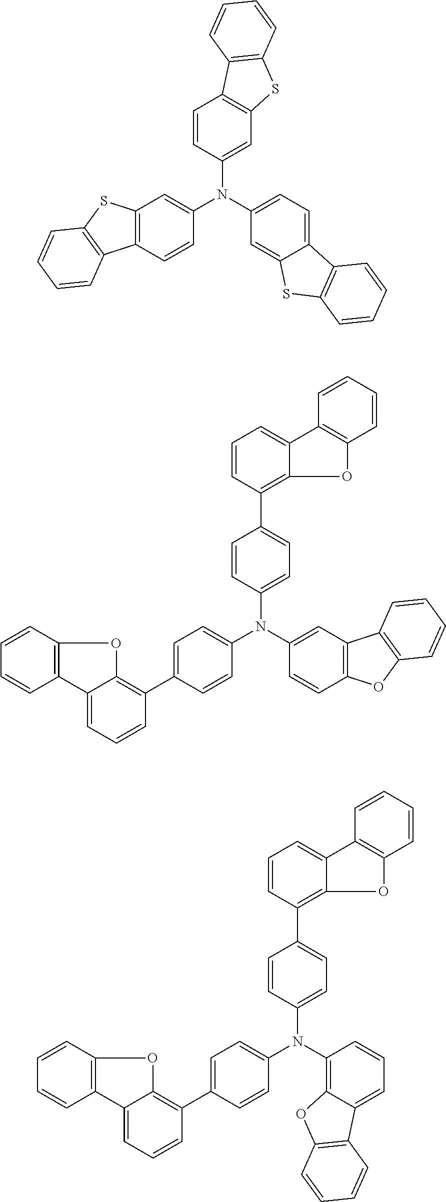 [SMILES: c1ccc2c(c1)sc1cc(N(c3ccc4c(c3)sc3ccccc34)c3ccc4c(c3)sc3ccccc34)ccc12 ; c1ccc2c(c1)oc1ccc(N(c3ccc(-c4cccc5c4oc4ccccc45)cc3)c3ccc(-c4cccc5c4oc4ccccc45)cc3)cc12 ; c1ccc2c(c1)oc1c(-c3ccc(N(c4ccc(-c5cccc6c5oc5ccccc56)cc4)c4cccc5c4oc4ccccc45)cc3)cccc12]

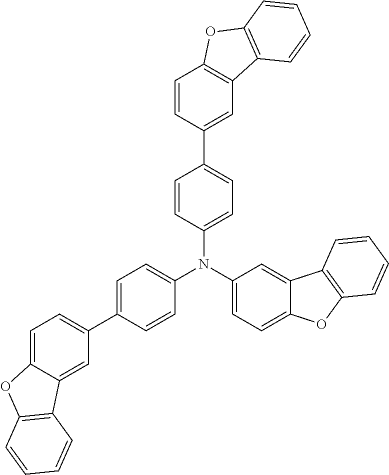 [SMILES: c1ccc2c(c1)oc1ccc(-c3ccc(N(c4ccc(-c5ccc6oc7ccccc7c6c5)cc4)c4ccc5oc6ccccc6c5c4)cc3)cc12]

Although depending on a combination of the hole transporting material, the host material and a later-described phosphorescent dopant material, the second host material preferably has the ionization potential Ip(h2) in a range of 5.3 eV to 5.7 eV, more preferably in a range of 5.4 eV to 5.6 eV.

### Phosphorescent Dopant Material

The phosphorescent dopant material preferably contains a metal complex, and the metal complex preferably has a metal atom selected from Jr (iridium), Pt (platinum), Os (osmium), Au (gold), Cu (copper), Re (rhenium) and Ru (ruthenium), and a ligand.

Particularly, the ligand preferably has an ortho-metal bond.

The phosphorescent dopant material is preferably a compound containing a metal atom selected from Ir, Os, and Pt because such a compound, which exhibits high phosphorescence quantum yield, can further enhance an external quantum efficiency of the organic EL device. The phosphorescent dopant material is more preferably a metal complex such as an iridium complex, an osmium complex or a platinum complex, among which an iridium complex and a platinum complex are more preferable and ortho metalation of an iridium complex is the most preferable. The organic metal complex formed of the ligand selected from the group consisting of phenyl quinoline, phenyl isoquinoline, phenyl pyridine, phenyl pyrimidine and phenyl imidazoles is preferable in terms of the luminous efficiency and the like.

Examples of such a preferable metal complex are shown below.

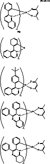

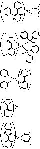

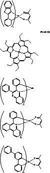

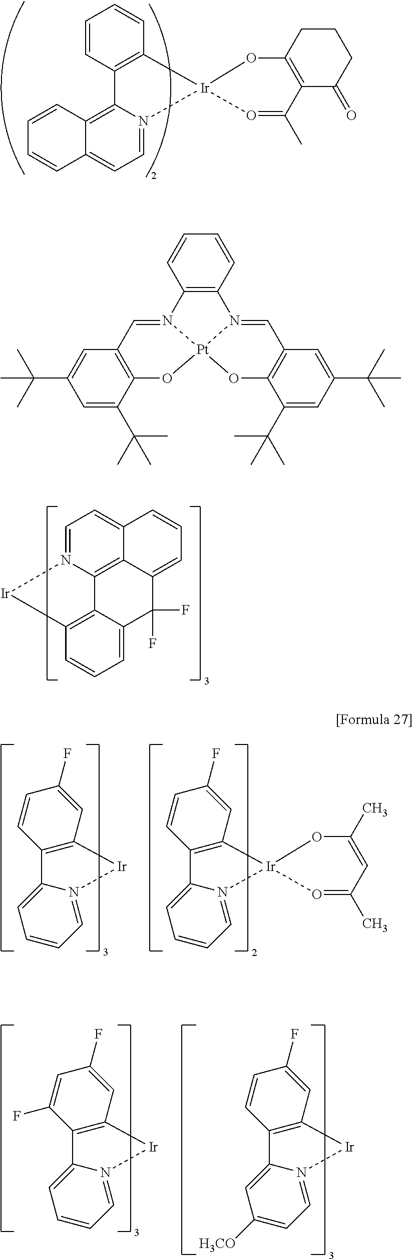

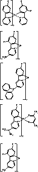

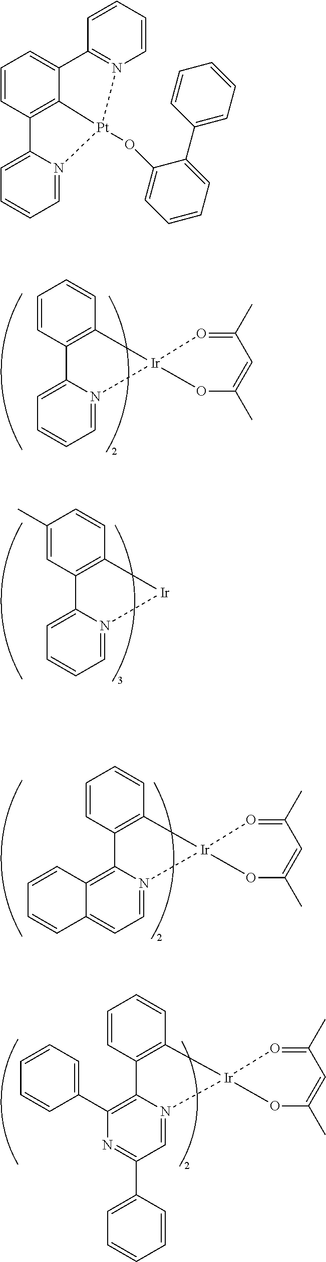

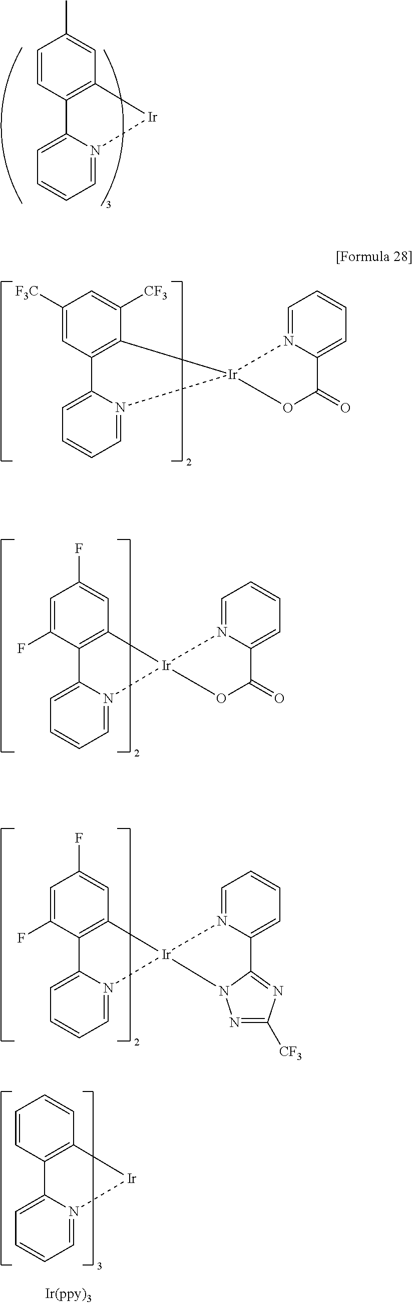

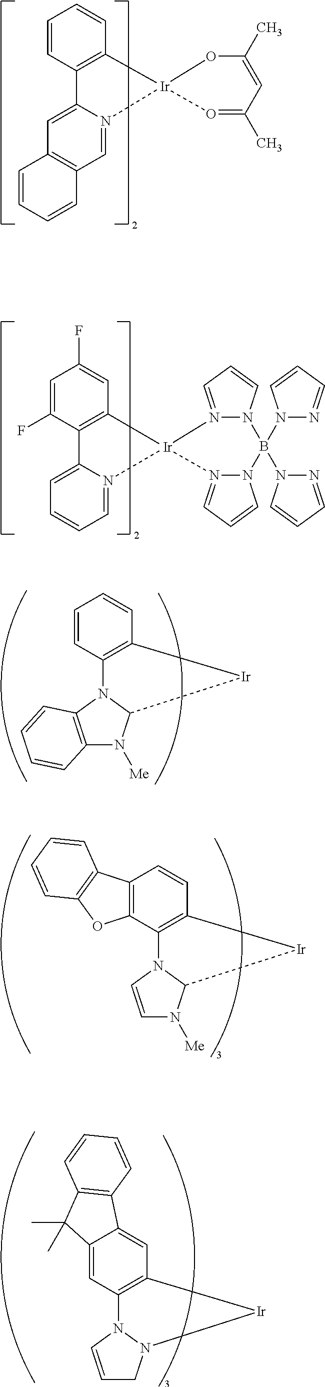

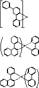

One of the phosphorescent dopant material may be used alone, or two or more thereof may be used in combination.

At least one phosphorescent dopant material contained in the emitting layer 5 preferably has a peak emission wavelength of 500 nm to 650 nm, more preferably of 510 nm to 630 nm. In the exemplary embodiment, green is preferable as an emission color. Although the peak emission wavelength providing green emission is from 495 mm to 570 um, an emission wavelength of 510 nm to 570 nm is preferable in the exemplary embodiment.

By doping the phosphorescent dopant material having such an emission wavelength to the specific first and second host materials to form the emitting layer 5, the organic EL device can exhibit a high efficiency.

### Relationship Between Ionization Potentials of Materials in Emitting Layer

In the exemplary embodiment, the ionization potential Ip(h1) of the first host material, ionization potential Ip(h2) of the second host material and ionization potential IP(d) of the phosphorescent dopant material preferably satisfy the following relationship.

Ip(h1)>Ip(h2)>Ip(d) (Numerical Formula 1)

The ionization potential (Ip) is measured by a later-described measurement method.

Typically, in the emitting layer 5, when an energy barrier (i.e., ionization potential Ip(h1)) of the first host material represented by the formula (1) is large, holes are not directly injected to HOMO of the first host material while the holes are injected to HOMO of the phosphorescent dopant material having a smaller energy barrier than the first host material. However, when the second host material represented by the formula (2) and having the ionization potential Ip(h2) satisfying the numerical formula 1 is contained in the emitting layer 5, the holes are injected to HOMO of the second host material in addition to the phosphorescent dopant material.

Herein, in order to enhance a hole injection efficiency to the first host material, it is conceivable to increase a concentration of the phosphorescent dopant material. However, when the concentration of the phosphorescent dopant material is increased, a luminous efficiency is decreased due to concentration quenching. Moreover, since a large amount of the phosphorescent dopant material, which is generally expensive, is required, the production costs are increased. When the concentration of the phosphorescent dopant material is decreased, the holes in the emitting layer become insufficient, so that recombination of the holes and the electrons is localized at an adjacent interface of the hole transporting layer to shorten lifetime.

However, in the exemplary embodiment, since the second host material represented by the formula (2) is added, the hole injection efficiency to the emitting layer 5 can be maintained while the concentration of the phosphorescent dopant material is decreased to reduce the production cost. Moreover, since the concentration of the phosphorescent dopant material can be kept low, occurrence of concentration quenching can be inhibited. Further, since a carrier balance in the emitting layer can be improved, the recombination of the holes and the electrons can be spread over the entire emitting layer 5. Thus, in the organic EL device 1, while the initial performance such as drive voltage is maintained, the luminous efficiency and the lifetime can be improved.

### Substrate

The organic EL device 1 is formed by laminating the anode 3, the emitting layer 5, the cathode 4 and the like on the light-transmissive substrate 2. The substrate 2, which supports the anode 3 and the like, is preferably a smoothly-shaped substrate that transmits 50% or more of light in a visible region of 400 nm to 700 nm.

The light-transmissive substrate 2 is exemplified by a glass plate and a polymer plate.

For the glass plate, materials such as soda-lime glass, barium/strontium-containing glass, lead glass, aluminosilicate glass, borosilicate glass, barium borosilicate glass and quartz can be used.

For the polymer plate, materials such as polycarbonate, acryl, polyethylene terephthalate, polyether sulfide and polysulfone can be used.

### Anode and Cathode

The anode 3 of the organic EL device 1 is used for injecting holes into the hole injecting layer, the hole transporting layer 6 or the emitting layer 5. It is effective that the anode 3 has a work function of 4.5 eV or more.

Exemplary materials for the anode are alloys of indium-tin oxide (ITO), tin oxide (NESA), indium zinc oxide, gold, silver, platinum and copper.

The anode 3 can be manufactured by forming a thin film from these anode materials, for instance, on the substrate 2 through methods such as vapor deposition and sputtering.

When light from the emitting layer 5 is to be emitted through the anode 3, the anode 3 preferably transmits more than 10% of the light in the visible region. Sheet resistance of the anode 3 is preferably several hundreds Ω/square or lower. Although depending on the material of the anode 3, thickness of the anode is typically in a range of 10 nm to 1 μm, and preferably in a range of 10 nm to 200 nm.

The cathode is preferably formed of a material with smaller work function in order to inject electrons into the emitting layer.

Although the material for the cathode is subject to no specific limitation, examples of the material are indium, aluminum, magnesium, alloy of magnesium and indium, alloy of magnesium and aluminum, alloy of aluminum and lithium, alloy of aluminum, scandium and lithium, alloy of magnesium and silver and the like.

Like the anode 3, the cathode 4 may be made, for instance, on the electron transporting layer 7 by forming a thin film through a method such as vapor deposition or sputtering. In addition, the light from the emitting layer 5 may be extracted through the cathode 4. When light from the emitting layer 5 is extracted through the cathode 4, the cathode 4 preferably transmits more than 10% of the light in the visible region.

Sheet resistance of the cathode is preferably several hundreds Ω/sq. or lower.

Although depending on the material of the cathode, a thickness of the cathode is typically in a range from 10 nm to 1 μm, preferably in a range from 50 to 200 nm.

### Other Layers

In order to further increase a current efficiency (or luminous efficiency), the hole injecting layer, hole transporting layer, electron injecting layer and the like may be provided as needed. The organic EL device 1 is provided with the hole transporting layer 6 and the electron transporting layer 7.

In order to enhance hole injectability to the emitting layer, a difference Δ Ip(EML−HT) between an ionization potential Ip(HT) of an adjacent layer (e.g., hole injecting layer and hole transporting layer) which is provided adjacent to the emitting layer 5 near the anode and an ionization potential Ip(EML) of the emitting layer 5 preferably satisfies the following relationship. The smaller difference ΔIp(EML−HT) is better.

0.1 eV≦ΔIp(EML−HT)≦0.5 eV

Herein, a difference between Ip(HT) and an ionization potential Ip(EML2) of the emitting layer including the first host material and the phosphorescent dopant material and not including the second host material is defined by ΔIp(EML2−HT). It is more preferable that a ratio of difference between ΔIp(EML2−HT) and ΔIp(EML−HT) relative to ΔIp(EML−HT) satisfies the following relationship represented by the numerical formula 2.

{ΔIp(EML2−HT)-ΔIp(EML−HT)}×100/ΔIp(EML−HT)≧10 (Numerical Formula 2)

The ionization potential Ip(EML) of the emitting layer 5 is calculated according to the following numerical formula 3 based on the ionization potential Ip(h1) of the first host material, the ionization potential Ip(h2) of the second host material, the ionization potential Ip(d) of the phosphorescent dopant material and the concentration (mass %) of each of the first host material, the second host material and the phosphorescent dopant material in the emitting layer.

Ip(EML)=Ip(h1)×Q(h1)/100+Ip(H2)×Q(h2)/100+Ip(d)×Q(d)/100 (Numerical Formula 3)

In the formula, Q(h1) represents a concentration (mass %) of the first host material, Q(h2) represents a concentration (mass %) of the second host material, and Q(d) represents a concentration (mass %) of the phosphorescent dopant material.

### Hole Transporting Layer

The hole transporting layer 6 helps injection of holes to the emitting layer and transport the holes to an emitting region. The hole transporting layer 6 has a large hole mobility and a small ionization potential.

A material for forming the hole transporting layer 6 is preferably a material of transporting the holes to the emitting layer 5 at a lower electric field intensity. The second host material represented by the formula (2) in the exemplary embodiment is usable. Additionally, for instance, an aromatic amine derivative represented by the following formula (A1) is preferably used.

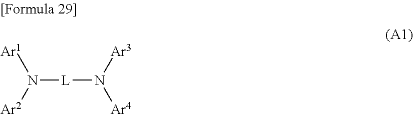

In the formula (A1), Ar¹ to Ar⁴ each represent an aromatic hydrocarbon group having 6 to 50 ring carbon atoms, a fused aromatic hydrocarbon group having 6 to 50 ring carbon atoms, an aromatic heterocyclic group having 2 to 40 ring carbon atoms, a fused aromatic heterocyclic group having 2 to 40 ring carbon atoms, a group provided by bonding the aromatic hydrocarbon group and the aromatic heterocyclic group, a group provided by bonding the aromatic hydrocarbon group and the fused aromatic heterocyclic group, a group provided by bonding the fused aromatic hydrocarbon group and the aromatic heterocyclic group, and a group provided by bonding the fused aromatic hydrocarbon group and the fused aromatic heterocyclic group. Note that the above-described aromatic hydrocarbon group, fused aromatic hydrocarbon group, aromatic heterocyclic group and fused aromatic heterocyclic group may be substituted.

In the formula (A1), L is a linking group and represents a divalent aromatic hydrocarbon group having 6 to 50 ring carbon atoms, a divalent fused aromatic hydrocarbon group having 6 to 50 ring carbon atoms, a divalent aromatic heterocyclic group having 5 to 50 ring carbon atoms, a divalent fused aromatic heterocyclic group having 5 to 50 ring carbon atoms, and a divalent group provided by bonding two or more aromatic hydrocarbon groups or aromatic heterocyclic groups via a single bond, an ether bond, a thioether bond, an alkylene group having 1 to 20 carbon atoms, an alkenylene group having 2 to 20 carbon atoms, or an amino group. Note that the above-described divalent aromatic hydrocarbon group, divalent fused aromatic hydrocarbon group, divalent aromatic heterocyclic group and divalent fused aromatic heterocyclic group may be substituted.

Examples of the compound represented by the formula (A1) are shown below. However, the compound is not limited thereto.

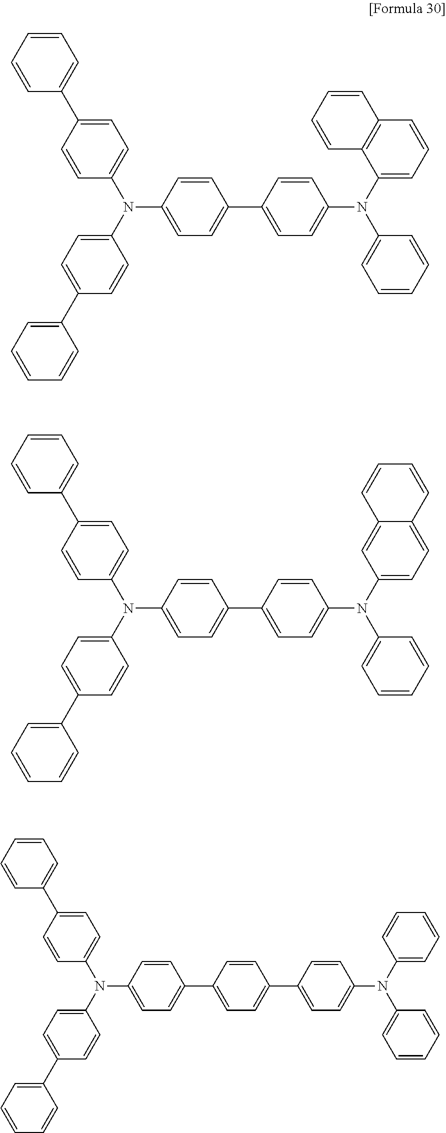 [SMILES: c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(N(c3ccc(-c4ccccc4)cc3)c3ccc(-c4ccc(N(c5ccccc5)c5ccc6ccccc6c5)cc4)cc3)cc2)cc1 ; c1ccc(-c2ccc(N(c3ccc(-c4ccccc4)cc3)c3ccc(-c4ccc(-c5ccc(N(c6ccccc6)c6ccccc6)cc5)cc4)cc3)cc2)cc1]

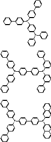 [SMILES: c1ccc(-c2ccc(N(c3ccc(-c4ccccc4)cc3)c3ccc(N(c4ccccc4)c4ccccc4)cc3)cc2)cc1 ; c1ccc(-c2ccc(N(c3ccc(-c4ccccc4)cc3)c3ccc(-c4ccc(N(c5cccc(-c6ccccc6)c5)c5cccc(-c6ccccc6)c5)cc4)cc3)cc2)cc1 ; c1ccc(-c2ccc(N(c3ccc(-c4ccccc4)cc3)c3ccc(-c4ccc(N(c5ccc6ccccc6c5)c5ccc6ccccc6c5)cc4)cc3)cc2)cc1]

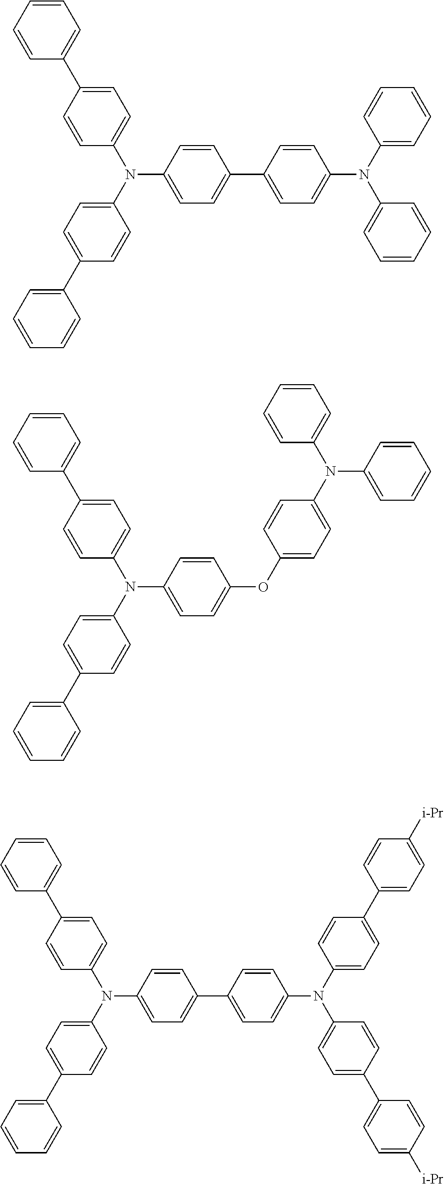 [SMILES: c1ccc(-c2ccc(N(c3ccc(-c4ccccc4)cc3)c3ccc(-c4ccc(N(c5ccccc5)c5ccccc5)cc4)cc3)cc2)cc1 ; c1ccc(-c2ccc(N(c3ccc(Oc4ccc(N(c5ccccc5)c5ccccc5)cc4)cc3)c3ccc(-c4ccccc4)cc3)cc2)cc1 ; CC(C)c1ccc(-c2ccc(N(c3ccc(-c4ccc(C(C)C)cc4)cc3)c3ccc(-c4ccc(N(c5ccc(-c6ccccc6)cc5)c5ccc(-c6ccccc6)cc5)cc4)cc3)cc2)cc1]

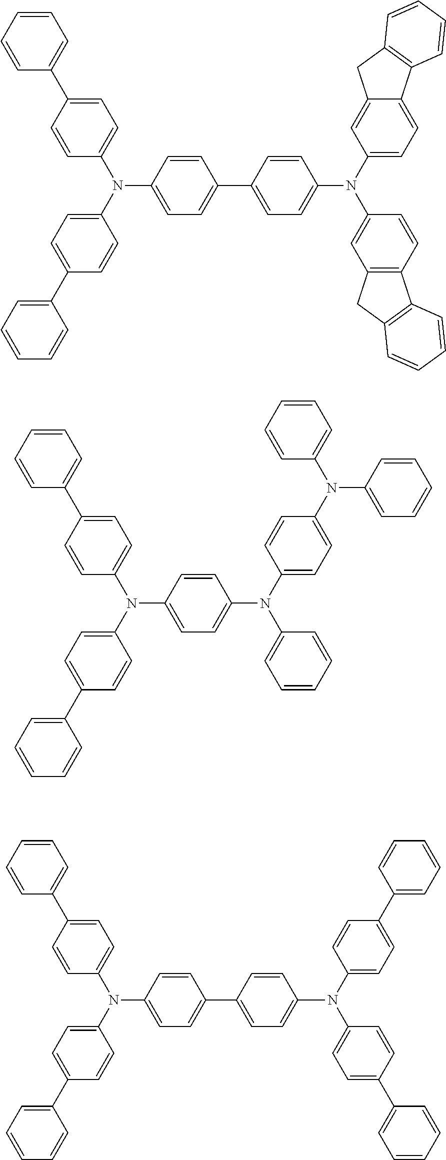 [SMILES: c1ccc(-c2ccc(N(c3ccc(-c4ccccc4)cc3)c3ccc(-c4ccc(N(c5ccc6c(c5)Cc5ccccc5-6)c5ccc6c(c5)Cc5ccccc5-6)cc4)cc3)cc2)cc1 ; c1ccc(-c2ccc(N(c3ccc(-c4ccccc4)cc3)c3ccc(N(c4ccccc4)c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

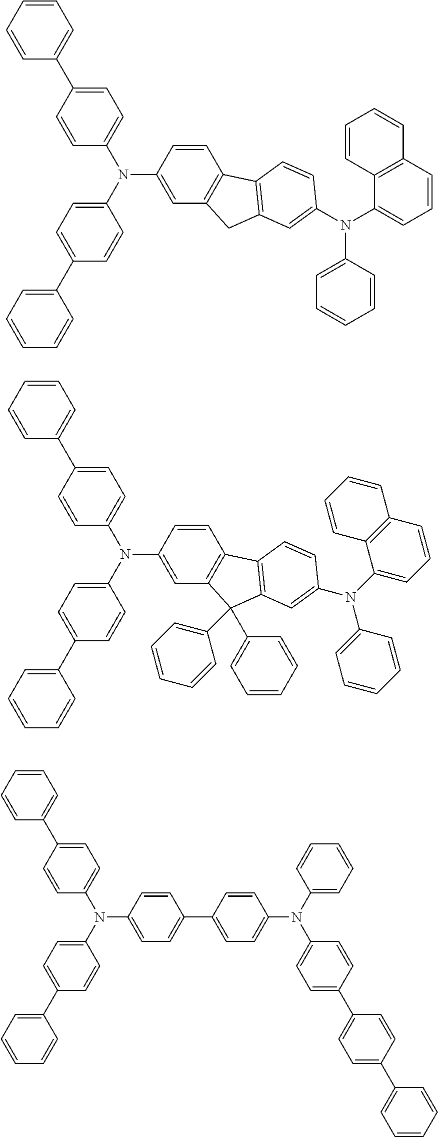

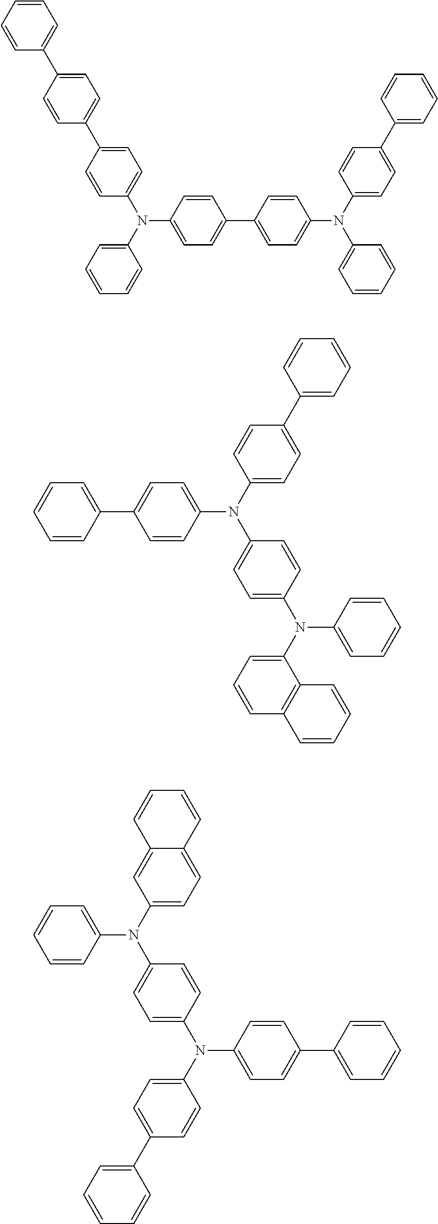 [SMILES: c1ccc(-c2ccc(-c3ccc(N(c4ccccc4)c4ccc(-c5ccc(N(c6ccccc6)c6ccc(-c7ccccc7)cc6)cc5)cc4)cc3)cc2)cc1 ; c1ccc(-c2ccc(N(c3ccc(-c4ccccc4)cc3)c3ccc(N(c4ccccc4)c4cccc5ccccc45)cc3)cc2)cc1 ; c1ccc(-c2ccc(N(c3ccc(-c4ccccc4)cc3)c3ccc(N(c4ccccc4)c4ccc5ccccc5c4)cc3)cc2)cc1]

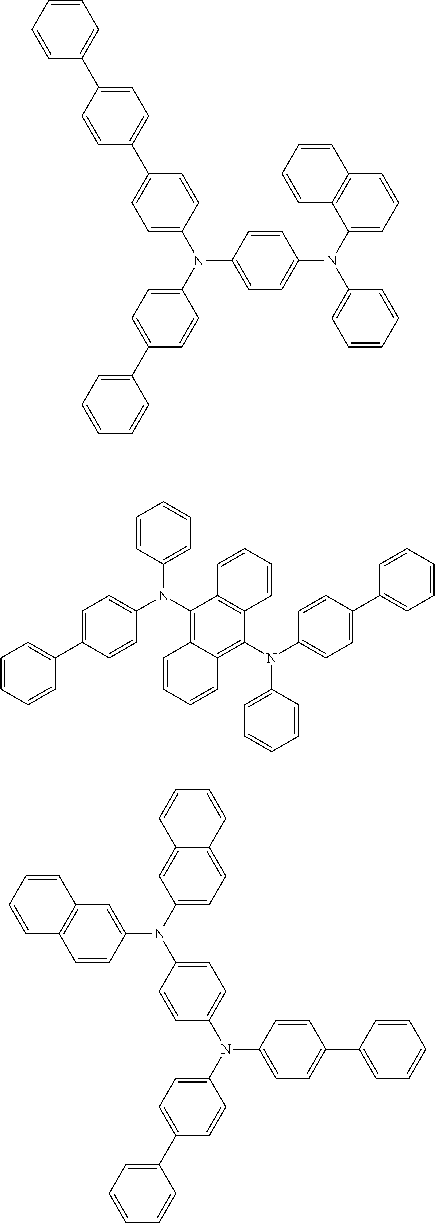 [SMILES: c1ccc(-c2ccc(-c3ccc(N(c4ccc(-c5ccccc5)cc4)c4ccc(N(c5ccccc5)c5cccc6ccccc56)cc4)cc3)cc2)cc1 ; c1ccc(-c2ccc(N(c3ccccc3)c3c4ccccc4c(N(c4ccccc4)c4ccc(-c5ccccc5)cc4)c4ccccc34)cc2)cc1 ; c1ccc(-c2ccc(N(c3ccc(-c4ccccc4)cc3)c3ccc(N(c4ccc5ccccc5c4)c4ccc5ccccc5c4)cc3)cc2)cc1]

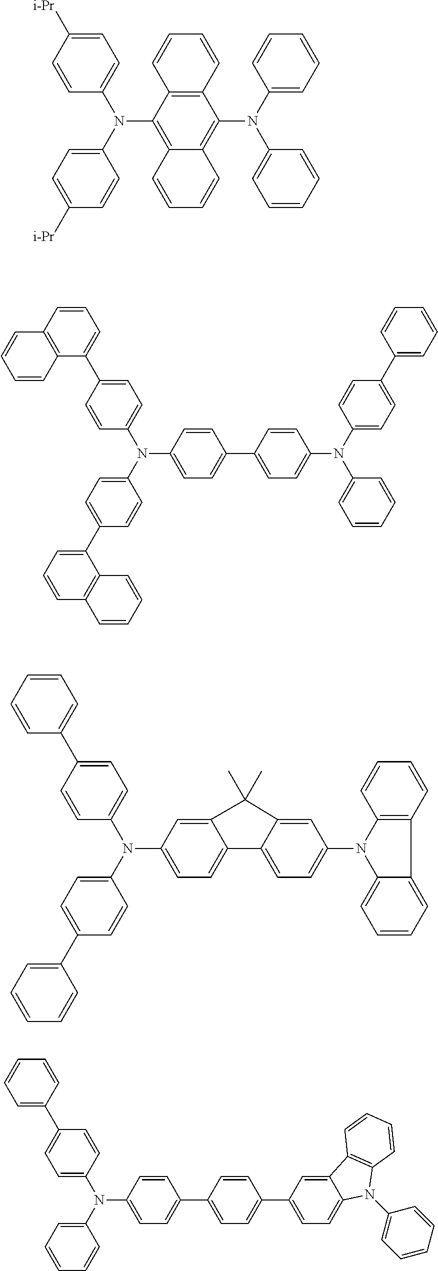

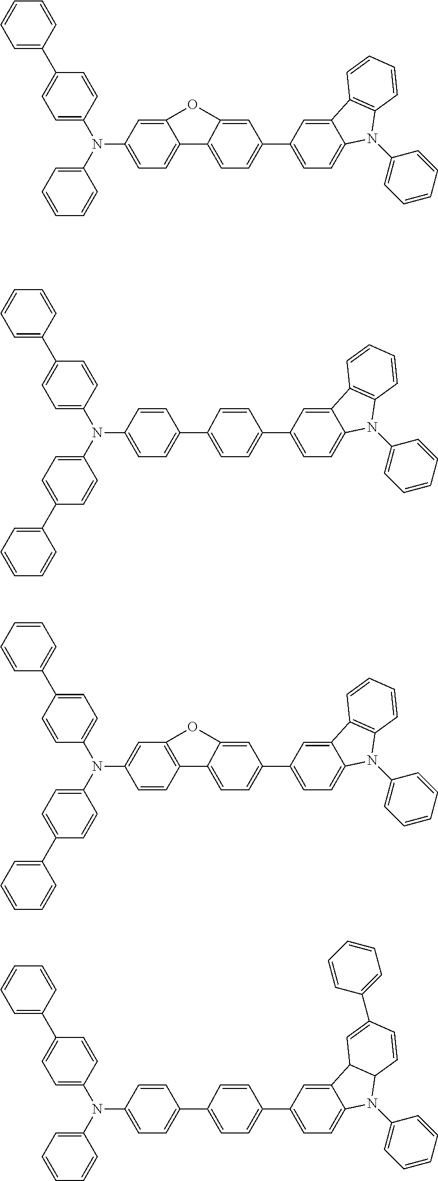 [SMILES: c1ccc(-c2ccc(N(c3ccccc3)c3ccc4c(c3)oc3cc(-c5ccc6c(c5)c5ccccc5n6-c5ccccc5)ccc34)cc2)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; c1ccc(-c2ccc(N(c3ccc(-c4ccccc4)cc3)c3ccc4c(c3)oc3cc(-c5ccc6c(c5)c5ccccc5n6-c5ccccc5)ccc34)cc2)cc1 ; C1=CC2C(C=C1c1ccccc1)c1cc(-c3ccc(-c4ccc(N(c5ccccc5)c5ccc(-c6ccccc6)cc5)cc4)cc3)ccc1N2c1ccccc1]

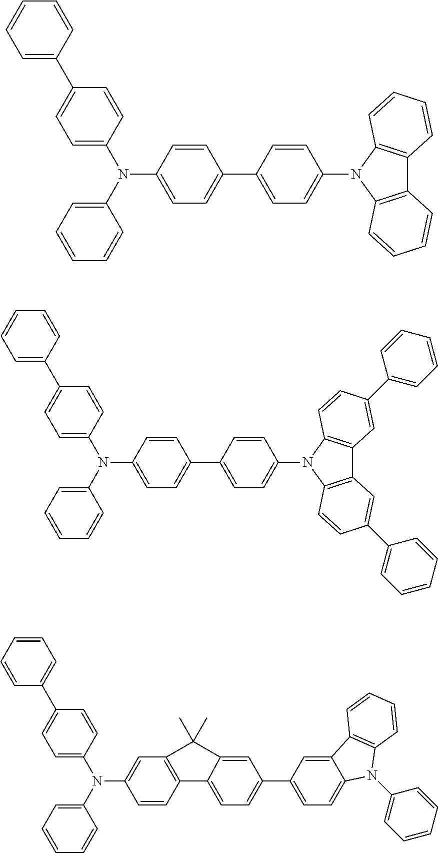 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccccc3)c3ccc(-c4ccc(-n5c6ccc(-c7ccccc7)cc6c6cc(-c7ccccc7)ccc65)cc4)cc3)cc2)cc1 ; CC1(C)c2cc(-c3ccc4c(c3)c3ccccc3n4-c3ccccc3)ccc2-c2ccc(N(c3ccccc3)c3ccc(-c4ccccc4)cc3)cc21]

Aromatic amine represented by the following formula (A2) can also be preferably used for forming the hole transporting layer.

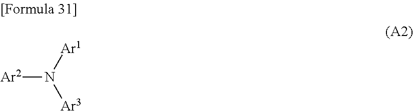

In the above formula (A2), Ar¹ to Ar^{a} each represent the same as Ar¹ to Ar⁴ of the above formula (A1). Examples of the compound represented by the formula (A2) are shown below. However, the compound represented by the formula (A2) is not limited thereto.

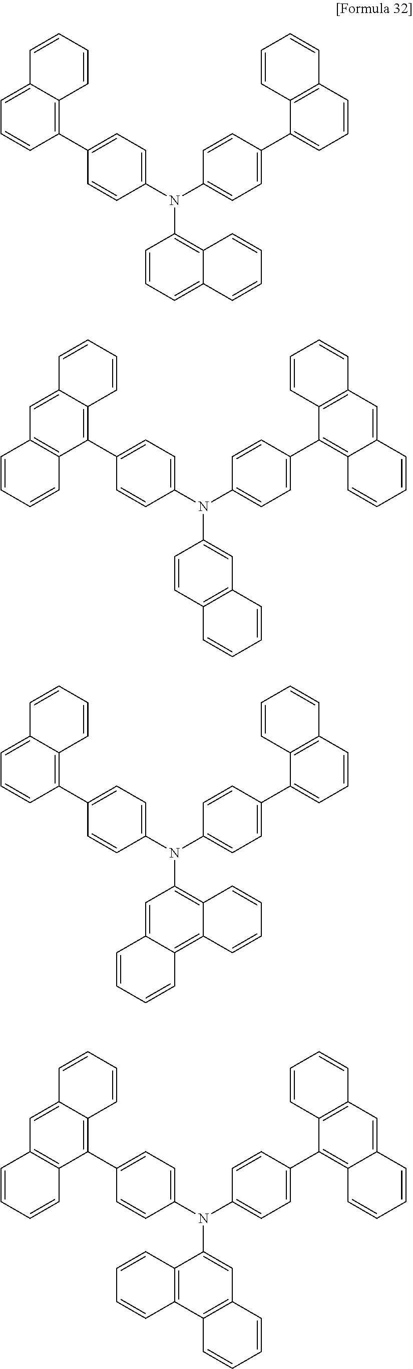 [SMILES: c1ccc2c(-c3ccc(N(c4ccc(-c5cccc6ccccc56)cc4)c4cccc5ccccc45)cc3)cccc2c1 ; c1ccc2cc(N(c3ccc(-c4c5ccccc5cc5ccccc45)cc3)c3ccc(-c4c5ccccc5cc5ccccc45)cc3)ccc2c1 ; c1ccc2c(-c3ccc(N(c4ccc(-c5cccc6ccccc56)cc4)c4cc5ccccc5c5ccccc45)cc3)cccc2c1 ; c1ccc2c(-c3ccc(N(c4ccc(-c5c6ccccc6cc6ccccc56)cc4)c4cc5ccccc5c5ccccc45)cc3)c3ccccc3cc2c1]

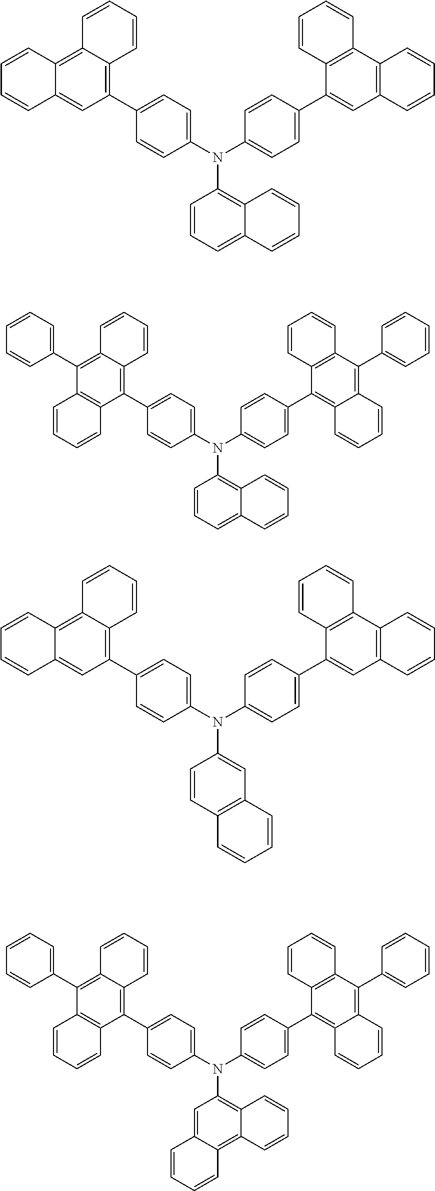 [SMILES: c1ccc2c(N(c3ccc(-c4cc5ccccc5c5ccccc45)cc3)c3ccc(-c4cc5ccccc5c5ccccc45)cc3)cccc2c1 ; c1ccc(-c2c3ccccc3c(-c3ccc(N(c4ccc(-c5c6ccccc6c(-c6ccccc6)c6ccccc56)cc4)c4cccc5ccccc45)cc3)c3ccccc23)cc1 ; c1ccc2cc(N(c3ccc(-c4cc5ccccc5c5ccccc45)cc3)c3ccc(-c4cc5ccccc5c5ccccc45)cc3)ccc2c1 ; c1ccc(-c2c3ccccc3c(-c3ccc(N(c4ccc(-c5c6ccccc6c(-c6ccccc6)c6ccccc56)cc4)c4cc5ccccc5c5ccccc45)cc3)c3ccccc23)cc1]

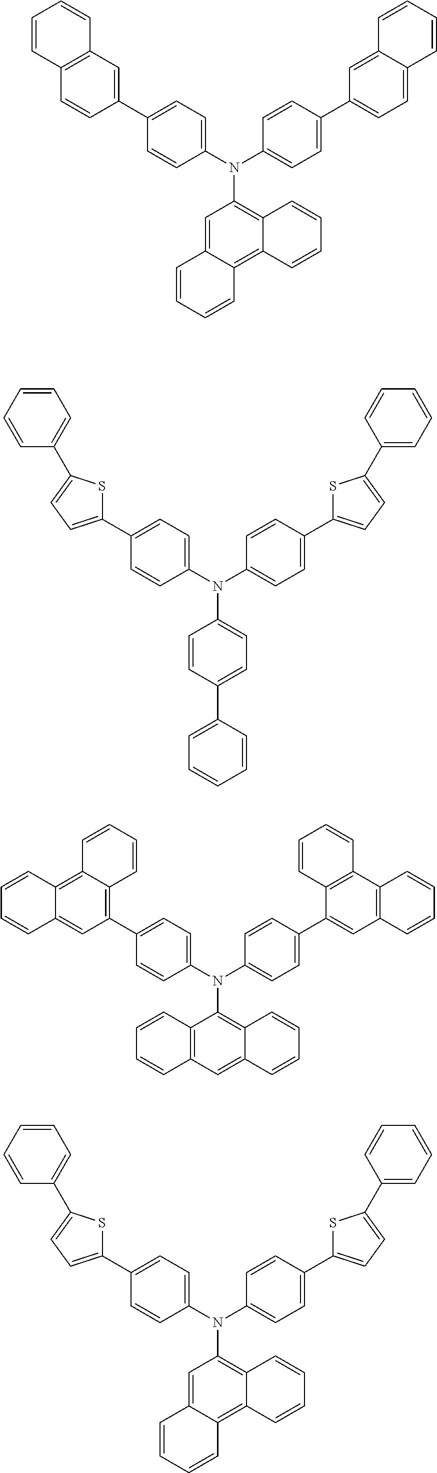 [SMILES: c1ccc2cc(-c3ccc(N(c4ccc(-c5ccc6ccccc6c5)cc4)c4cc5ccccc5c5ccccc45)cc3)ccc2c1 ; c1ccc(-c2ccc(N(c3ccc(-c4ccc(-c5ccccc5)s4)cc3)c3ccc(-c4ccc(-c5ccccc5)s4)cc3)cc2)cc1 ; c1ccc2c(N(c3ccc(-c4cc5ccccc5c5ccccc45)cc3)c3ccc(-c4cc5ccccc5c5ccccc45)cc3)c3ccccc3cc2c1 ; c1ccc(-c2ccc(-c3ccc(N(c4ccc(-c5ccc(-c6ccccc6)s5)cc4)c4cc5ccccc5c5ccccc45)cc3)s2)cc1]

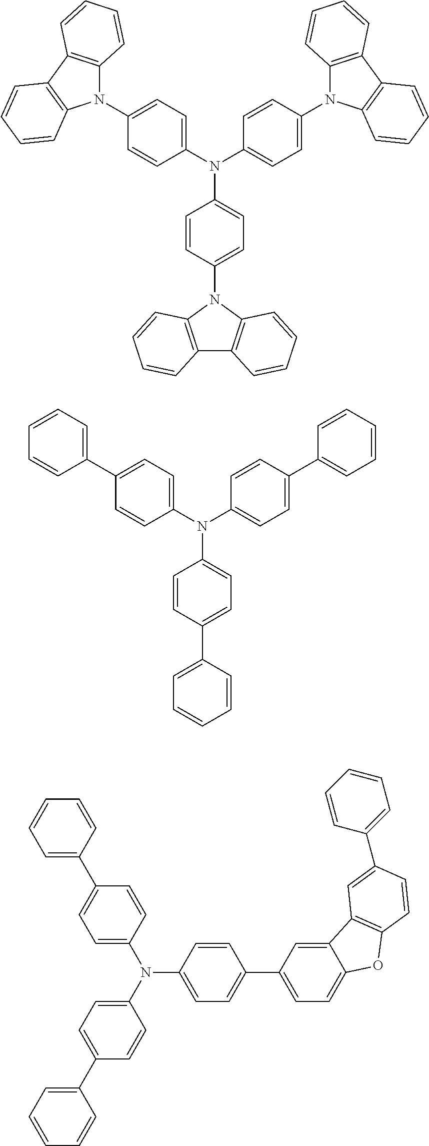 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(-c2ccc(N(c3ccc(-c4ccccc4)cc3)c3ccc(-c4ccccc4)cc3)cc2)cc1 ; c1ccc(-c2ccc(N(c3ccc(-c4ccccc4)cc3)c3ccc(-c4ccc5oc6ccc(-c7ccccc7)cc6c5c4)cc3)cc2)cc1]

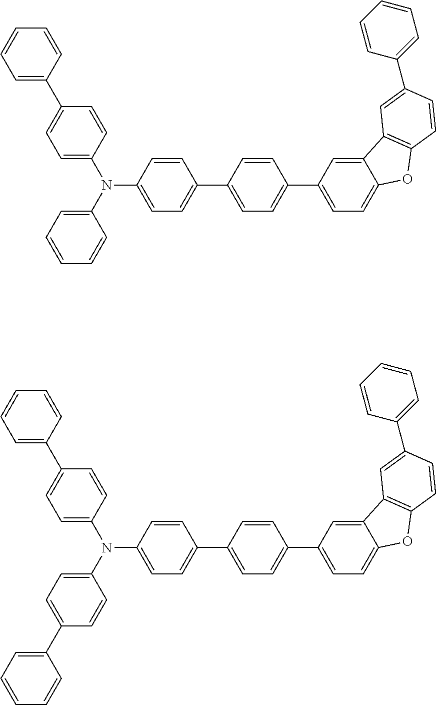 [SMILES: c1ccc(-c2ccc(N(c3ccccc3)c3ccc(-c4ccc(-c5ccc6oc7ccc(-c8ccccc8)cc7c6c5)cc4)cc3)cc2)cc1 ; c1ccc(-c2ccc(N(c3ccc(-c4ccccc4)cc3)c3ccc(-c4ccc(-c5ccc6oc7ccc(-c8ccccc8)cc7c6c5)cc4)cc3)cc2)cc1]

Although depending on a combination of the first host material, the second host material and the phosphorescent dopant material, the hole transporting material preferably has an ionization potential Ip(HT) in a range of 5.3 eV to 5.7 eV.

### Electron Transporting Layer

The electron transporting layer 7, which helps injection of electrons to the emitting layer 5, has a large electron mobility.

In the exemplary embodiment, the electron transporting layer 7 is provided between the emitting layer 5 and the cathode. The electron injecting layer 7 preferably contains a nitrogen-containing cyclic derivative as a main component. The electron injecting layer may serve as the electron transporting layer.

Noted that “as a main component” means that the nitrogen-containing cyclic derivative is contained in the electron injecting layer 7 at a content of 50 mass % or more.

A preferable example of an electron transporting material for forming the electron injecting layer 7 is an aromatic heterocyclic compound having in the molecule at least one heteroatom. Particularly, a nitrogen-containing cyclic derivative is preferable. The nitrogen-containing cyclic derivative is preferably an aromatic ring having a nitrogen-containing six-membered or five-membered ring skeleton, or a condensed aromatic cyclic compound having a nitrogen-containing six-membered or five-membered ring skeleton.

A preferable example of the nitrogen-containing cyclic derivative is a nitrogen-containing cyclic metal chelate complex represented by the following formula (B1).

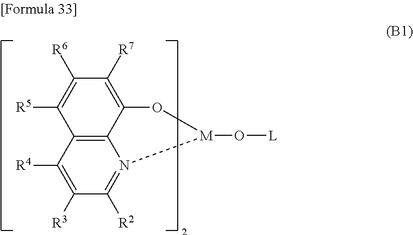

In the formula (B1), R² to R⁷ are independently

a hydrogen atom, a halogen atom, an oxy group, an amino group, a hydrocarbon group having 1 to 40 carbon atoms, an alkoxyl group, an aryloxy group, a alkoxycarbonyl group or an aromatic heterocyclic group, which may be substituted.

Examples of the halogen atom are fluorine, chlorine, bromine and iodine. In addition, examples of the substituted or unsubstituted amino group include an alkylamino group, an arylamino group, and an aralkylamino group.

The alkoxycarbonyl group is represented by —COOY′. Examples of Y′ are the same as the examples of the alkyl group. The alkylamino group and the aralkylamino group are represented by —NQ¹Q². Examples for each of Q¹ and Q² are the same as the examples described in relation to the alkyl group and the aralkyl group (i.e., a group provided by substituting a hydrogen atom of the alkyl group by an aryl group), and preferred examples for each of Q¹ and Q² are also the same as those described in relation to the alkyl group and the aralkyl group. One of Q¹ and Q² may be a hydrogen atom. Note that the aralkyl group is a group provided by substituting a hydrogen atom of the alkyl group by an aryl group.

The arylamino group is represented by —NAr¹Ar². Examples for each of Ar¹ and Ar² are the same as the examples described in relation to the non-fused aromatic hydrocarbon group and the fused aromatic hydrocarbon group. One of Ar¹ and Ar² may be a hydrogen atom.

M represents aluminum (Al), gallium (Ga) or indium (In), among which In is preferable.

L in the formula (B1) represents a group represented by the following formula (B2) or (B3).

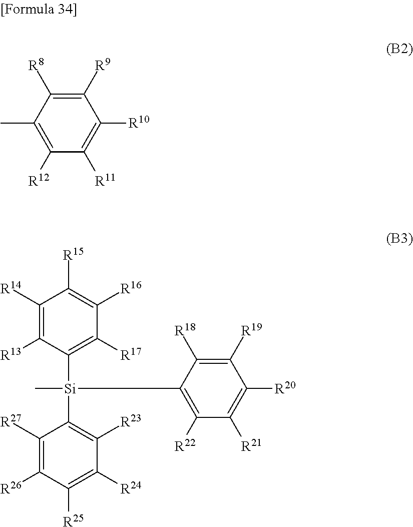

In the formula (B2), R⁸ to R¹² independently represent a hydrogen atom or a hydrocarbon group having 1 to 40 carbon atoms. Adjacent groups may form a cyclic structure. The hydrocarbon group may be substituted. In the formula (B3), R¹³ to R²⁷ independently represent a hydrogen atom or a hydrocarbon group having 1 to 40 carbon atoms.

Adjacent groups may form a cyclic structure. The hydrocarbon group may be substituted.

Examples of the hydrocarbon group having 1 to 40 carbon atoms represented by each of R⁸ to R¹² and R¹³ to R²⁷ in the formulae (B2) and (B3) are the same as those of R² to R⁷ in the formula (B1).

Examples of the divalent group formed when adjacent ones of groups R⁸ to R¹² and R¹³ to R²⁷ form a cyclic structure are a tetramethylene group, a pentamethylene group, a hexamethylene group, a diphenylmethane-2,2′-diyl group, a diphenylethane-3,3′-diyl group and a diphenylpropane-4,4′-diyl group.

The electron transporting layer preferably contains at least one of nitrogen-containing heterocycle derivatives respectively represented by the following formulae (B4) to (B6).

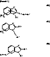

In the formulae (B4) to (B6), R represents a hydrogen atom, an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, or an alkoxy group having 1 to 20 carbon atoms.

n is an integer of 0 to 4.

In the formulae (B4) to (B6), R¹ represents an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, or an alkoxy group having 1 to 20 carbon atoms.

In the formulae (B4) to (B6), R² and R³ independently represent a hydrogen atom, an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, or an alkoxy group having 1 to 20 carbon atoms.

In the formulae (B4) to (B6), L represents an aromatic hydrocarbon group having 6 to 60 ring carbon atoms, a fused aromatic hydrocarbon group having 6 to 60 ring carbon atoms, a pyridinylene group, a quinolinylene group, or a fluorenylene group.

In the formulae (B4) to (B6), Ar¹ represents an aromatic hydrocarbon group having 6 to 60 ring carbon atoms, a fused aromatic hydrocarbon group having 6 to 60 ring carbon atoms, a pyridinylene group, or a quinolinylene group.

In the formulae (B4) to (B6), Ar² represents an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, or an alkoxy group having 1 to 20 carbon atoms.

In the formulae (B4) to (B6), Ar³ represents an aromatic hydrocarbon group having 6 to 60 ring carbon atoms, a fused aromatic hydrocarbon group having 6 to 60 ring carbon atoms, a pyridyl group, a quinolyl group, an alkyl group having 1 to 20 carbon atoms, an alkoxy group having 1 to 20 carbon atoms, or a group represented by —Ar¹—Ar² (in which Ar¹ and Ar² are the same as described above).

The fused aromatic hydrocarbon group, fused aromatic hydrocarbon group, pyridyl group, quinolyl group, alkyl group, alkoxy group, pyridinylene group, quinolinylene group and fluorenylene group described in relation to R, R¹, R², R³, L, Ar¹, Ar² and Ar³ in the formulae (B4) to (B6) may be substituted.

As an electron transporting compound for the electron injecting layer or the electron transporting layer, 8-hydroxyquinoline or a metal complex of its derivative, an oxadiazole derivative and a nitrogen-containing heterocyclic derivative are preferable. An example of the 8-hydroxyquinoline or the metal complex of its derivative is a metal chelate oxinoid compound containing a chelate of oxine (typically 8-quinolinol or 8-hydroxyquinoline). For instance, tris(8-quinolinol) aluminum can be used. Examples of the oxadiazole derivative are as follows.

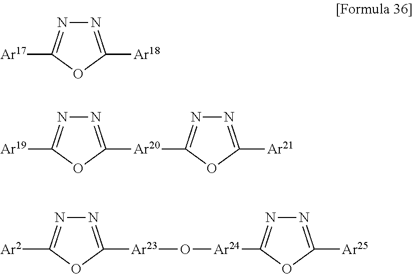

In each of the formulae representing the oxadiazole derivatives, Ar¹⁷, Ar¹⁸, Ar¹⁹, Ar²¹, Ar²² and Ar²⁵ represent an aromatic hydrocarbon group having 6 to 40 ring carbon atoms, or a fused aromatic hydrocarbon group having 6 to 40 ring carbon atoms.

Note that the above-described aromatic hydrocarbon group and fused aromatic hydrocarbon group may be substituted. Ar¹⁷ and Ar¹⁸, Ar¹⁹ and Ar²¹, and Ar²² and Ar²⁵ may be mutually the same or different.

Examples of the above-described aromatic hydrocarbon group or fused aromatic hydrocarbon group are a phenyl group, naphthyl group, biphenyl group, anthranil group, perylenyl group and pyrenyl group. Examples of the substituent therefor are an alkyl group having 1 to 10 carbon atoms, alkoxy group having 1 to 10 carbon atoms and cyano group.

In each of the formulae representing the oxadiazole derivatives, Ar²⁰, Ar²³ and Ar²⁴ represent a divalent aromatic hydrocarbon group having 6 to 40 ring carbon atoms, or a divalent fused aromatic hydrocarbon group having 6 to 40 ring carbon atoms.

Note that the above-described aromatic hydrocarbon group and fused aromatic hydrocarbon group may be substituted.

Ar²³ and Ar²⁴ may be mutually the same or different.

Examples of the above-described divalent aromatic hydrocarbon group or divalent fused aromatic hydrocarbon group are a phenylene group, naphthylene group, biphenylene group, anthranylene group, perylenylene group and pyrenylene group. Examples of the substituent therefor are an alkyl group having 1 to 10 carbon atoms, alkoxy group having 1 to 10 carbon atoms and cyano group.

Such an electron transport compound is preferably an electron transport compound that can be favorably formed into a thin film(s). Examples of the electron transport compound are as follows.

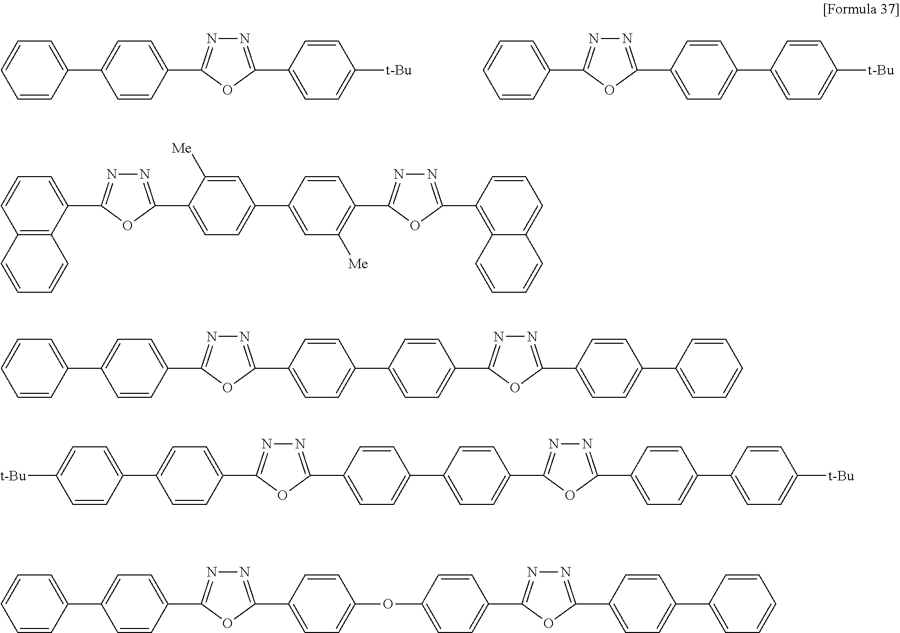

An example of the nitrogen-containing heterocyclic derivative as the electron transporting compound is a nitrogen-containing compound that is not a metal complex, the derivative being formed of an organic compound represented by one of the following general formulae. Examples of the nitrogen-containing heterocyclic derivative are five-membered ring or six-membered ring derivative having a skeleton represented by the formula (B7) and a derivative having a structure represented by the formula (B8).

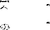

In the formula (B8), X represents a carbon atom or a nitrogen atom. Z₁ and Z₂ each independently represent a group of atoms capable of forming a nitrogen-containing heterocycle.

Preferably, the nitrogen-containing heterocyclic derivative is an organic compound having a nitrogen-containing aromatic polycyclic group having a five-membered ring or six-membered ring. Further, when the nitrogen-containing heterocyclic derivative is such a nitrogen-containing aromatic polycyclic group that contains plural nitrogen atoms, the nitrogen-containing heterocyclic derivative is preferably a nitrogen-containing aromatic polycyclic organic compound having a skeleton formed by a combination of the skeletons respectively represented by the formulae (B7) and (B8), or by a combination of the skeletons respectively represented by the formulae (B7) and (B9).

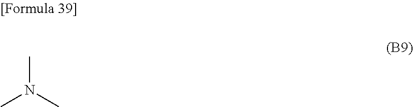

A nitrogen-containing group of the nitrogen-containing aromatic polycyclic organic compound is selected from nitrogen-containing heterocyclic groups respectively represented by the following formulae.

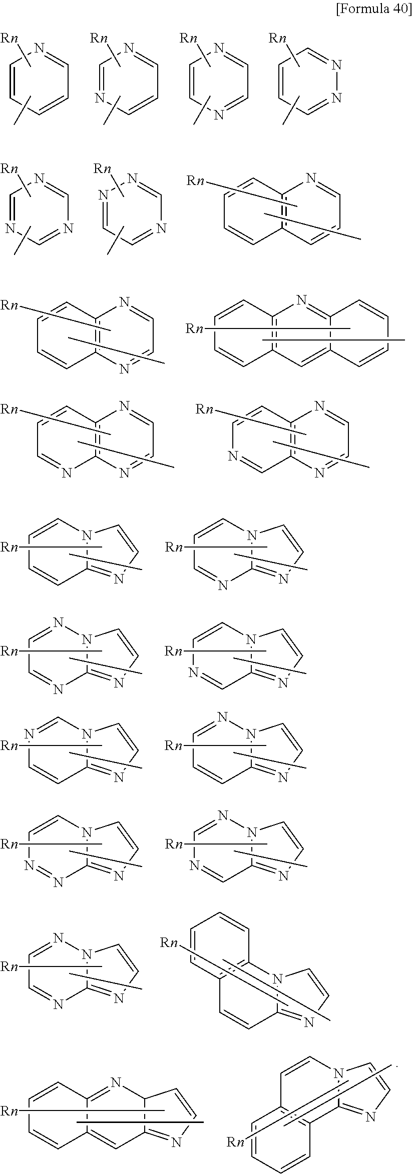

In each of the formulae representing the nitrogen-containing heterocyclic groups, R represents an aromatic hydrocarbon group having 6 to 40 ring carbon atoms, a fused aromatic hydrocarbon group having 6 to 40 ring carbon atoms, an aromatic heterocyclic group having 2 to 40 ring carbon atoms, a fused aromatic heterocyclic group having 2 to 40 ring carbon atoms, an alkyl group having 1 to 20 carbon atoms, or an alkoxy group having 1 to 20 carbon atoms.

In each of the formulae representing the nitrogen-containing heterocyclic groups, n is an integer of 0 to 5. When n is integer of 2 or more, a plurality of R may be mutually the same or different.

A preferable specific compound is a nitrogen-containing heterocyclic derivative represented by the following formula (B10).

HAr-L¹-Ar¹—Ar² (B10)

In the formula (B10), HAr represents a nitrogen-containing heterocyclic group having 1 to 40 ring carbon atoms.

In the formula (B10), L¹ represents a single bond, an aromatic hydrocarbon group having 6 to 40 ring carbon atoms, a fused aromatic hydrocarbon group having 6 to 40 ring carbon atoms, an aromatic heterocyclic group having 2 to 40 ring carbon atoms, or a fused aromatic heterocyclic group having 2 to 40 ring carbon atoms.

In the formula (B10), Ar¹ represents a divalent aromatic hydrocarbon group having 6 to 40 ring carbon atoms.

In the formula (B10), Ar² represents an aromatic hydrocarbon group having 6 to 40 ring carbon atoms, a fused aromatic hydrocarbon group having 6 to 40 ring carbon atoms, an aromatic heterocyclic group having 2 to 40 ring carbon atoms, or a fused aromatic heterocyclic group having 2 to 40 ring carbon atoms.

The nitrogen-containing heterocyclic group, aromatic hydrocarbon group, fused aromatic hydrocarbon group, aromatic heterocyclic group and fused aromatic heterocyclic group described in relation to HAr, L¹, Ar¹ and Ar² in the formula (B10) may be substituted.

HAr in the formula (B 10) is exemplarily selected from the following group.

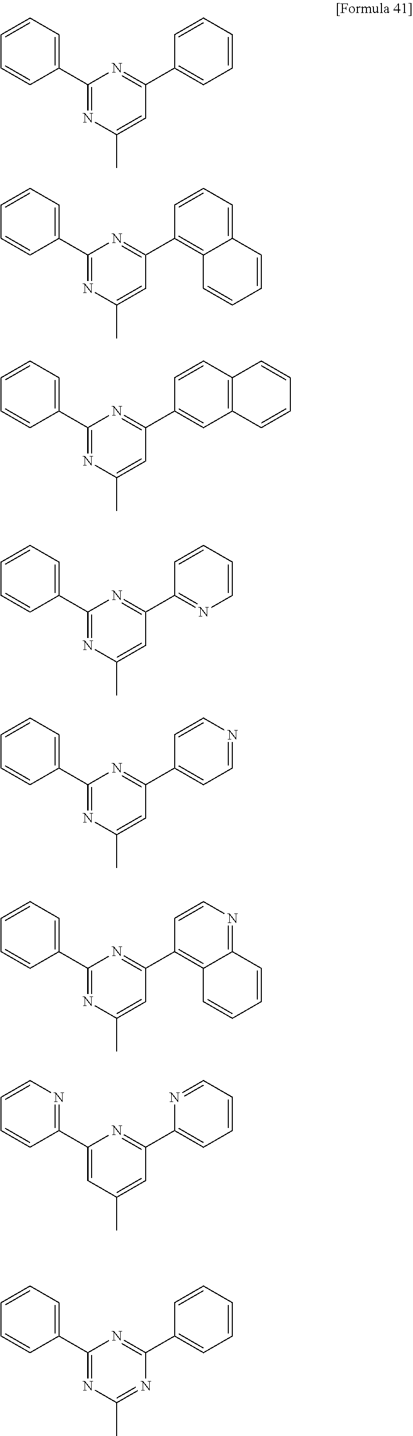

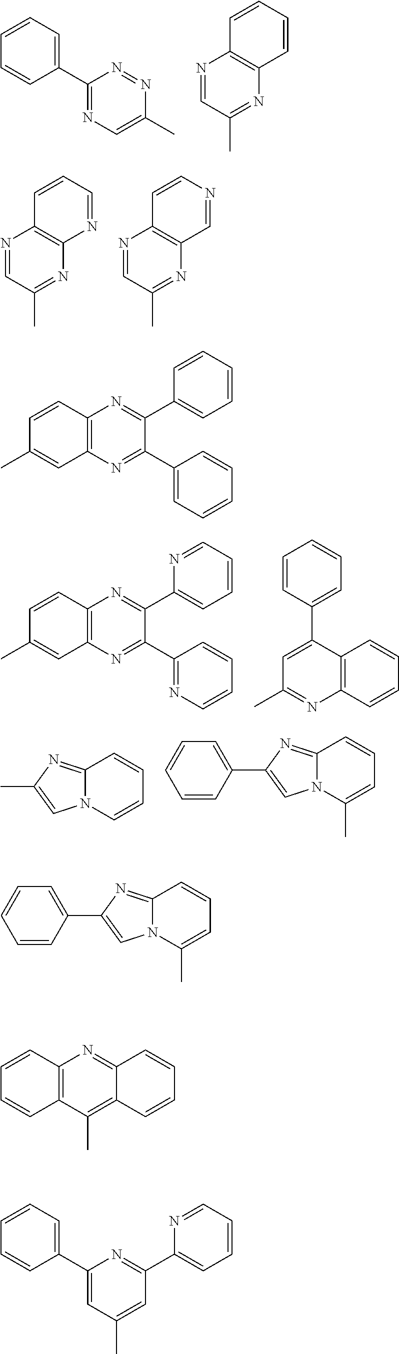

L¹ in the formula (B10) is exemplarily selected from the following group.

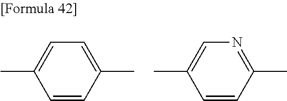

Ar¹ in the formula (B10) is exemplarily selected from the following arylanthranil group.

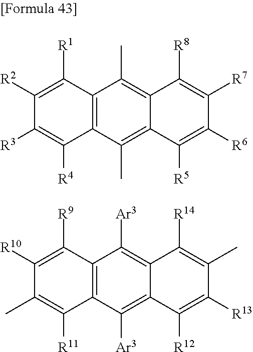

In the formula of the arylanthranil group, R¹ to R¹⁴ independently represent a hydrogen atom, a halogen atom, an alkyl group having 1 to 20 carbon atoms, an alkoxy group having 1 to 20 carbon atoms, an aryloxy group having 6 to 40 ring carbon atoms, an aromatic hydrocarbon group having 6 to 40 ring carbon atoms, a fused aromatic hydrocarbon group having 6 to 40 ring carbon atoms, an aromatic heterocyclic group having 2 to 40 ring carbon atoms, or a fused aromatic heterocyclic group having 2 to 40 ring carbon atoms.

In the formula of the arylanthranil group, Ar³ represents an aromatic hydrocarbon group having 6 to 40 ring carbon atoms, a fused aromatic hydrocarbon group having 6 to 40 ring carbon atoms, an aromatic heterocyclic group having 2 to 40 ring carbon atoms, or a fused aromatic heterocyclic group having 2 to 40 ring carbon atoms.

The aromatic hydrocarbon group, fused aromatic hydrocarbon group, aromatic heterocyclic group and fused aromatic heterocyclic group described in relation to R¹ to R¹⁴ and Ar³ in the formula of the arylanthranil group may be substituted.

All of R¹ to R⁸ of the nitrogen-containing heterocyclic derivative may be hydrogen atoms.

In the formula of the arylanthranil group, Ar² is exemplarily selected from the following group.

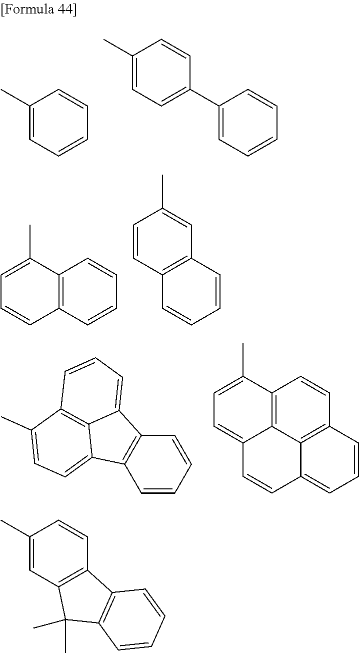

Other than the above, the following compound (see JP-A-9-3448) can be favorably used for the nitrogen-containing aromatic polycyclic organic compound as the electron transporting compound.

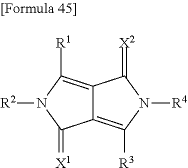

In the formula of the nitrogen-containing aromatic polycyclic organic compound, R¹ to R⁴ independently represent a hydrogen atom, an aliphatic group, an alicyclic group, a carbocyclic aromatic cyclic group, or a heterocyclic group.

Note that the above-described aliphatic group, alicyclic group, carbocyclic aromatic cyclic group and heterocyclic group may be substituted.

In the formula of the nitrogen-containing aromatic polycyclic organic compound, X¹ and X² independently represent an oxygen atom, a sulfur atom or a dicyanomethylene group.

Alternatively, the following compound (see JP-A-2000-173774) can also be favorably used for the electron transporting compound.

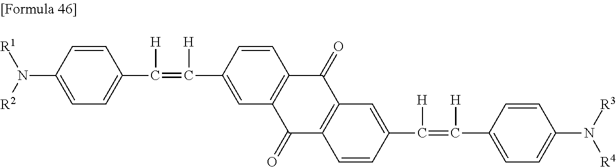

In the formula, R¹, R², R³ and R⁴, which may be mutually the same or different, each represent an aromatic hydrocarbon group or fused aromatic hydrocarbon group represented by the following formula.

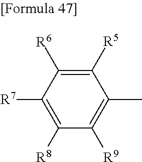

In the formula, R⁵, R⁶, R⁷, R⁸ and R⁹, which may be mutually the same or different, each represent a hydrogen atom, saturated or unsaturated alkoxy group, alkyl group, amino group or alkylamino group. At least one of R⁵, R⁶, R⁷, R⁸ and R⁹ represents a saturated or unsaturated alkoxy group, alkyl group, amino group or alkylamino group.

A polymer compound containing the nitrogen-containing heterocyclic group or a nitrogen-containing heterocyclic derivative may be used for the electron transporting compound.

The electron injecting layer preferably contains an inorganic compound such as an insulator or a semiconductor in addition to the nitrogen-containing cyclic derivative. Such an insulator or a semiconductor, when contained in the electron injecting layer, can effectively prevent a current leak, thereby enhancing electron capability of the electron injecting layer.

The electron injecting layer in the exemplary embodiment may preferably contain a reduction-causing dopant.

### Thickness

In the organic EL device according to the exemplary embodiment, a thickness of each of the layers between the anode and the cathode is not particularly limited except for a thickness of each of the above-mentioned layers to be particularly defined. However, the thickness of each of the emitting layer and the like is typically preferably in a range from several nanometers to 1 μm because an excessively-thinned film is likely to entail defects such as a pin hole while an excessively-thickened film requires application of high voltage and deteriorates efficiency.

### Manufacturing Method of Organic EL Device

A manufacturing method of the organic EL device according to the exemplary embodiment is not particularly limited. Any conventional manufacturing method of the organic EL device is usable. Specifically, the respective layers on the substrate are formable by vacuum deposition, a casting method, a coating method and a spin coating method. Moreover, in addition to the casting method, the coating method and the spin coating using a solution, in which the organic material of the layers are dispersed, on a transparent polymer such as polycarbonate, polyurethane, polystyrene, polyarylate and polyester, the respective layers can be formed by simultaneous deposition with the organic material and the transparent polymer.

### Measurement Method of Physical Properties

Physical properties of the materials used for the organic EL device are measured by the following method.

### Ionization Potential (Ip)

The respective materials are irradiated with spectroscopic light (excitation light) of a deuterium lamp through a monochromator. Ejected photoelectrons are measured by an electrometer. A threshold for ejecting photoelectrons is obtained by an extrapolation from an irradiation photon energy curve of the ejected photoelectrons. As a measurement device, Atmospheric Ultraviolet Photoelectron Spectroscopy AC-3 (manufactured by RIKEN KEIKI Co., Ltd.) is used.

### Second Exemplary Embodiment

Next, a second exemplary embodiment is described below.

In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable.

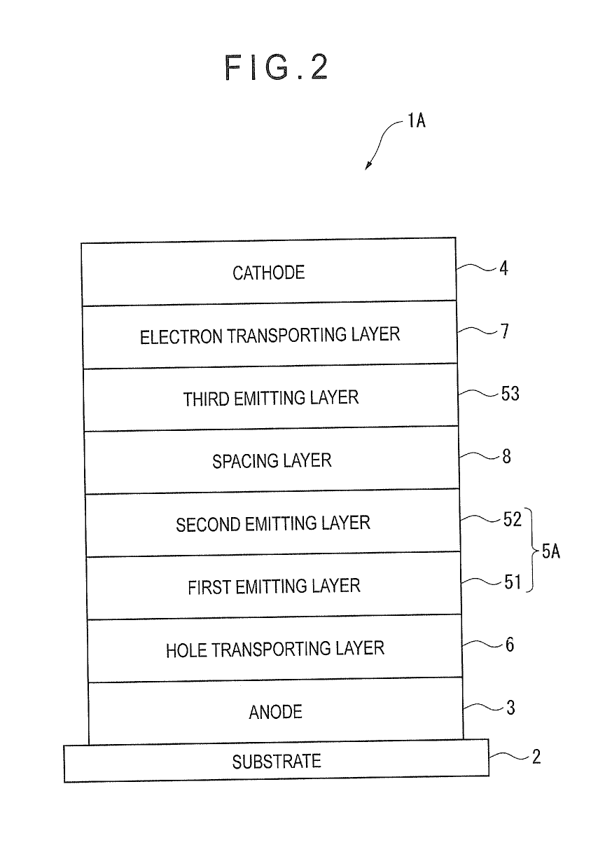

An organic EL device 1A according to the second exemplary embodiment is different from the organic EL device according to the first exemplary embodiment in including an emitting unit 5A, a third emitting layer 53, and a spacing layer 8 interposed between the emitting unit 5A and the third emitting layer 53. As shown in FIG. 2, the anode 3, the hole transporting layer 6, the emitting unit 5A, the spacing layer 8, the third emitting layer 53, the electron transporting layer 7 and cathode 4 are sequentially laminated on the substrate 2.

The emitting unit 5A includes: a first emitting layer 51 formed continuous to the hole transporting layer 6; and a second emitting layer 52 formed between the first emitting layer 51 and the spacing layer 8 and continuous thereto.

The first emitting layer 51 contains the first host material and a first luminescent material. As the first host material, an amine derivative such as a monoamine compound, diamine compound, triamine compound, tetramine compound and amine compound substituted by a carbazole group is preferable. Alternatively, the first host material may be the same as the first host material represented by the formula (1) and the second host material represented by the formula (2). The first luminescent material preferably exhibits an emission peak of 570 nm or more. Herein, an emission color providing the emission peak of 570 nm or more is, for instance, red.

The second emitting layer 52 is an emitting layer in the second exemplary embodiment. In other words, The second emitting layer 52 is the same as the emitting layer 5 in the first exemplary embodiment.

The spacing layer 8 is a layer for adjusting injection of charges (holes or electrons) to the second emitting layer 52 and the third emitting layer 53 to adjust balance of the charges injected to the second emitting layer 52 and the third emitting layer 53, by providing energy barriers at HOMO level and LUMO level against the second emitting layer 52 and the third emitting layer 53 which are adjacent to the spacing layer 8. Moreover, the spacing layer 8 prevents dispersion of the triplet energy generated in the second emitting layer 52 to the third emitting layer 53 by providing a triplet energy barrier, thereby effectively causing light emission in the second emitting layer 52.

The third emitting layer 53 is, for instance, a layer exhibiting a blue fluorescent emission with a peak wavelength of 450 nm to 500 nm. The third emitting layer 53A contains a third host material and a third luminescent material.

The third host material is exemplified by a compound having a structure represented by the following formula (41) having an anthracene central skeleton.

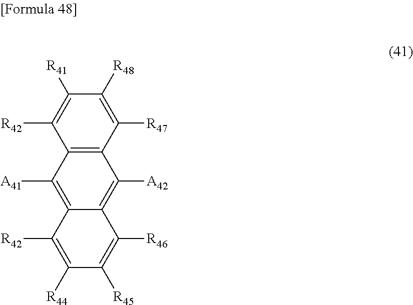

In the formula (41), A₄₁ and A₄₂ each represent a group derived from a substituted or unsubstituted aromatic ring having 6 to 20 ring carbon atoms.

R₄₁ to R₄₈ each represent any one of a hydrogen atom, a substituted or unsubstituted aryl group having 6 to 50 ring carbon atoms, a substituted or unsubstituted heteroaryl group having 5 to 50 ring atoms, a substituted or unsubstituted alkyl group having 1 to 50 carbon atoms, a substituted or unsubstituted cycloalkyl group having 3 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 ring atoms, a substituted or unsubstituted arylthio group having 5 to 50 ring atoms, a substituted or unsubstituted alkoxycarbonyl group having 1 to 50 carbon atoms, a substituted or unsubstituted silyl group, a carboxyl group, a halogen atom, a cyano group, a nitro group and a hydroxyl group.

Examples of the substituent for the aromatic ring in A₄₁ and A₄₂ are a substituted or unsubstituted aryl group having 6 to 50 ring carbon atoms, a substituted or unsubstituted alkyl group having 1 to 50 carbon atoms, a substituted or unsubstituted cycloalkyl group having 3 to 50 carbon atoms, a substituted or unsubstituted alkoxy group having 1 to 50 carbon atoms, a substituted or unsubstituted aralkyl group having 6 to 50 carbon atoms, a substituted or unsubstituted aryloxy group having 5 to 50 ring atoms, a substituted or unsubstituted arylthio group having 5 to 50 ring atoms, a substituted or unsubstituted alkoxycarbonyl group having 1 to 50 carbon atoms, a substituted or unsubstituted silyl group, a carboxyl group, a halogen atom, a cyano group, a nitro group and a hydroxyl group.

Examples of the third luminescent material are an arylamine compound, a styrylamine compound, anthracene, naphthalene, phenanthrene, pyrene, tetracene, coronene, chrysene, fluorescein, perylene, phthaloperylene, naphthaloperylene, perynone, phthaloperynone, naphthaloperynone, diphenylbutadiene, tetraphenylbutadiene, coumaline, oxadiazole, aldazine, bisbenzoxazoline, bisstyryl, pyrazine, cyclopentadiene, a metal complex of quinoline, a metal complex of aminoquinoline, a metal complex of benzoquinoline, imine, dipehnylethylene, vinylanthracene, diaminocarbazole, pyrane, thiopyrane, polymethine, merocyanine, an imidazole chelated oxinoid compound, quinacridone, rubrene and fluorescent pigment.

The third emitting layer 53 is, for instance, a layer exhibiting a blue fluorescent emission with a peak wavelength of 450 nm to 500 nm.

Since the organic EL device 1A includes the red-emitting first emitting layer 51, the green-emitting second emitting layer 52 and the blue-emitting third emitting layer 53, the entire device can emit white light.

Accordingly, the organic EL device 1A is suitably usable as a planar light source such as an illuminator and a backlight.

### Third Exemplary Embodiment

Next, a third exemplary embodiment is described below.

In the description of the third exemplary embodiment, the same components as those in the first exemplary embodiment are denoted by the same reference signs and names to simplify or omit an explanation of the components. In the third exemplary embodiment, the same materials and compounds as described in the first exemplary embodiment are usable.

An organic EL device according to the third exemplary embodiment is a so-called tandem-type device including a charge generating layer and at least two emitting units. In addition to charges injected from a pair of electrodes, charges supplied from the charge generating layer are injected into the emitting units. Accordingly, by providing the charge generating layer, luminous efficiency (current efficiency) relative to injected current is improved.

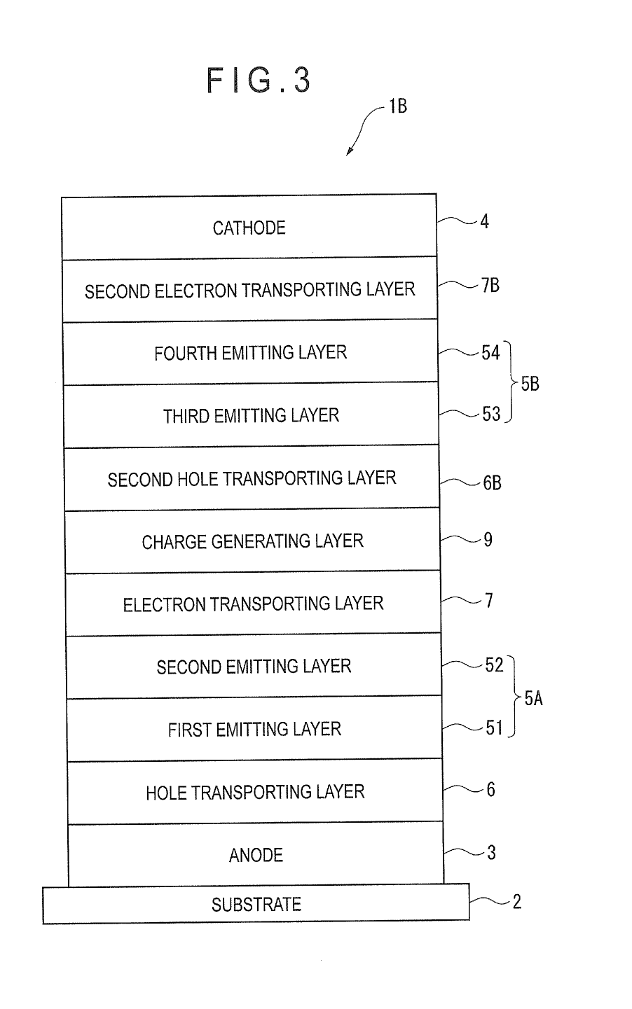

As shown in FIG. 3, an organic EL device 1B according to the third exemplary embodiment is provided by laminating the anode 3, the hole transporting layer 6, the first emitting unit 5A, the electron transporting layer 7, a charge generating layer 9, a second hole transporting layer 6B, a second emitting unit 5B, a second transporting layer 7B and the cathode 4 on the substrate 2 in this sequence.

The first emitting unit 5A is the same as the first emitting unit in the second exemplary embodiment. The second emitting layer 52 forming the first emitting unit 5A is the emitting layer of the invention, in other words, the same as the emitting layer 5 of the first exemplary embodiment and the second emitting layer of the second exemplary embodiment.

The second emitting unit 5B includes: the third emitting layer 53 formed continuous to the second hole transporting layer 6B; and a fourth emitting layer 54 formed between the third emitting layer 53 and the second electron transporting layer 7B and continuous thereto.

The third emitting layer 53 is the same as the third emitting layer of the second exemplary embodiment.

The fourth emitting layer 54B is, for instance, a layer exhibiting a green fluorescent emission with a peak wavelength of 500 nm to 570 nm. The fourth emitting layer 54 contains a fourth host material and a fourth luminescent material.

The charge generating layer 9 generates charges when an electric field is applied to the organic EL device 1B and injects electrons to the electron transporting layer 7 while injecting holes to the second hole transporting layer 6B.

As a material for the charge generating layer 9, a known material such as a material described in U.S. Pat. No. 7,358,661 is usable. Specific examples of the material include oxides, nitrides, iodides and borides of metals such as In, Sn, Zn, Ti, Zr, Hf, V, Mo, Cu, Ga, Sr, La and Ru. In order that the third emitting layer 53 easily accepts the electrons from the charge generation layer 9, it is suitable to dope a donor represented by an alkali metal in the vicinity of an interface of the charge generation layer in the electron transporting layer 7. As the donor, at least one of a donor metal, donor metal compound and donor metal complex can be selected. Specific examples of the compounds used for the donor metal, donor metal compound and donor metal complex include compounds disclosed in Patent Application Number PCT/JP2010/003434.

The second hole transporting layer 6B and the second electron transporting layer 7B are the same as the hole transporting layer and the electron transporting layer according to the first exemplary embodiment.

Since the organic EL device 1B is a so-called tandem-type device, the drive voltage can be reduced and durability can also be improved.

### Modifications of Embodiment(s)

It should be noted that the present invention is not limited to the above description but may include any modification as long as such modification stays within a scope and a spirit of the present invention.

Although the hole transporting layer is formed continuous to the anode in the first and second exemplary embodiments, a hole injecting layer may be further formed between the anode and the hole transporting layer.

A material for the hole injecting layer is preferably a porphyrin compound, an aromatic tertiary amine compound or a styryl amine compound, particularly preferably the aromatic tertiary amine compound such as hexacyanohexaazatriphenylene (FIAT).

Although the electron transporting layer is formed continuous to the cathode in the first to third exemplary embodiments, an electron injecting layer may be further formed between the cathode and the electron transporting layer.

Although two emitting units are formed in the third exemplary embodiment, three or more emitting units may be formed.

### EXAMPLES

Embodiments of the invention will be described in detail below with reference to Examples and Comparatives. However, the invention is not limited to Example and the like.

### Example 1

The organic EL device according to Example 1 was manufactured as follows.

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes.

After the glass substrate having the transparent electrode line was cleaned, the glass substrate was mounted on a substrate holder of a vacuum deposition apparatus, so that a compound HA-1 was deposited to form a 5-nm thick HA-1 film on a surface of the glass substrate where the transparent electrode line was provided so as to cover the transparent electrode. The HA-1 film serves as a hole injecting layer.

On the HA-1 film, a compound HT-1 was deposited to form a 55-nm thick HT-1 film. The HT-1 film serves as a first hole transporting layer.

On the HT-1 film, a compound GH1-1 was deposited to form a 10-nm thick GH1-1 film. The GH1-1 film serves as a second hole transporting layer.

On the second hole transporting layer, a compound GH2-1 (first host material), the compound GH1-1 (second host material) and Ir(Phppy)₃ (phosphorescent dopant material) were co-deposited. Thus, a 35-nm thick emitting layer of green emission was formed. The concentration of the second host material and the concentration of the phosphorescent dopant material were respectively 10 mass % and the rest was occupied by the first host material.

Then, the compound GH2-1 was deposited on this emitting layer to form a 5-nm thick hole blocking layer.

A compound ET-1 was deposited on the hole blocking layer to form a 30-nm thick electron transporting layer.

Further, LiF was deposited on the electron transporting layer at a rate of 1 Å/min to form a 1-nm thick electron injecting layer. Furthermore, a metal Al was deposited on an electron injecting cathode to form an 80-nm thick cathode.

### Comparative 1

An organic EL device was manufactured in the same manner as Example 1, except that the compound GH1-1 of the second host material was not used in Example 1.

Table 1 shows device structures of Example 1 and Comparative 1. The numerals without a unit in parentheses in Table 1 indicate a thickness of each layer (unit: nm). The numerals with % indicate a mass % concentration of the compound. In the emitting layer, the mass % concentrations of the second host material and the phosphorescent dopant material are shown but the concentration of the first host material is omitted.

### Evaluation of Organic EL Device

The manufactured organic EL devices were evaluated in terms of a drive voltage, a current efficiency L/J, a power efficiency η, an external quantum efficiency EQE and lifetime. A current density for each of the evaluation items was 10.00 mA/cm². The results of the evaluation are shown in Table 2.

### Drive Voltage

Electrical current was applied between ITO and Al such that a current density was 10.00 mA/cm², where voltage (unit: V) was measured.

### Current Efficiency L/J and Power Efficiency η

When voltage was applied on the device such that the current density was 10.00 mA/cm², spectral radiance spectrum was measured by a spectroradiometer (CS-1000: manufactured by Konica Minolta Inc.). From the obtained spectral radiance spectrum, the current efficiency (unit: cd/A) and the power efficiency η (unit: lm/W) were calculated.

### External Quantum Efficiency EQE

The external quantum efficiency EQE (unit: %) was calculated based on the obtained spectral-radiance spectra, assuming that the spectra was provided under a Lambertian radiation.

### Lifetime

An elapsed time (LT80) until an initial luminance intensity of 25,000 nit(cd/m²) was reduced to 80% of the initial luminance intensity was obtained.

### Examples 2 to 9 and Comparatives 2 to 6

The organic EL devices according to Examples 2 to 9 and Comparatives 2 to 6 were formed in the same manner as in Example 1, except that the materials, a thickness of each of the layers and a concentration of each of the emitting materials were changed as shown in Table 1.

Compounds used in Examples 1 to 9 and Comparatives 1 to 9 will be shown below. In Examples 1 to 9, GH2-1, GH2-2 and GH2-4 contained in the emitting layer correspond to the first host material in the invention and GH1-1, GH1-2 and GH1-3 correspond to the second host material in the invention.

Evaluation results of these organic EL devices in the same manner as in Example 1 are shown in Table 2.

In Tables 1 and 2, device systems represented by A to C show a difference in a device arrangement except for the compound of the first host material, the compound of the second host material and the concentration thereof. For instance, Ir(Phppy)₃ is used as the dopant material in the device system A, whereas Ir(ppy)₃ is used as the dopant material in the device system B. The device system C is different from the device system B in the thickness of the each of the first and second hole transporting layers, that the hole blocking layer is not provided and that the compound used in the electron transporting layer is the compound ET-2.

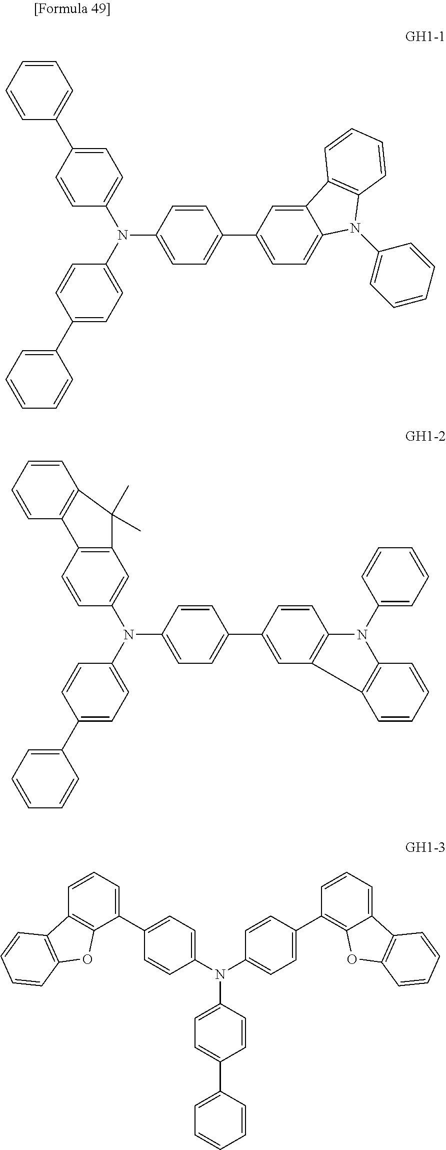 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4cccc5c4oc4ccccc45)cc3)c3ccc(-c4cccc5c4oc4ccccc45)cc3)cc2)cc1]

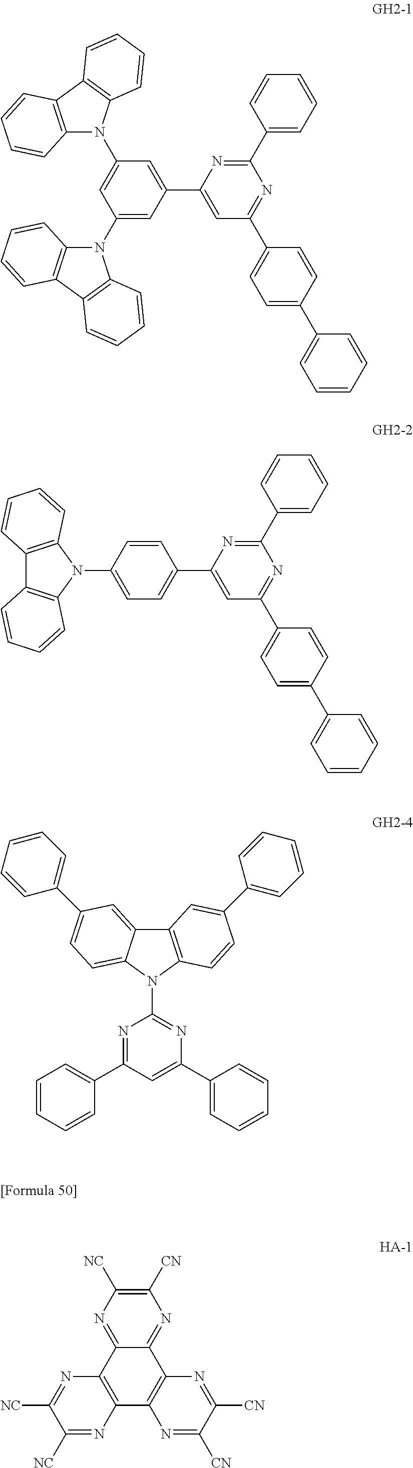 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2ccc(-c3cc(-c4ccc(-n5c6ccccc6c6ccccc65)cc4)nc(-c4ccccc4)n3)cc2)cc1 ; c1ccc(-c2ccc3c(c2)c2cc(-c4ccccc4)ccc2n3-c2nc(-c3ccccc3)cc(-c3ccccc3)n2)cc1 ; N#Cc1nc2c3nc(C#N)c(C#N)nc3c3nc(C#N)c(C#N)nc3c2nc1C#N]

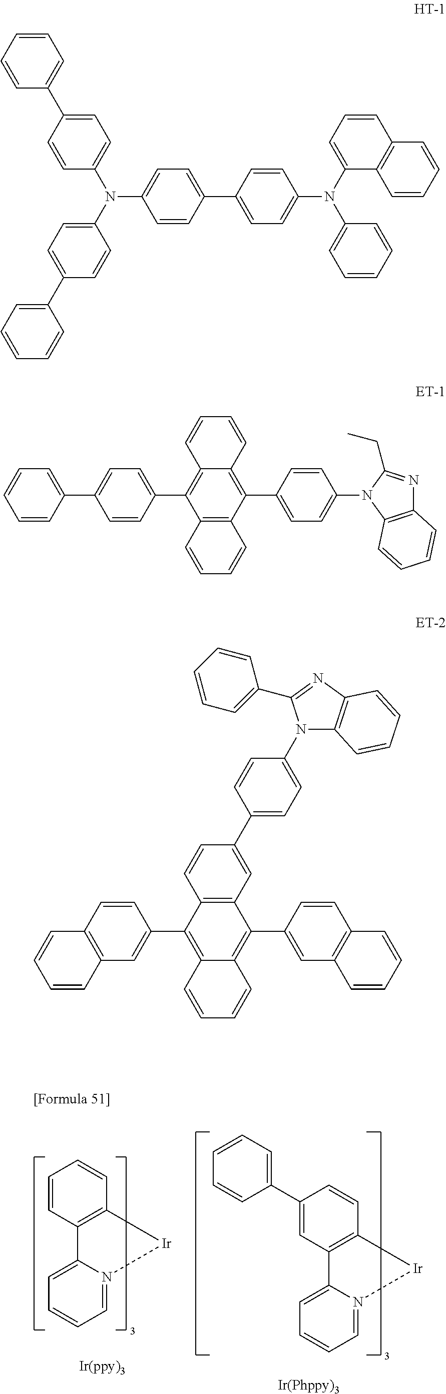

TABLE 1

| | Device | |
|---|---|---|
| | System | Device Arrangements |
| Example 1 | A | ITO(75)/HA-1(5)/HT-1(55)/GH1-1(10)/GH2-1: GH1-1: Ir(Phppy)₃(35, 10%: 10%)/GH2-1(5)/ET-1(30)/LiF(1)/Al(80) |
| Comp. 1 | | ITO(75)/HA-1(5)/HT-1(55)/GH1-1(10)/GH2-1: Ir(Phppy)₃ (35, 10%)/GH2-1(5)/ET-1(30)/LiF(1)/Al(80) |
| Example 2 | | ITO(75)/HA-1(5)/HT-1(55)/GH1-1(10)/GH2-1: GH1-2: Ir(Phppy)₃ (35, 10%: 10%)/GH2-1(5)/ET-1(30)/LiF(1)/Al(80) |
| Example 3 | B | ITO(75)/HA-1(5)/HT-1(55)/GH1-1(10)/GH2-2: GH1-1: Ir(ppy)₃(35, 10%: 10%)/GH2-1(5)/ET-1(30)/LiF(1)/Al(80) |
| Comp. 2 | | ITO(75)/HA-1(5)/HT-1(55)/GH1-1(10)/GH2-2: Ir(ppy)₃(35, 10%)/GH2-1(5)/ET-1(30)/LiF(1)/Al(80) |
| Example 4 | | ITO(75)/HA-1(5)/HT-1(55)/GH1-1(10)/GH2-1: GH1-1: Ir(ppy)₃(35, 10%: 10%)/GH2-1(5)/ET-1(30)/LiF(1)/Al(80) |
| Comp. 3 | | ITO(75)/HA-1(5)/HT-1(55)/GH1-1(10)/GH2-1: Ir(ppy)₃(35, 10%)/GH2-1(5)/ET-1(30)/LiF(1)/Al(80) |
| Example 5 | | ITO(75)/HA-1(5)/HT-1(55)/GH1-1(10)/GH2-4: GH1-1: Ir(ppy)₃(35, 10%: 10%)/GH2-1(5)/ET-1(30)/LiF(1)/Al(80) |
| Comp. 4 | | ITO(75)/HA-1(5)/HT-1(55)/GH1-1(10)/GH2-4: Ir(ppy)₃(35, 10%)/GH2-1(5)/ET-1(30)/LiF(1)/Al(80) |
| Example 6 | C | ITO(75)/HA-1(5)/HT-1(150)/GH1-1(20)/GH2-1: GH1-1: Ir(ppy)₃(40, 10%: 5%)/ET-2(30)/LiF(1)/Al(80) |
| Example 7 | | ITO(75)/HA-1(5)/HT-1(150)/GH1-1(20)/GH2-1: GH1-1: Ir(ppy)₃(40, 10%: 10%)/ET-2(30)/LiF(1)/Al(80) |
| Example 8 | | ITO(75)/HA-1(5)/HT-1(150)/GH1-1(20)/GH2-1: GH1-3: Ir(ppy)₃(40, 10%: 5%)/ET-2(30)/LiF(1)/Al(80) |
| Example 9 | | ITO(75)/HA-1(5)/HT-1(150)/GH1-1(20)/GH2-1: GH1-3: Ir(ppy)₃(40, 10%: 10%)/ET-2(30)/LiF(1)/Al(80) |
| Comp. 5 | | ITO(75)/HA-1(5)/HT-1(150)/GH1-1(20)/GH2-1: Ir(ppy)₃(40, 5%)/ET-2(30)/LiF(1)/Al(80) |
| Comp. 6 | | ITO(75)/HA-1(5)/HT-1(150)/GH1-1(20)/GH2-1: Ir(ppy)₃(40, 10%)/ET-2(30)/LiF(1)/Al(80) |

TABLE 2

| | | Cur- | | | | | |
|---|---|---|---|---|---|---|---|
| | De- | rent | | | | | |
| | vice | Den- | Drive | | | | LT80 |
| | Sys- | sity | Voltage | L/J | η | EQE | @25000 ni |
| | tem | (mA/cm²) | (V) | (cd/A) | (Im/W) | (%) | (hrs) |
| Ex- | A | 10 | 3.43 | 79.1 | 72.4 | 21 | 100 |
| ample 1 | | | | | | | |
| Comp. 1 | | 10 | 3.55 | 75.9 | 67.2 | 20.2 | 70 |
| Ex- | | 10 | 3.4 | 79.2 | 73.2 | 21.1 | 150 |
| ample 2 | | | | | | | |
| Ex- | B | 10 | 3.17 | 71.3 | 70.6 | 19.3 | 90 |
| ample 3 | | | | | | | |
| Comp. 2 | | 10 | 3.15 | 63.1 | 63 | 17.1 | 40 |
| Ex- | | 10 | 3.21 | 68.2 | 66.7 | 18.5 | 100 |
| ample 4 | | | | | | | |
| Comp. 3 | | 10 | 3.04 | 61.1 | 63.2 | 16.6 | 50 |
| Ex- | | 10 | 4.31 | 74.6 | 54.4 | 20.2 | 80 |
| ample 5 | | | | | | | |
| Comp. 4 | | 10 | 4.7 | 71.9 | 48 | 19.5 | 40 |
| Ex- | C | 10 | 3.69 | 53.6 | 45.7 | 15 | 35 |
| ample 6 | | | | | | | |
| Ex- | | 10 | 4.06 | 59.2 | 45.9 | 16.5 | 45 |
| ample 7 | | | | | | | |
| Ex- | | 10 | 4.01 | 45.4 | 35.6 | 12.6 | 30 |
| ample 8 | | | | | | | |
| Ex- | | 10 | 4.22 | 57.9 | 43.1 | 15.9 | 50 |
| ample 9 | | | | | | | |
| Comp. 5 | | 10 | 4.03 | 38.1 | 29.7 | 10.4 | 20 |
| Comp. 6 | | 10 | 3.92 | 50.7 | 40.7 | 14.1 | 30 |

Measurement results of ionization potentials of the first and second host materials and the hole transporting material are shown in Table 3. The ionization potentials were measured in the same manner as described above in the atmosphere by using a photoelectron spectrometer (AC-3 manufactured by RIKEN KEIKI Co., Ltd.). Specifically, a material was irradiated with light and the amount of electrons generated by charge separation was measured.

TABLE 3

| Compound | Ip(eV) |
|---|---|
| GH1-1 | 5.5 |
| GH1-2 | 5.48 |
| GH1-3 | 5.61 |
| GH2-1 | 6.13 |
| GH2-2 | 6.11 |
| GH2-4 | 5.71 |
| Ir(ppy)₃ | 5.1 |
| Ir(Phppy)₃ | 4.8 |

As shown in Table 3, the ionization potential Ip(h1) of the first host material, the ionization potential Ip(h2) of the second host material and the ionization potential Ip(d) of the phosphorescent dopant material which are used in Examples 1 to 9 satisfy the following relationship:

Ip(h1)>Ip(h2)>Ip(d)

Moreover, when the ionization potential Ip(EML) of the emitting layer of each of Examples was calculated according to the above numerical formula 3 based on the above ionization potential of each of the compounds, it was confirmed that the above numerical formula 2 was satisfied in each of Examples. The calculation results are shown in Table 4.

TABLE 4

| | Second | Emitting layer | | | | | | | | | | | [ΔIp(EML2- |
|---|---|---|---|---|---|---|---|---|---|---|---|---|---|
| | hole | | | | | Phos- | | | | | | ΔIp | HT)- |
| | trans- | First | | | | phorescent | | | | | | (EML2- | ΔIp(EML- |
| | porting | host | | Second host | | dopant | | | | | | HT)- | HT)] × |
| Layer | layer | material | | material | | material | | | | ΔIp | ΔIp | ΔIp | 100/ |
| Compound | GH1-1 | GH2-1 | | GH1-1 | | Ir(Phppy)₃ | | Ip | Ip | (EML- | (EML2- | (EML- | ΔIp(EML- |
| Ip | Ip(HT) | Ip(h1) | mass % | Ip(h2) | mass % | Ip(d) | mass % | (EML) | (EML2) | HT) | HT) | HT) | HT) |
| Comparative 1 | 5.5 eV | 6.1 eV | 90 | | 0 | 4.8 eV | 10 | | 5.997 | | 0.497 | | |
| Example 1 | 5.5 eV | 6.1 eV | 80 | 5.5 eV | 10 | 4.8 eV | 10 | 5.934 | | 0.434 | | 0.063 | 14.51612903 |
| | Second | Emitting layer | | | | | | | | | | | [ΔIp(EML2- |
| | hole | | | | | Phos- | | | | | | ΔIp | HT)- |
| | trans- | First | | Second | | phorescent | | | | | | (EML2- | ΔIp(EML- |
| | porting | host | | host | | dopant | | | | | | HT)- | HT)] × |
| Layer | layer | material | | material | | material | | | | ΔIp | ΔIp | ΔIp | 100/ |
| Compound | GH1-1 | GH2-2 | | GH1-1 | | Ir(ppy)₃ | | Ip | Ip | (EML- | (EML2- | (EML- | ΔIp(EML- |
| Ip | Ip(HT) | Ip(h1) | mass % | Ip(h2) | mass % | Ip(d) | mass % | (EML) | (EML2) | HT) | HT) | HT) | HT) |
| Comparative 2 | 5.5 eV | 6.1 eV | 90 | | 0 | 5.1 eV | 10 | | 6.009 | | 0.509 | | |
| Example 3 | 5.5 eV | 6.1 eV | 80 | 5.5 eV | 10 | 5.1 eV | 10 | 5.934 | | 0.448 | | 0.061 | 13.61607143 |
| | Second | Emitting layer | | | | | | | | | | | [ΔIp(EML2- |
| | hole | | | | | Phos- | | | | | | ΔIp | HT)- |
| | trans- | First | | Second | | phorescent | | | | | | (EML2- | ΔIp(EML- |
| | porting | host | | host | | dopant | | | | | | HT)- | HT)] × |
| Layer | layer | material | | material | | material | | | | ΔIp | ΔIp | ΔIp | 100/ |
| Compound | GH1-1 | GH2-4 | | GH1-1 | | Ir(ppy)₃ | | Ip | Ip | (EML- | (EML2- | (EML- | ΔIp(EML- |
| Ip | Ip(HT) | Ip(h1) | mass % | Ip(h2) | mass % | Ip(d) | mass % | (EML) | (EML2) | HT) | HT) | HT) | HT) |
| Comparative 4 | 5.5 eV | 5.7 eV | 90 | | 0 | 5.1 eV | 10 | | 5.649 | | 0.149 | | |
| Example 5 | 5.5 eV | 5.7 eV | 80 | 5.5 eV | 10 | 5.1 eV | 10 | 5.628 | | 0.128 | | 0.021 | 16.40625 |
| | Second | Emitting layer | | | | | | | | | | | [ΔIp(EML2- |
| | hole | | | | | Phos- | | | | | | ΔIp | HT)- |
| | trans- | First | | Second | | phorescent | | | | | | (EML2- | ΔIp(EML- |
| | porting | host | | host | | dopant | | | | | | HT)- | HT)] × |
| | layer | material | | material | | material | | | | ΔIp | ΔIp | ΔIp | 100/ |
| Layer | GH1-1 | GH2-1 | | GH1-1 | | Ir(ppy)₃ | | Ip | Ip | (EML- | (EML2- | (EML- | ΔIp(EML- |
| Compound | Ip(HT) | Ip(h1) | mass % | Ip(h2) | mass % | Ip(d) | mass % | (EML) | (EML2) | HT) | HT) | HT) | HT) |
| Comparative 5 | 5.5 eV | 6.1 eV | 95 | | 0 | 5.1 eV | 5 | | 6.0785 | | 0.5785 | | |
| Example 6 | 5.5 eV | 6.1 eV | 85 | 5.5 eV | 10 | 5.1 eV | 5 | 6.0155 | | 0.5155 | | 0.063 | 12.22114452 |
| | Second | Emitting layer | | | | | | | | | | | [ΔIp(EML2- |
| | hole | | | | | Phos- | | | | | | ΔIp | HT)- |
| | trans- | First | | Second | | phorescent | | | | | | (EML2- | ΔIp(EML- |
| | porting | host | | host | | dopant | | | | | | HT)- | HT)] × |
| | layer | material | | material | | material | | | | ΔIp | ΔIp | ΔIp | 100/ |
| Layer | GH1-1 | GH2-1 | | GH1-1 | | Ir(ppy)₃ | | Ip | Ip | (EML- | (EML2- | (EML- | ΔIp(EML- |
| Compound | Ip(HT) | Ip(h1) | mass % | Ip(h2) | mass % | Ip(d) | mass % | (EML) | (EML2) | HT) | HT) | HT) | HT) |
| Comparative 6 | 5.5 eV | 6.1 eV | 90 | | 0 | 5.1 eV | 10 | | 6.027 | | 0.527 | | |
| Example 7 | 5.5 eV | 6.1 eV | 80 | 5.5 eV | 10 | 5.1 eV | 10 | 5.964 | | 0.464 | | 0.063 | 13.57758621 |

In comparison between the organic EL devices in Examples and the organic EL devices in Comparatives in each of the device systems in Table 1, when the same compound as the first host material in Examples is contained as the host material and the concentration of the phosphorescent dopant material is the same as that in Examples, it is recognized that all the organic EL device in Examples exhibit a higher efficiency and a longer lifetime than those of the organic EL devices in Comparatives.

For instance, the organic EL device in Example 1 in which 10 mass % of the compound GH1-1 was added was confirmed to have improved in all of the drive voltage, current efficiency, voltage efficiency, external quantum efficiency EQE and lifetime as compared with the organic EL device in Comparative 1 in which the second host material was not added.

Moreover, the organic EL device in Comparative 6 contained 10 mass % of the phosphorescent dopant material Ir(ppy)₃, whereas the organic EL device in Comparative 5 contained 50 mass % of the phosphorescent dopant material Ir(ppy)₃. With reference to Table 2, it was confirmed that Comparative 5 having less phosphorescent dopant material than Comparative 6 exhibited a poor performance in all the above evaluation items. However, it was confirmed that the organic EL device in Example 6 containing the compound GH1-1 as the second host material, although having the same content (5 mass %) of the phosphorescent dopant material as in Comparative 5, exhibited a higher performance than not only the organic EL device in Comparative 5 but also the organic EL device in Comparative 6. In other words, in Example 6, addition of the second host material can improve performance, particularly, the efficiency and lifetime of the organic EL device with the low content of the phosphorescent dopant material.

### Example 10

The organic EL devices according to Example 10 was manufactured in the same manner as in Example 1, except that the materials, a thickness of each of the layers and a concentration of each of the materials were changed as shown in Table 5 and that the electron transporting layer was provided on the emitting layer. In other words, no hole blocking layer was provided in the organic EL device of Example 10. In comparison with Example 10, a device arrangement and the like in Comparative 6 are also shown below.

TABLE 5

| | Device Arrangement |
|---|---|
| Example 10 | ITO(75)/HA-1(5)/HT-1(150)/GH1-1(20)/GH2-5: GH1-1: Ir(ppy)₃ (40, 10%: 10%)/ET-2(30)/LiF(1)/Al(80) |
| Comp. 6 | ITO(75)/HA-1(5)/HT-1(150)/GH1-1(20)/GH2-1: Ir(ppy)₃ (40, 10%)/ET-2(30)/LiF(1)/Al(80) |

The compound GH2-5 used in Example 10 is shown. Other materials are the same as the above.

In Example 10, the compound GH2-5 contained in the emitting layer corresponds to the first host material of the invention and the compound GH1-1 corresponds to the second host material of the invention. The ionization potential of the compound GH2-5 was 5.9 eV. Measurement of the ionization potential was conducted in the same manner as the above.

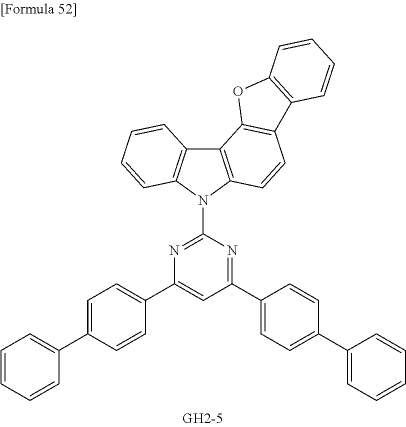 [SMILES: c1ccc(-c2ccc(-c3cc(-c4ccc(-c5ccccc5)cc4)nc(-n4c5ccccc5c5c6oc7ccccc7c6ccc54)n3)cc2)cc1]

### Evaluation of Organic EL Device

The manufactured organic EL devices were evaluated in the same manner as the above in terms of a drive voltage, a current efficiency L/J, an electrical power efficiency η, an external quantum efficiency EQE and lifetime (LT80). A current density for each of the evaluation items was set at 10.00 mA/cm². The results of the evaluation are shown in Table 6.

TABLE 6

| | Drive | | | | LT80 |
|---|---|---|---|---|---|
| | Voltage | L/J | η | EQE | @25000 nit |
| | (V) | (cd/A) | (lm/W) | (%) | (hrs) |
| Example 10 | 4.41 | 55.6 | 39.6 | 15.3 | 44 |
| Comp. 6 | 3.92 | 50.7 | 40.7 | 14.1 | 30 |

As shown in Table 6, the organic EL device in Example 10 exhibited a high luminous efficiency and a lifetime of about 1.5 times as long as the lifetime of the organic EL device in Comparative 6.

Moreover, based on the above ionization potential of each of the compounds, the ionization potential Ip(EML) of the emitting layer in Example 10 was calculated according to the above numerical formula 3. It was confirmed that the above numerical formula 2 was satisfied in Example 10. The calculation results are shown in Table 7. It should be noted that a value of Ip(EML2) was calculated for the emitting layer that contains the first host material (the compound GH2-5) and the phosphorescent dopant material (Ir(ppy)₃) but does not contain the second host material (the compound GH1-1). At this time, as for the concentration of each of the materials in the emitting layer in Example 10, the first host material was set at 90 mass % and the phosphorescent dopant material was set at 10 mass %. In other words, the mass of the first host material was increased by the mass of the second host material not to be contained.

TABLE 7

| Emitting layer | | {ΔIp |
|---|---|---|
| | Phos- | (EML2- |

| | Second | First | | Second | | phorescent | | | | | | | HT)− |
|---|---|---|---|---|---|---|---|---|---|---|---|---|---|
| | hole | host | | host | | dopant | | | | | | ΔIp | ΔIp |
| | transporting | material | | material | | material | | | | | | (EML2- | (EML- |
| Layer | layer | GH2-5 | | GH1-1 | | (Ir(ppy)₃ | | | | | | HT)− | HT)} × |
| Compound | GH1-1 | | Concen- | | Concen- | | Concen- | Ip | Ip | ΔIp | ΔIp | ΔIp | 100/ |
| Ip/Concen- | Ip (HT) | Ip(h1) | tration | Ip(h2) | tration | Ip(d) | tration | (EML) | (EML2) | (EML- | (EML2- | (EML- | ΔIp(EML- |
| tration | [eV] | [eV] | [mass %] | [eV] | [mass %] | [eV] | [mass %] | [eV] | [eV] | HT) | HT) | HT) | HT) |
| Example 10 | 5.5 | 5.9 | 80 | 5.5 | 10 | 5.1 | 10 | 5.78 | 5.82 | 0.280 | 0.320 | 0.040 | 14.286 |

### INDUSTRIAL APPLICABILITY

An organic EL device of the invention is applicable to a display and an illuminator.

### EXPLANATION OF CODES

1, 1A, 1B: organic EL device (organic electroluminescence device)
2: substrate
3: anode
4: cathode
5: emitting layer
6: hole transporting layer
7: electron transporting layer

1. An organic electroluminescence device comprising:
an anode;
a cathode; and
at least an emitting layer interposed between the anode and the cathode, wherein
the emitting layer comprises a first host material, a second host material and a phosphorescent dopant material as main components,
the first host material is a compound represented by a formula (1) below, and
the second host material is represented by a formula (2) below, 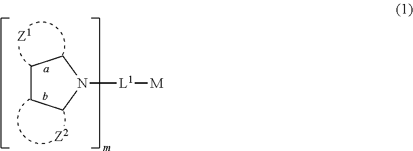
where:
Z¹ to be fused at a represents a cyclic structure represented by the following formula (1-1) or (1-2);
Z² to be fused at b represents a cyclic structure represented by the following formula (1-1) or (1-2); at least one of Z¹ and Z² is represented by the formula (1-1);
M is a substituted or unsubstituted nitrogen-containing heteroaromatic ring having 2 to 40 ring carbon atoms;
L¹ is a single bond or a linking group and represents as the linking group a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group; and
m is 1 or 2, 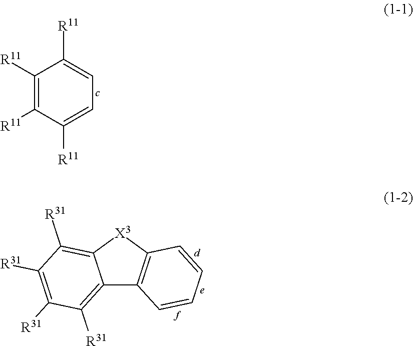
where:
c, d, e and f are fused to a or b in the formula (1);
R¹¹ and R³¹ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms;
a plurality of R¹¹ are optionally mutually the same or different;
a plurality of R³¹ are optionally mutually the same or different;
X³ represents a sulfur atom, an oxygen atom or N—R³²; and
R³² represents the same described above as R¹¹ and R³¹, 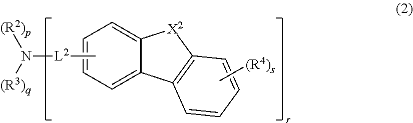
X² represents a sulfur atom, an oxygen atom or N—R⁵;
L² is a single bond or a linking group and represents the same as L¹ in the formula (1);
R² and R³ each independently represent a substituted or unsubstituted aromatic hydrocarbon group having 6 to 30 ring carbon atoms, or a substituted or unsubstituted aromatic heterocyclic group having 2 to 30 ring carbon atoms;
R⁴ and R⁵ are the same as R¹¹ and R³¹ in the formulae (1-1) and (1-2);
p and q represent an integer of 0 to 2 and r represents an integer of 1 to 3, provided that p+q+r=3;
s represents an integer 1 to 4; and when s is an integer of 2 to 4, a plurality of R⁴ are optionally the same or different.

2. The organic electroluminescence device according to claim 1, wherein the first host material is represented by a formula (3) below, 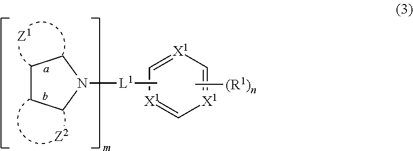
where:
Z¹ to be fused at a represents a cyclic structure represented by the following formula (1-1) or (1-2);
Z² to be fused at b represents a cyclic structure represented by the formula (1-1) or (1-2);
at least one of Z¹ and Z² is represented by the formula (1-1);
L¹ is a single bond or a linking group and represents as the linking group a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group;
X¹ is a nitrogen atom or C—R¹⁰, and at least one of a plurality of X¹ is a nitrogen atom;
R¹ and R¹⁰ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms;
m and n are an integer of 1 to 2, and
in the formulae (1-1) and (1-2), c, d, e and f are fused to a or b in the formula (3).

3. The organic electroluminescence device according to claim 1, wherein
the first host material is represented by a formula (4) below, 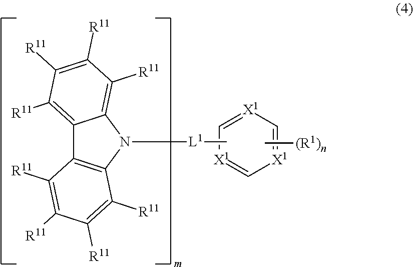
where:
L¹ represents a single bond or a linking group and represents as the linking group a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group;
X¹ is a nitrogen atom or C—R¹⁰, and at least one of a plurality of X¹ is a nitrogen atom;
R¹, R¹⁰ and R¹¹ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms; and
m and n are an integer of 1 to 2.

4. The organic electroluminescence device according to claim 1, wherein
an ionization potential Ip(h1) of the first host material, an ionization potential Ip(h2) of the second host material and an ionization potential Ip(d) of the phosphorescent dopant material satisfy the following relationship:
Ip(h1)>Ip(h2)>Ip(d).

5. The organic electroluminescence device according to claim 1, wherein
a wavelength of an emission peak of the phosphorescent dopant material is in a range of 510 nm to 570 nm.

6. The organic electroluminescence device according to claim 2, wherein the first host material is represented by a formula (4) below, 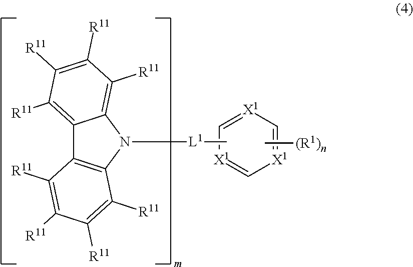
where:
L¹ represents a single bond or a linking group and represents as the linking group a substituted or unsubstituted aromatic hydrocarbon group having 6 to 30 ring carbon atoms, a substituted or unsubstituted aromatic heterocyclic group having 2 to 30 ring carbon atoms, a cyclic hydrocarbon group having 5 to 30 ring carbon atoms, or a group provided by bonding the aromatic hydrocarbon group, the aromatic heterocyclic group and the cyclic hydrocarbon group;
X¹ is a nitrogen atom or C—R¹⁰, and at least one of a plurality of X¹ is a nitrogen atom;
R¹, R¹⁰ and R¹¹ each independently represent a hydrogen atom, a fluorine atom, a cyano group, a substituted or unsubstituted alkyl group having 1 to 20 carbon atoms, a substituted or unsubstituted alkoxy group having 1 to 20 carbon atoms, a substituted or unsubstituted haloalkyl group having 1 to 20 carbon atoms, a substituted or unsubstituted haloalkoxy group having 1 to 20 carbon atoms, a substituted or unsubstituted alkylsilyl group having 1 to 10 carbon atoms, a substituted or unsubstituted arylsilyl group having 6 to 30 carbon atoms, a substituted or unsubstituted aromatic hydrocarbon group having 6 to 30 ring carbon atoms, or a substituted or unsubstituted aromatic heterocyclic group having 2 to 30 ring carbon atoms; and
m and n are an integer of 1 to 2.

7. The organic electroluminescence device according to claim 2, wherein
an ionization potential Ip(h1) of the first host material, an ionization potential Ip(h2) of the second host material and an ionization potential Ip(d) of the phosphorescent dopant material satisfy the following relationship:
Ip(h1)>Ip(h2)>Ip(d).

8. The organic electroluminescence device according to claim 3, wherein
an ionization potential Ip(h1) of the first host material, an ionization potential Ip(h2) of the second host material and an ionization potential Ip(d) of the phosphorescent dopant material satisfy the following relationship:
Ip(h1)>Ip(h2)>Ip(d).
